(19) United States
(12) Patent Application Publication
(10) Pub. No.: US 2018/0009213 A1
(43) Pub. Date: Jan. 11, 2018

(54) LITHOGRAPHIC PRINTING PLATES PRECURSORS COMPRISING A RADIATION SENSITIVE IMAGEABLE LAYER WITH A CROSSLINKED SURFACE

(71) Applicant: Mylan Group, Tra Vinh City (VN)

(72) Inventors: My T. Nguyen, Tra Vinh City (VN); Thanh Sang Nguyen, Tra Vinh (VN); Thanh Dien Luu, Vinh Long (VN); Thi Thuy Linh Kien, Tra Vinh (VN)

(21) Appl. No.: 15/701,626

(22) Filed: Sep. 12, 2017

Related U.S. Application Data
(62) Division of application No. 15/320,403, filed on Dec. 20, 2016.
(60) Provisional application No. 62/031,904, filed on Aug. 1, 2014.
(60) Provisional application No. 62/014,815, filed on Jun. 20, 2014.

(51) Int. Cl. B41C 1/10; G03F 7/038; G03F 7/032; G03F 7/105; G03F 7/031

(52) U.S. Cl. CPC B41C 1/1016; G03F 7/105; G03F 7/031; G03F 7/0325; G03F 7/0388; B41C 2210/06; B41C 2210/08; B41C 2210/20; B41C 2210/22; B41C 2210/04; B41C 2210/26

(57) ABSTRACT

There are free radical scavengers of formula (Pₘ-L)ₙ-T_{q}. Also provided are negative-working lithographic printing plate precursors comprising a hydrophilic substrate and a NIR photopolymerizable or UV-violet photopolymerizable imageable layer coated on the hydrophilic layer, the imageable layer also being photopolymerizable by visible light, the imageable layer having an outer surface and a thickness, the outer surface of the imageable layer being uniformly, and partially or completely crosslinked down to a depth corresponding to at most about 70% of the thickness of the imageable layer.

### CROSS REFERENCE TO RELATED APPLICATIONS

N/A

### FIELD OF THE INVENTION

This present invention relates to a lithographic offset printing plate. More specifically, this present invention relates to a negative working lithographic offset printing plate suitable for use in computer-to-plate systems, which comprises a radiation sensitive imageable layer having a crosslinked surface.

### BACKGROUND OF THE INVENTION

In lithographic printing, a printing plate is mounted on the cylinder of a printing press. The printing plate bears a lithographic image of what is to be printed. A printed copy is obtained by applying ink to the image and then transferring the ink from the printing plate onto a receiver material, which typically is a sheet of paper. In fact, generally, the ink is first transferred to an intermediate blanket, which in turn transfers the ink to the surface of the receiver material (this is called offset printing).

In conventional, so-called “wet” lithographic printing, the hydrophobic ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. When the surface of the printing plate is moistened by the fountain solution and ink, the hydrophilic regions retain water and repel ink, and the ink-receptive regions retain ink and repel water. During printing, the ink is transferred to the surface of the receiver material upon which the image is to be reproduced.

Lithographic printing plates are obtained by imaging and developing lithographic printing plate precursors. Such precursors typically comprise a hydrophobic imageable layer (also called imaging layer or coating) applied over the hydrophilic surface of a substrate, typically aluminum.

During imaging, targeted laser radiation is used to elicit a localized transformation of the imageable layer. Indeed, exposure to the targeted radiation will trigger a physical and/or chemical change in the imageable layer so that the exposed areas become different from the unexposed areas. This can be carried out in different ways. In direct digital imaging (computer-to-plate), precursors are irradiated with near infrared (NIR) or ultraviolet-violet (UV-violet) lasers digitally controlled by computer so that exposure of the precursor can be performed directly from digitized information stored in a computer.

Typically, through imaging, the exposed (i.e. irradiated) areas are made more or less susceptible to subsequent development. Indeed, following imaging, the precursor will be developed. During development, either the exposed areas or the unexposed areas of the hydrophobic imageable layer will be removed, revealing the underlying hydrophilic surface of the substrate. If the exposed areas are removed, the precursor is positive working. Conversely, if the unexposed areas are removed, the precursor is negative working. In each case, the regions of the imageable layer that remain are hydrophobic, and the regions of the substrate revealed by development are hydrophilic. This produces a pattern of hydrophobic and hydrophilic areas, i.e. the desired lithographic image, on the printing plate.

Development can be carried out by immersing the imaged precursor in a developer. Developers are typically aqueous alkaline solutions, which may also contain organic solvents. Alternatively, “on-press developable” lithographic printing plates can be directly mounted on a press after imaging, and are developed through contact with the ink and/or the fountain solution during initial press operation.

In negative-working printing plate precursors, irradiation typically makes the exposed areas less soluble in the developer/fountain solution and/or more adherent to the substrate, which allows obtaining the desired lithographic image upon development. This decrease in solubility and increase in adhesion is generally due to the crosslinking of the imageable layer and/or the coalescence (fusion) of polymeric particles in the exposed areas of the imageable layer. The crosslinking is commonly achieved via free-radical polymerization; the free radicals being created in the imageable layer by the laser irradiation. The particle coalescence is due to the heat produced in the imageable layer when some of its component absorbs the laser irradiation. Generally, crosslinking is the primary mechanism at work in UV-violet plates. In NIR printing plates (which are also called thermal plates), the coalescence of particles is more important and may contribute as much as, or even more than, crosslinking.

Optionally, after imaging but prior to development, the imaged precursor may be heated, for example at the temperature between 100 and 140° C., to complete the crosslinking reactions and harden the formed image.

Generally speaking, the above technology is not without shortcomings.

First, if not prevented to do so, oxygen molecules from ambient air will penetrate into the imageable layer of the precursor. There, they will quench the free radicals produced by irradiation during imaging. These radicals are however necessary for the desired photopolymerization (crosslinking) of the exposed areas of the imageable layer. Therefore this will reduce the imaging speed as more energy from the laser will be needed to achieve a given level of crosslinking.

In addition, exposure to ambient air/humidity, especially during longer periods (e.g. during storage) is known to cause background staining through thermal fogging (water molecules penetrating the imageable layer and causing some polymerization at the imageable layer/substrate interface). This means that areas that are supposed to be free of ink during printing will accept some ink, which will cause stains in the background of the printed image.

Of course, it will be easily understood that the above sensitivity of the negative-working precursors to ambient air generally translates into rather short self-lives.

Finally, on the practical side, the imageable layers tend to be tacky and prone to scratches. Tackiness causes several problems during production. Among them is the problem of plate precursors sticking together (they are stored in piles). Scratches can reduce printing quality. They can be reduced by using a protective interleaving paper, which then must be removed before use.

To alleviate these problems, it has been suggested to add an overcoat (also called top coat) over the imaging layer. Printing plate precursors comprising a polymeric overcoat, which are typically hydrophilic, have several advantages. First, the overcoat act as an oxygen barrier, which provides faster laser imaging speeds as it prevents quenching of the initiating and propagating free radicals involved in the photopolymerization process by oxygen molecules from the air (especially during laser imaging and pre-development heating when the precursor is exposed to air). These coats also help in overcoming the surface tackiness of the radiation sensitive imageable layer, which is often due to the presence of viscous liquid radical polymerizable oligomers in the formulation. The polymeric overcoat also provides some scratching resistance to the radiation sensitive imageable layer during transportation, storage and pre-press operation.

Examples of negative-working precursors with or without overcoats are provided by U.S. Pat. No. 5,821,030 (West et al.), U.S. Pat. No. 5,888,700 (West et al.), U.S. Pat. No. 6,899,994 (Huang et al.), U.S. Pat. No. 7,261,998 (Hayashi et al.), U.S. Pat. No. 7,732,118 (Tao et al.), U.S. Pat. No. 7,955,776 (Baumann et al.), U.S. Pat. No. 6,830,862 (Kitson et al.), which are incorporated herein by reference. Typical overcoats are preferably transparent to the laser radiation that will be used for imaging and are usually coated from an aqueous solution comprising a water soluble polymer, such as polyvinyl alcohol, polyvinylpyrrolidone, or hydroxy alkyl cellulose.

It should be noted however that the use of such overcoats also has some disadvantages. First, overcoats increase production costs, since they require multiple coating processes (steps) due to differences in the solubility and the chemical nature of the materials used in the overcoat compared to that used in the radiation sensitive imageable layer. In addition, delamination of the overcoat is commonly observed. Solving this particular issue requires the use of adhesion promoting agents in the overcoat. However, diffusion of such adhesion promoting agents in the imageable layer (e.g. during storage and prepress operation) can shorten the shelf-life of the plate precursor and adversely modify the image forming property of the radiation sensitive imageable layer. Finally, when the overcoat adhere sufficiently to avoid delamination, it often becomes difficult to remove during development. Therefore, it may remain over to the imageable layer and undesirably reduce its hydrophobicity. In other words, it reduces the capacity of the imageable layer to accept as much ink as it should. As a result, the printing image has a lower optical density (i.e. it is paler). This phenomenon is called “blinding”.

### SUMMARY OF THE INVENTION

In accordance with the present invention, there is provided:
1. A negative-working lithographic printing plate precursor comprising a hydrophilic substrate and a NIR and/or UV-violet photopolymerizable imageable layer coated on the hydrophilic layer,
   the imageable layer also being photopolymerizable by visible light,
   the imageable layer having an outer surface and a thickness, the outer surface of the imageable layer being uniformly, and partially or completely crosslinked down to a depth corresponding to at most about 70% of the thickness of the imageable layer.
2. The precursor of item 1, wherein said depth correspond to between about 5% and about 50% of the thickness of the imageable layer.
3. The precursor of item 2, wherein said depth correspond to between about 5% and about 15% of the thickness of the imageable layer.
4. The precursor of any one of items 1 to 3, wherein the outer surface of the imageable layer is partially crosslinked.
5. The precursor any one of items 1 to 4, wherein the outer surface of the imageable layer is completely crosslinked.
6. The precursor any one of items 1 to 5, wherein the imageable layer comprises one or more of each of:
   a polymeric binder;
   a radical polymerizable copolymer;
   a radical polymerizable oligomer;
   a photoinitiating system sensitive to NIR and/or UV-violet radiation comprising:
      a free radical photoinitiator sensitive to visible radiation,
      a free radical coinitiator,
      a free radical scavenger,
      a photosensitizer, and
      a photostabilizer; and
   a visible colorant.
7. The precursor of item 6, wherein said visible radiation has a wavelength between about 400 and about 450 nm.
8. The precursor of item 6 or 7, wherein the free radical scavenger is a free radical scavenger as defined in any one of items 29 to 35.
9. The precursor of any one of items 6 to 8, wherein the imageable layer further comprises a visible light reflective pigment.
10. The precursor of item 9, wherein the visible light reflective pigment is titanium dioxide, zinc oxide, and aluminum oxide.
11. The precursor of any one of items 6 to 10, wherein the imageable layer is UV-violet photopolymerizable, the free radical photoinitiator being sensitive to visible radiation and UV-violet radiation, and the photosensitizer being sensitive to UV-violet radiation.
12. The precursor of any one of items 6 to 10, wherein the imageable layer is NIR photopolymerizable, the free radical photoinitiator being sensitive to visible radiation, and the photosensitizer being sensitive to NIR radiation.
13. The precursor of any one of items 6 to 10, wherein the imageable layer is NIR photopolymerizable and UV-violet photopolymerizable, the free radical photoinitiator being sensitive to visible radiation and UV-violet radiation, and the imageable layer comprising a photosensitizer sensitive to NIR radiation and a photosensitizer sensitive to UV-violet radiation.
14. The precursor of any one of items 11 to 13, wherein the photoinitiator has one or more absorption bands in the UV-violet range, with at least one of these bands trailing into the visible range of the electromagnetic spectrum or with a shoulder or one or more further minor bands in the visible range.
15. The precursor of any one of items 11 to 14, wherein the photoinitiator is a triazine, thioxanthone, mercaptothioxanthone, cyanine, monomethine, coumarine, ketocoumarine, pyrromethene, or oxime ester photoinitiator.
16. The precursor of any one of items 11 to 15, wherein the photosensitizer sensitive to UV-violet radiation is a triazine, thioxanthone, mercaptothioxanthone, cyanine, monomethine, coumarine, ketocoumarine, pyrromethene, or oxime ester photosensitizer.
17. The precursor of any one of items 11 to 16, where the photoinitiator and the photosensitizer sensitive to UV-violet radiation are the same molecule.
18. The precursor of any one of items 11 to 17, wherein one or more of the polymeric binder, the radical polymerizable copolymer, the photoinitiator, the scavenger, and the photosensitizer is in the form of polymeric particles that coalesce in the presence of heat.
19. The precursor of any one of items 11 to 18, wherein the photosensitizer sensitive to NIR radiation is a cyanine dye or a squaraine dye.
20. A method of manufacturing a negative-working lithographic printing plate precursor, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
21. A method of creating an oxygen barrier on an imageable layer of a negative-working lithographic printing plate precursor, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
22. A method for protecting an imageable layer of a negative-working lithographic printing plate precursor from scratches, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
23. A method for reducing the tackiness of an imageable layer of a negative-working lithographic printing plate precursor, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
24. A method for reducing absorption by an imageable layer of a negative-working lithographic printing plate precursor of oxygen molecules from the air, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
25. A method for increasing the laser imaging speed of an imageable layer of a negative-working lithographic printing plate precursor, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
26. A method for increasing the self-life of a negative-working lithographic printing plate precursor, the method comprising the steps of:
   a) providing a hydrophilic substrate coated with a NIR and/or UV-violet photopolymerizable imageable layer, the imageable layer comprising a free radical photoinitiator sensitive to visible radiation, the imageable layer having an outer surface and a thickness,
   b) uniformly, and partially or completely crosslinking the outer surface of the imageable layer down to a depth corresponding to at most about 70% of the thickness of the imageable layer.
27. The method of any one of items 20 to 26, wherein step b) is carried out by irradiating the imageable layer with visible light.
28. A negative-working lithographic printing plate precursor produced according to the method of any one of items 20 to 27.
29. A free radical scavenger of formula:

(Pₘ-L)ₙ-T_{q},

wherein:
P is a radical polymerizable functional group or a substituent formed by joining two or more radical polymerizable functional groups together;
L is a linker having a valence equal to m+q;
T is a thiol group, or a substituent comprising a thiol group and optionally further comprising a carboxylic acid group, wherein said substituent has a valence equal to n;
m is an integer between 1 to 5;
n is an integer between 1 to 5; and
q is an integer between 1 to 5.
30. The free radical scavenger of item 29 being of formula:

P-L-T,

Pₘ-L-T

P-L-T_{q}, or

(P-L)ₙ-T.
31. The free radical scavenger of item 29 or 30, wherein P is:
   —X,
   —C—(CH₂—X)₃, or
   —C(CH₂—X)₂(CH₂—O—CH₂—C—(CH₂—X)₃),
   in which X is a radical polymerizable functional group.
32. The free radical scavenger of item 31, wherein P is:

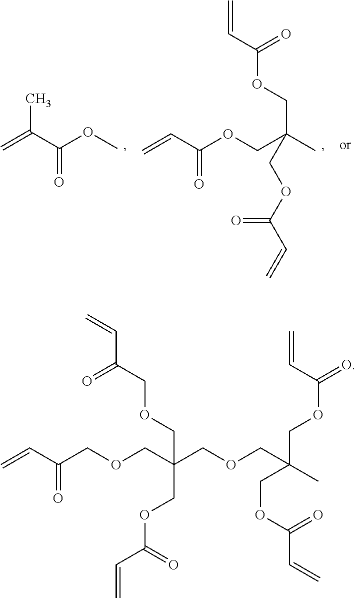

33. The free radical scavenger of any one of items 29 to 32, wherein T is:

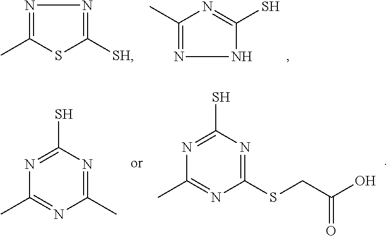

34. The free radical scavenger of any one of items 29 to 33, wherein L is an alkylene or alkylyne group comprising one or more following functional groups:
   —NH—C(═O)—S—,
   —S—C(═O)—NH—
   —NH—C(═O)—NH—,
   —NH—C(═O)—O—,
   —O—C(═O)—NH—,
   —S—,

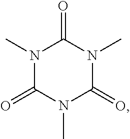

—NH—C(═O)—, and
—C(═O)—NH—.
35. The free radical scavenger of any one of items 29 to 33, wherein L is a copolymer, with P and T being attached as pendant groups to different monomers.

### BRIEF DESCRIPTION OF THE DRAWINGS

In the appended drawings:

FIG. 1 is a cross-sectional view of a negative working precursor according to an embodiment of the invention;

FIG. 2 is a cross-sectional view of a negative working precursor according to another embodiment of the invention;

FIG. 3 is a cross-sectional view of a negative working precursor according to yet another embodiment of the invention;

FIG. 4 shows the emission spectrum of the visible light source used to form a crosslinked surface on the radiation sensitive imageable layer in the Examples;

FIG. 5 shows the absorption spectrum of the UV-violet radiation sensitive imageable layer (solid line) of Example 1 and the emission spectrum of the visible light source (dash line);

FIG. 6 shows the dot gains at 50% dot target at different energy densities for printing plates with a UV-violet laser radiation sensitive imageable layer with (circles) and without (squares) a crosslinked surface, as produced in Example 1;

FIG. 7 shows the dot gains after different aging duration for printing plates with (circles) and without (squares) a crosslinked surface, as produced in Example 1;

FIG. 8 shows the dot gains for a printing plate with an imageable layer without TiO₂ (Example UV-7, circles) and that for a printing plate with an imageable layer with 1% TiO₂ (Example UV-8, squares) as a function of the duration of exposition to visible light;

FIG. 9 shows the optical density of the developed printed plates (without laser imaging) produced in Examples 7 and 8, as a function of the duration of exposition to visible light;

FIG. 10 shows the absorption spectrum of the NIR radiation sensitive imageable layer (solid line) of the precursor of Example 9 and the emission spectrum of the visible light source (dash line);

FIG. 11 shows the dot gains at different energy densities for fresh NIR radiation sensitive printing plates with (circles) and without (squares) a crosslinked surface, as produced in Example 9; and

FIG. 12 shows the dot gains at 120 mJ/cm² of the printing plates comprising a NIR laser radiation sensitive imageable layer with (circles) and without (squares) a crosslinked surface, as produced in Example 9, after aging at 40° C. and 80% RH.

### DETAILED DESCRIPTION OF THE INVENTION

### Negative-Working Lithographic Printing Plate Precursor

Turning now to the invention in more details, there is provided a negative-working lithographic printing plate precursor comprising a hydrophilic substrate and a NIR and/or UV-violet photopolymerizable imageable layer coated on the hydrophilic layer, the imageable layer being photopolymerizable by visible light, the imageable layer having an outer surface and a thickness, the outer surface of the imageable layer being uniformly, and partially or completely, crosslinked down to a depth corresponding to at most about 70% of the thickness of the imageable layer.

Herein, a “lithographic printing plate precursor” refers to a lithographic printing plate that has not yet been imaged. A precursor bears a radiation sensitive imageable layer. However, unlike in a printing plate, this imageable layer does not (yet) bears a lithographic image. In the case of the NIR and/or UV-violet radiation sensitive photopolymerizable lithographic printing plate precursor above, this means that the precursor has not been imaged with the NIR and/or UV-violet radiation.

The precursor is suitable for use in computer-to-plate (CTP) systems.

The precursor is suitable for development on press.

### Advantages

The precursor of the present invention can, in embodiment, have the following advantages.

In the present invention, the crosslinked outer surface of the imageable layer acts as an overcoat. Contrary to conventional overcoats however, the crosslinked outer surface of the imageable layer is advantageously an integral part of the imageable layer. This eliminates risks of delamination.

It will be understood that since the crosslinked outer surface of the imageable layer acts as an overcoat, the precursor will typically be free of such overcoats. It other words, the imageable layer will not be covered by any coating, i.e. it will be accessible to ambient air.

For certainty, it should also be understood that, as the imageable layer itself, the crosslinked outer surfaced of the imageable layer is hydrophobic. In other words, the crosslinking of the outer surface of the imageable layer does not reduce the optical density of the printed image.

The crosslinked outer surface acts as an overcoat; as an oxygen barrier. It thus contributes to faster laser imaging speeds because it prevents/reduces quenching of the initiating and propagating free radicals involved in the photopolymerization process by oxygen molecules from the air. In turn, this contributes to increasing the shelf-life of the precursor, especially in non-optimal conditions (at higher temperature and/or higher relative humidity).

After laser imaging and development, the imageable layer with a crosslinked surface is generally stronger/harder than a corresponding imageable layer without a crosslinked surface, as such the imageable layer with a crosslinked surface provides a better print quality and longer print length.

The crosslinked outer surface is often less tacky and/or, as stated above, harder (i.e. more scratch- and fingerprint-resistant) than the un-crosslinked imageable layer. Therefore, provides some degree of physical protection to the underlying imageable layer.

Finally, the manufacture of the precursor of the present invention is easier and more-effective than that of similarly precursor with overcoats. As described below, the crosslinking of the outer surface can indeed by carried out after coating (and drying) of the imageable layer simply by adding a suitable visible light source in the production line.

### Imageable Layer

As stated above, the precursor comprises a hydrophilic substrate and also comprises an imageable layer. This imageable layer is coated on the hydrophilic substrate. Typically, this means that it (entirely or almost entirely) covers one side of the substrate.

The imageable layer has an outer surface and a thickness. The outer surface is the surface of the imageable layer that is opposite the substrate/imageable layer interface. In other words, it is the surface accessible to ambient air.

The thickness of the imageable layer is that commonly found in the art. Preferably, the thickness is between about 0.6 and about 3.0 μm, preferably from about 0.8 to about 1.0 μm. In particular, the imageable layer may have a coating weight between about 0.6 and about 3.0 g/m². A preferred coating weight is of between about 0.8 and 1.0 g/m².

### Crosslinked Outer Surface

In the present invention, the outer surface of the imageable layer is uniformly, and partially or completely, crosslinked down to a depth corresponding to at most about 70% of the thickness of the imageable layer, preferably between about 5% and about 70%, for example between about 5% and about 50%, between about 5% and about 25%, between about 5% and about 15%, of the thickness of the imageable layer, most preferably down to about 10% of the thickness of the imageable layer. Preferably, the imageable layer is thus crosslinked down to a depth between about 0.06 and about 0.30 μm.

FIG. 1 is a cross-sectional view of a negative working precursor according to an embodiment of the invention. In this figure:
[101] is the imageable layer;
[102] is the part of the imageable layer that is crosslinked; and
[103] is the hydrophilic substrate.

It should be understood that the part of the imageable layer that is crosslinked is integral to the imageable layer. It is not a (separate) overcoat covering the imageable layer.

In the present invention, the outer surface of the imageable layer is crosslinked “down to a depth . . . ” This means that the outer surface of the imageable layer is crosslinked and that this crosslinking extends from this outer surface down into the imageable layer towards the substrate/imageable layer interface. For reference, this interface is identified as [104] in FIG. 1, while the outer surface is labelled as [105]. Of note, the crosslinking does not extend all the way down to the substrate/imageable layer interface. Rather, as stated above, it extends at most 70% of the way.

In that regard, the crosslinking of the outer surface of the imageable layer is very different from the photopolymerization that takes place when the precursor is imaged with a laser in view of printing. The latter is produced by a powerful and focused light source (typically a laser focused with a condenser) in a way that purposefully insures that the exposed areas of imageable layer are crosslinked down to the substrate/imageable layer interface. This indeed reduces the solubility of the exposed areas to a minimum while adhering (almost fusing) the exposed imageable layer on the substrate. Indeed, it is necessary that this photopolymerization reach down as such because, otherwise, the printing plate cannot be properly developed (some areas that should retain the imageable layer would be free of it for lack of adhesion) and cannot be used for printing.

In the present invention, the outer surface the imageable layer is “uniformly” crosslinked. This means that this crosslinking does not form a lithographic image (which would be characterized by a pattern of crosslinked and un-crosslinked areas) or any other pattern on the precursor. Rather, the crosslinking is uniform over the whole outer surface. Perfect uniformity is not required as long as the outer surface is crosslinked enough to fulfill its purpose (more on that below). Rather, the “uniform” crosslinking refers to the fact that the precursor has not been irradiated, to imprint therein a lithographic image in view of development and printing.

In the present invention, the outer surface of the imageable layer is “partially or completely” crosslinked. Complete crosslinking means that the outer surface cannot be meaningfully crosslinked anymore. This occurs when all the radical polymerizable functional groups that could undergo crosslinking reactions have done so. Partially crosslinking means that the outer surface has the potential to be further crosslinked as there remain therein radical polymerizable functional groups that can still undergo crosslinking reactions.

Typically, the denser the crosslinking, the thinner the crosslinked layer needs to be.

### Photopolymerization and Light Sensitivity of the Imageable Layer

In the present invention, the imageable layer is NIR and/or UV-violet photopolymerizable. Further, it is photopolymerizable by visible light.

Visible radiation is radiation at wavelengths perceived by the human eye. It is defined as radiation with a wavelength between about 400 (violet) to about 700 (red) nm. Near-infrared (NIR) radiation has longer wavelengths, while ultraviolet (UV) has shorter wavelengths. Herein, NIR is defined as having a wavelength from about 780 to about 1100 nm, while “UV-violet” is defined as radiation having a wavelength between about, from about 200 to about 420 nm.

NIR photopolymerizable and UV-violet photopolymerizable imageable layers are well known in the art. In fact, most negative-working printing plate precursors are either NIR-sensitive or UV-violet-sensitive.

Typically, NIR photopolymerizable and UV-violet photopolymerizable imageable layers comprise a photoinitiating system sensitive of NIR and/or UV-violet radiation, respectively. This means, in fact, that it comprises a photoinitiator and/or a photosensitizer which, during imaging, absorbs incoming NIR and/or UV-violet laser radiation and produce free radicals and/or heat, respectively. These free radicals and/or this heat will trigger the desired crosslinking/coalescence in the imageable layer. Such photoinitiators and photosensitizers are well-known to the skilled person.

The UV-violet laser radiation generally has a wavelength between about 354 and about 410 nm, preferably 405 nm. Lasers emitting at such wavelengths are well-known in the art and include gallium (III) nitrile, indium gallium nitrile, and triple neodymium-doped yttrium aluminum garnet. The NIR laser radiation generally has a wavelength between about 780 and 1064 nm, preferably between 800 and 850 nm. Lasers emitting at such wavelengths are well-known in the art and include aluminum and/or indium doped gallium arsenide lasers, gallium manganese arsenide laser, and gallium arsenide phosphide laser.

The imageable layer in the precursors of the invention is also photopolymerizable by visible light. This means that the imageable layer comprises a photoinitiator that is sensitive to (i.e. absorbs) (at least slightly) incoming visible radiation and produces at least some free radicals. These free radicals will trigger crosslinking of the imageable layer (photopolymerization). This allows crosslinking of the outer surface of the imageable layer using a visible light source emitting at such wavelengths. More specifically, this means that the photoinitiator already used in the precursor for imaging (if any) also absorbs visible light or alternatively that an additional photoinitiator is used in the precursor for the specific purpose absorbing visible light and producing free radicals for crosslinking the outer surface.

The visible light absorbed by the photoinitiator can be between about 400 and about 700 nm, for example between about 400 and about 600 nm, between about 400 and about 500 nm, between about 400 and about 475 nm, or between about 400 and about 450 nm.

Of note, the absorption of the photoinitiator in the visible range will typically be much lower than that of the photoinitiator/photosensitizer in the UV-violet/NIR ranges. Indeed, as much less crosslinking is desired (only the outer surface should be crosslinked), a high absorption is not necessary. The photoinitiator should simply be sufficiently absorbent in the visible range so that crosslinking is possible in a reasonable amount of time using a reasonable amount of energy. However, it should not be so absorbent that the precursor cannot be handled for a reasonable amount of time in ambient light. Within these boundaries, the absorption of the photoinitiator can vary; the light source used to elicit crosslinking and the duration of exposure will then simply be adapted to it as described below

It will be well-known to the skilled person that the absorption peaks/bands in the NIR/visible/UV regions of the electromagnetic spectrum are typically rather broad (see the Figures herein for typical examples). Therefore, light absorption in the various regions referred to above can be achieved in various ways. For example, two molecules having different absorption bands can each cover one of the desired ranges of interest (visible, and NIR or UV-violet). Alternatively, one molecule can have a single broad band (perhaps with shoulders or secondary/minor band(s)) covering at once wavelengths in more than one desired ranges of interest. Such variations are inconsequential as long as sufficient light is absorbed to achieve the desired photopolymerization, both during imaging of the precursor and when crosslinking the outer surface, in a reasonable amount of time using a reasonable amount of energy.

### Typical Components and Their Functions

In embodiments, the imageable layer comprises one or more of each of:
a polymeric binder;
a radical polymerizable copolymer;
a radical polymerizable oligomer;
a photoinitiating system sensitive to NIR and/or UV-violet radiation comprising:
   a free radical photoinitiator sensitive to visible radiation,
   a free radical coinitiator,
   a free radical scavenger,
   a photosensitizer, and
   a photostabilizer; and
a visible colorant.

As will be explained in more details in the following sections, many of these components can be provided in the form of polymeric particles. Such particles are advantageously used in NIR-photopolymerizable imageable layer as they will coalesce (fuse together) in the presence of heat.

The polymeric binders generally provide uniform film forming properties, improves development ability, and/or provides longer print length on press.

The radical polymerizable copolymers undergo photopolymerization in the presence of free radicals. Depending on the nature of their repeat units, some of these copolymers can also improve the film forming properties of the imageable layer, contribution to its adhesion on the substrate, act as free radical scavengers, etc.

The radical polymerizable oligomers, which typically comprise two or more radical polymerizable functional groups, also undergo photopolymerization in the presence of free radicals.

The photoinitiators are sensitive to (i.e. absorb) incoming radiation (typically UV and/or visible) and generate free radicals (and some heat). The photosensitizers are sensitive to (i.e. absorb) incoming radiation (UV or NIR) and generate heat (and some free radicals). A molecule can act as both a photoinitiator and a photosensitizer when it generates both free radicals and heat in significant amounts when absorbing incoming radiation.

The coinitiators absorb some of the free radicals generated by the photoinitiators and generate more free radicals. This process may be facilitated by heat generated in the imageable layer, more particularly in the case of NIR-sensitive precursor.

The free radical scavengers prevent the free radicals from recombining with one another and can act as hydrogen donators. This latter function is advantageous in NIR photopolymerizable precursors, where it is believed to help the crosslinking and the coalescence of the particles.

The photostabilizers help to stabilize the precursor and thus prolong its shelf-life. During storage, if some free radicals are generated, they can react with the photostabilizer. This molecule polymerize slowly, which will limit the damages done to the precursor.

The purpose of the visible colorant is to color the imageable layer and thus allow inspection of the precursor and imaged and developed printing plate. For note, visible colorant absorb visible light at various wavelength (and thus appeared to be colored), but they do not produce free radicals when they do so.

It should be noted that a single molecule can sometimes combine two or more of the above functions. Furthermore, two or more molecules above can be combined together. For example, a photosensitizer, photoinitiator, etc. can be attached as a pendant group to a polymeric binder, a copolymer, an oligomer, etc. As long as the functional group(s) responsible for the molecule's function are preserved, such attachment is expected to preserve the molecule function.

When the precursor is exposed to focused laser radiation at the right wavelength (NIR and/or UV-violet), the photoinitiating system will absorb this radiation and generate free radicals and heat. The radicals will trigger a photopolymerization via crosslinking reactions of the various radical polymerizable functional groups present in the imageable layer in the areas that were exposed to the laser radiation. The heat will cause the particles present in the areas that were exposed to the laser radiation to coalescence. The imaged precursor may be optionally be heated at a temperature between 100 and 140° C. or radication cured (for example UV-cured) as known in the art to complete the crosslinking/coalescence and/or harden the formed image. The precursor can then be developed with an aqueous developer in a processor or on-press with ink and a fountain solution. After development, the resulting printing plate is ready for printing.

Radical polymerizable functional groups are well-known to the skilled person. They typically comprise one or more polymerizable carbon-carbon double bonds (C═C), which are also referred to as an ethylenical unsaturations. Preferred examples of such functional groups include acrylate, methacrylate, acrylamide, methacrylamide, alkylacrylate, alkylmethacrylate, alkylacrylamide, alkylmethacrylamide, vinyl ether, allyl, and styryl, wherein, in embodiments, the alkyl has between 1 and 10 carbon atoms, preferably 1 or 2 carbon atoms. Most preferred radical polymerizable functional groups are acrylate, methacrylate, acrylamide, and methacrylamide.

Optionally, the imageable layer may further comprise one or more of each of:
a visible light reflective pigment,
a film forming surfactant; and
an adhesion promoting agent.

### Polymeric Binders

The imageable layer may comprise one or more polymeric binders. Polymeric binders for use in negative-working printing plate precursors are well-known to the skilled person. Any such known binder can be used in the present invention. Generally, polymeric binders can be used at a concentration between about 3 and about 50 weight percent.

The polymeric binders can be molecularly dispersed in the imageable layer or in the form of discrete particles, preferably having of a size ranging between about 60 and about 300 nm. Particles that can coalesce when heated are preferred in NIR-sensitive precursors.

Preferably, the polymeric binder is a high molecular weight polymer binder, for example having a molecular weight of about 3,000 Dalton or more.

The polymeric binder may or may not contain radical polymerizable functional groups.

Examples of typical polymeric binders include hydroxy-alkyl cellulose, acetal copolymers, acrylic acid copolymers, methacrylic acid copolymers, acrylamide copolymers, methacrylamide copolymers, acrylonitrile copolymers, substituted phenylimide copolymers, and alkylimide copolymers.

Examples of suitable polymeric binders can also be found in U.S. Pat. No. 8,323,867, which is incorporated herein by reference. This patent describes solvent- and/or water-soluble cellulose ethers comprising a functional group which can undergo radical and/or cationic polymerization. These cellulose ethers may have the following structure:

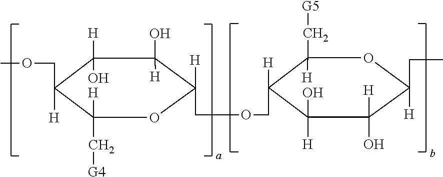

wherein:
G4 is hydroxy, hydroxyethyl and hydroxypropyl.
G5 is the functional group that can undergo radical and/or cationic polymerization.

More specifically, the G5 group may have the following structure:

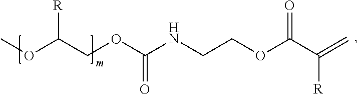

wherein m is 0 or 1 and R is hydrogen or methyl.

Examples of suitable polymeric binders can also be found in U.S. Pat. No. 8,323,867, which is also incorporated by reference, and which describes acetal copolymers having the following general structure:

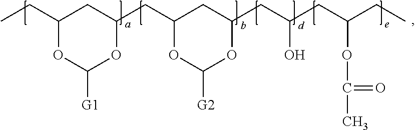

wherein G1, G2, a, b, d and e are as described below in regard of an acetal copolymeric photosensitizer of roughly similar formula described in the “Photosensitizer” section.

Other examples of suitable polymeric binders can be found in U.S. Pat. No. 7,723,010, which is also incorporated by reference. This patent describes polymer binders that may be, for example, cellulose polymers having non-ionic pendant groups, such as hydroxy, polyethylene oxide, polypropylene oxide or polybutylene oxide. The cellulose polymers may contain anionic pendant groups, such as carboxylic acid, sulfonic acid, phosphoric acid, and their corresponding lithium, sodium and potassium alkali salts. The cellulose polymers may contain cationic pendant groups, such as tetra-alkyl-ammonium salts. The cellulose polymers may contain radical polymerizable functional groups. The cellulose polymer binder may be that commercially available from American Dye Source, Inc. (Canada) under the trade-name Tuxedo® XCP10.

U.S. Pat. No. 7,723,010, which is also incorporated by reference, describes water soluble acetal copolymers having 4-hydroxyphenyl, 3-hydroxyphenyl, 2-hydroxyphenyl, alkyl, and hydroxy functional groups. In embodiments, the alkyl may be linear or branched alkyl having between 1 and 12 carbon atoms. The acetal copolymers may also comprise radical polymerizable functional groups. The water soluble acetal copolymer binder may be that commercially available from American Dye Source, Inc. (Canada) under the trade-name Tuxedo® XAP02.

A preferred polymer binder is hydroxy propyl cellulose having a molecular weight between 5,000 and 30,000 Dalton, which is available from American Dye Source (Quebec, Canada). This polymeric binder can be used at a concentration between about 3 and about 10 weight percent.

Other polymeric binders include polymeric particles having a particle size between 60 and 300 nm, preferably between 150-200 nm. Preferred polymeric particles include those commercially available from Mylan Group (Travinh, Vietnam) under tradenames Poly®NP 150, Poly®NP 180, Poly®NP 200 and Poly®NP 250, which have particle sizes of 150, 180, 200 and 250 nm respectively. Such polymeric binders can be used at a concentration between about 10 and about 50 weight percent. The ideal chemical structure of the Poly®NP series of particles (wherein x and y are the number of repeating units and are 10 and 31, respectively) is:

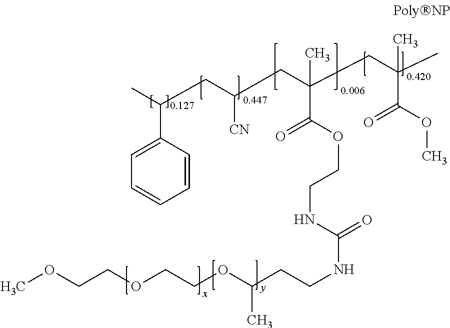

Radical polymerizable Copolymers

The imageable layer further comprises one or more a radical polymerizable copolymer. Those are copolymers, i.e. polymers comprising two or more different repeat units, wherein at least one type of repeat unit comprises pendant groups that include one or more radical polymerizable functional groups. Free radical polymerizable copolymers for use in negative-working printing plate precursors are well-known to the skilled person. Any such known copolymer can be used in the present invention. Generally, the radical polymerizable copolymers can be used at a concentration between about 5 and about 50 weight percent.

The radical polymerizable copolymers can be molecularly dispersed in the imageable layer or in the form of discrete particles, in particular particles having a particle size preferably between about 60 and about 250 nm. Particles that can coalesce when heated are preferred in NIR-sensitive precursor.

Examples of suitable known radical polymerizable copolymers include hydroxy-alkyl cellulose, acetal copolymers, acrylic acid copolymers, methacrylic acid copolymers, acrylamide copolymers, methacrylamide copolymers, acrylonitrile copolymers, substituted phenylimide copolymers, and alkylimide copolymers, said copolymers bearing radical polymerizable functional groups as pendant groups.

U.S. Pat. No. 8,323,867, which is incorporated by reference, provide examples of free radical polymerizable copolymers. More specifically, this patent describes copolymers comprising a functional group which can undergo radical and/or cationic polymerization. Such copolymers can be obtained from acrylonitrile, styrene, poly(ethylene glycol) acrylate, poly(ethylene glycol) methacrylate and methoxymethylmethacrylamide monomers.

Copolymers two or more of the following repeat units, at least one unit comprising a radical polymerizable functional group, can be used in the present invention:

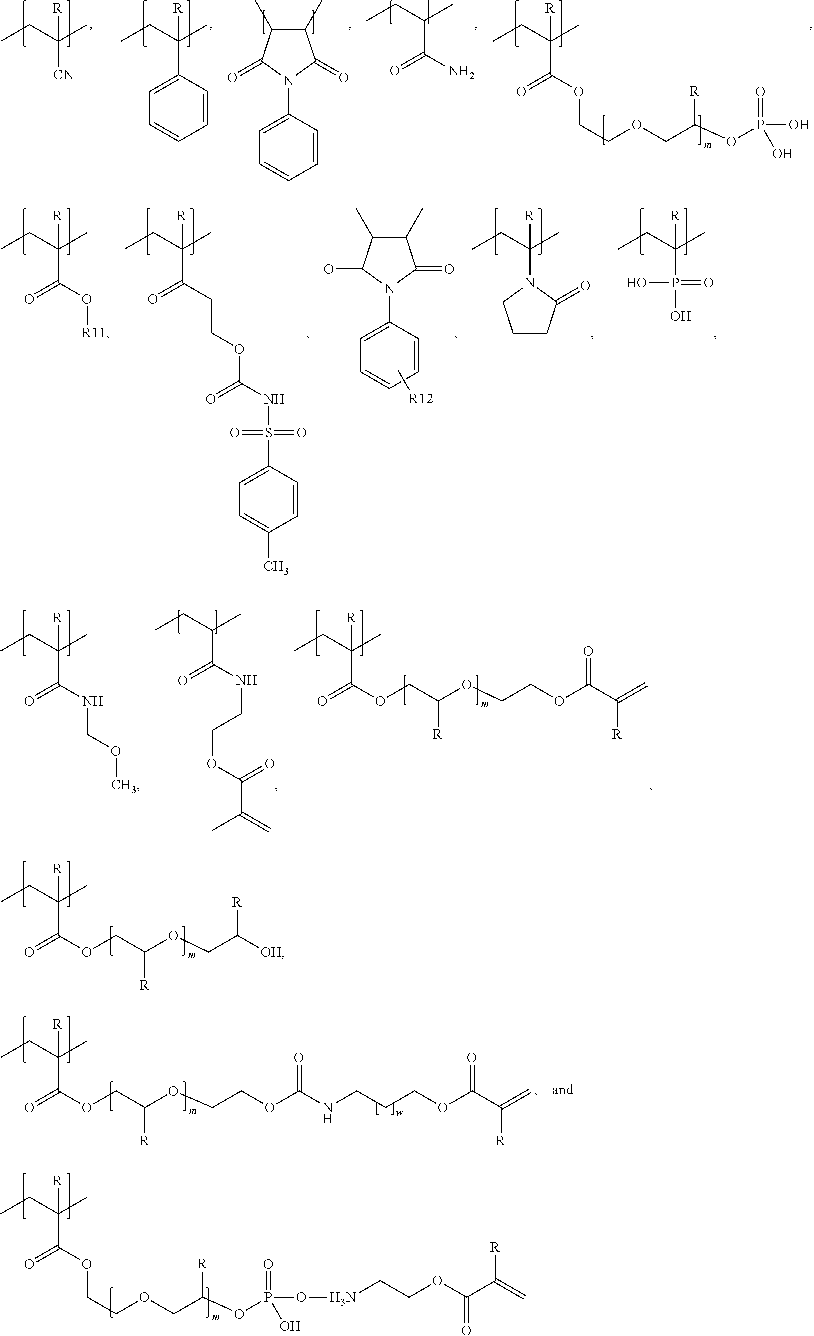

wherein:
m and w may vary between 0 and 50;
R is hydrogen or methyl;
R11 is H or linear and branched alkyl chain; and
R12 is alkyl, hydroxyl, or carboxylic acid.

The chemical structures of preferred radical polymerizable copolymers, which can be used at a concentration between about 5 and about 50 weight percent, and which are commercially available from Mylan Group (Travinh, Vietnam), are shown below:

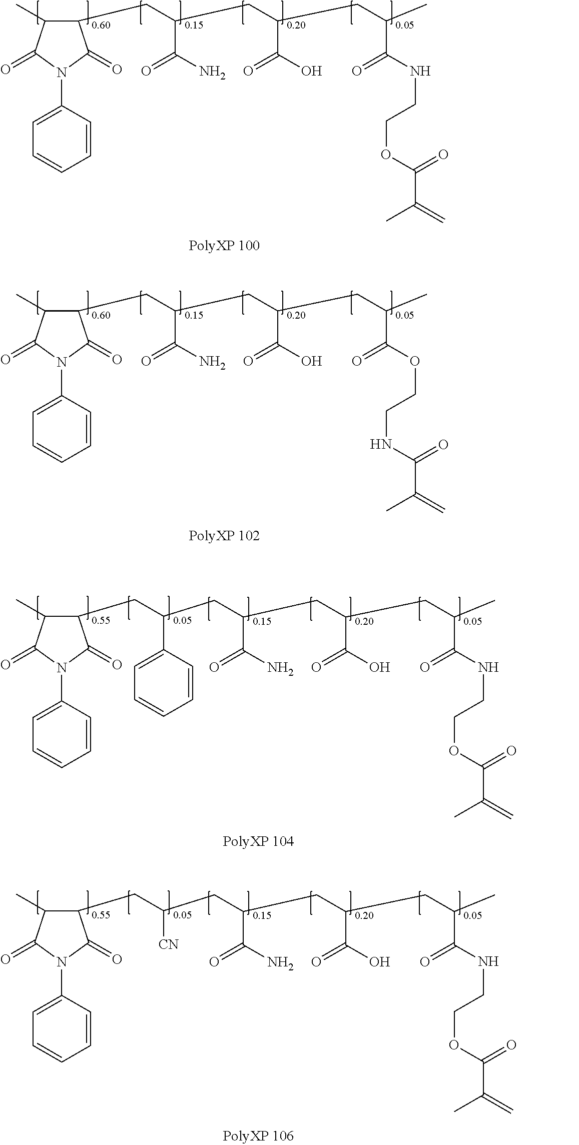

The chemical structures of preferred radical polymerizable copolymers in the form of nanoparticles (preferred for NIR sensitive precursors) are shown below. These can be used at a concentration between about 5 and about 50 weight percent. These are commercially available from Mylan Group (Travinh, Vietnam). (x and y are the number of repeating units and are 10 and 31, respectively.)

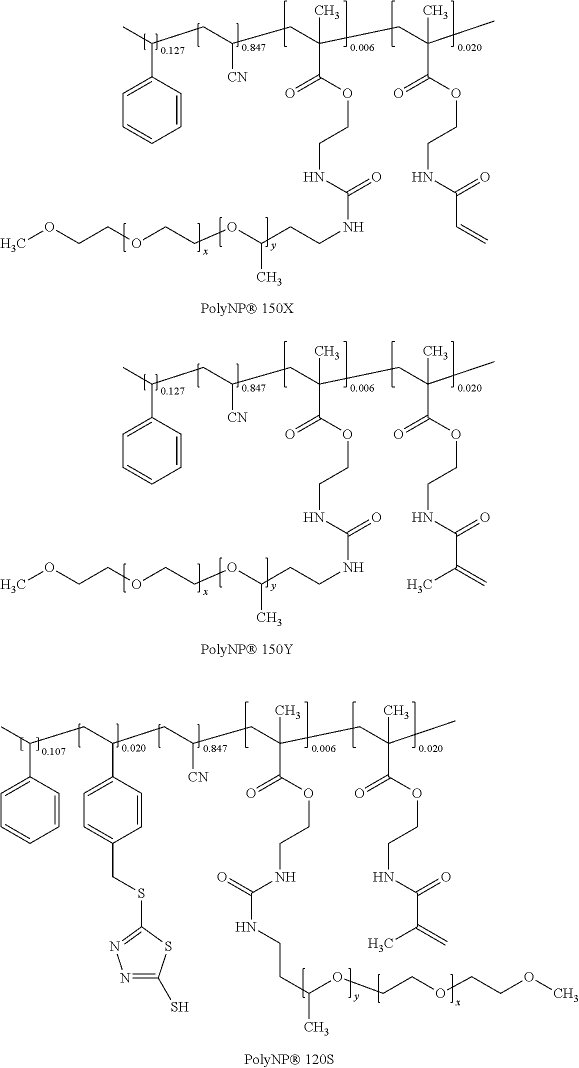

Radical polymerizable Oligomers

The imageable layer further comprises one or more radical polymerizable oligomers. These are small molecules comprising two or more radical polymerizable functional groups. There are generally in liquid form and as such can be responsible for the tackiness of the imageable layer.

Radical polymerizable oligomers for use in negative-working printing plate precursors are well-known to the skilled person. Any such known oligomer can be used in the present invention. Generally, the radical polymerizable oligomers can be used at a concentration between about 10 and about 50 weight percent.

Examples of suitable known radical polymerizable oligomers include those based on urethane, urea, ether, amide, ester compounds comprising multiple free radical polymerizable functional groups, preferably acrylate, methacrylate, vinyl ether, allyl ether, acrylamide, and methacrylamide.

US patent publication no. 2012/0137929, incorporated herein by reference, provides examples such radical polymerizable oligomers. In particular, it describes gallotannic compounds comprising gallotannin wherein at least one hydroxyl group is replaced by a substituent. Non-limiting examples of substituents include substituents comprising:
crosslinkers (i.e. is a molecule, an oligomer or a polymer that comprises a functional group capable of undergoing a crosslinking reaction via cationic or radical polymerization),
initiators,
adhesion promoters,
hydrogen bonding promoters,
chromophores,
binders,
any other molecule, oligomer, or polymer used in lithographic printing plate coatings,
gallotannin, and
another gallotannic compound.

Of course, several hydroxyl groups of gallotannin may be replaced to produce the gallotannic compound. There is no need that all the hydroxyl groups be replaced by the same type of substituents. There is no need that all the substituents of a particular type be the same.

The skilled person will appreciate that the substituents can be attached directly to the gallotannin. Alternatively, the substituent(s) is/are attached to the gallotannin through a linking group. In embodiments, the linking group may be alkyl optionally comprising one or more ester, ether, amine, amido, urea, carbamate, sulfonamide, or

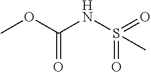

functional group (or any combination thereof). The alkyl may be linear, branched and/or cyclic. In other words, the alkyl may comprise linear parts, branched parts and cyclic parts at the same time. The alkyl group may have 1 to 50 carbon atoms. In the above, when it is said that the alkyl optionally comprises the listed functional groups, it means that the functional groups may be at end either of the alkyl or in between any two carbon atoms of the alkyl or its substituents. For more certainty, when more than one functional group is comprised in an alkyl, the functional groups do not need to be separated by carbons atoms of the alkyl; i.e. they may be directly attached to one another. For more certainty, herein an ether functional group is —O—; an ester functional group (or linker) is —(C═O)—O— or —O—(C═O)—; an amine functional group is —NR₃—, an amide (or amido) functional group (or linker) is —(C═O)—NR₃— or —NR₃—(C═O)—; an urea functional group is —NR₃—(C═O)—NR₃—; a sulfonamide functional group is —SO₂—NR₃— or —NR₃—SO₂—; and a carbamate functional group is —NR₃—(C═O)—O— or —O—(C═O)—NR₃—, R₃ being hydrogen or alkyl.

A most preferred oligomer it that synthesized by reacting 1 equivalent of gallotannic acid with 10 equivalent of 2-isocyanato ethylmethacrylate using dibutyl tin dilaurate catalyst in dioxolane solution at 50° C. according to Example 1 of the US patent publication no. 2012/0137929 (Nguyen et al.), which is incorporated herein by reference. This oligomer can be used at a concentration between about 5 and about 20 weight percent. The ideal chemical structure of this radical polymerizable gallotannic oligomer, which is commercially available from Mylan Group (Travinh, Vietnam) under tradename Tanmer 10X, is:

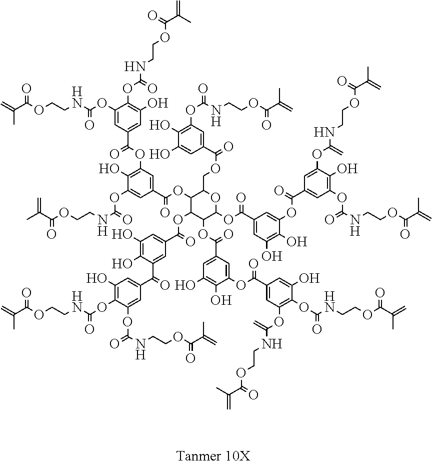 [SMILES: C=C(NCCOC(=O)C(=C)C)Oc1cc(C(=O)Oc2cc(C(=O)OC3OC(COC(=O)c4cc(O)c(O)c(OC(=O)NCCOC(=O)C(=C)C)c4)C(OC(=O)c4cc(OC(=O)NCCOC(=O)C(=C)C)c(O)c(OC(=O)c5cc(O)c(OC(=O)NCCOC(=O)C(=C)C)c(OC(=O)NCCOC(=O)C(=C)C)c5)c4)C(OC(=O)c4cc(O)c(O)c(C(=O)c5cc(O)c(OC(=O)NCCOC(=O)C(=C)C)c(OC(=O)NCCOC(=O)C(=C)C)c5)c4)C3OC(=O)c3cc(O)c(O)c(OC(=O)c4cc(O)c(OC(=O)NCCOC(=O)C(=C)C)c(OC(=C)NCCOC(=O)C(=C)C)c4)c3)cc(O)c2O)cc(OC(=O)NCCOC(=O)C(=C)C)c1O]

### Free Radical Photoinitiators

The photoinitiating system comprises one or more free radical photoinitiators.

The photoinitiator is sensitive (i.e. absorb), at least slightly, visible radiation. In both UV-violet and NIR-sensitive imageable layers of the invention, the photoinitiators will absorb visible light and produce the free radicals that are necessary for the crosslinking of the outer surface of the imageable layer.

When the imageable layer is UV-violet photopolymerizable, the photoinitiator also absorbs UV-violet (usually much more than it absorbs visible radiation during crosslinking of the outer layer). Therefore, during imaging with UV-violet-sensitive precursors, they will absorb UV-violet radiation and produce the free radicals that are necessary for imaging. Preferably, the free radical photoinitiators exhibit at least one strong absorption band in the UV-violet range so that they also act as photosensitizers during imaging with UV-violet radiation.

The photoinitiators play no significant role during imaging with NIR radiation. In NIR-sensitive precursors, the photosensitizer will provide the heat (and the fewer free radicals) necessary for imaging.

To produce a precursor that is both NIR and UV-violet photopolymerizable, a photoinitiator sensitive to both UV-violet and visible light can be used together with a photosensitizer sensitive to NIR-radiation. In such cases, the photoinitiator preferably also acts as a UV-violet sensitive photosensitizer, so that a separate UV-violet sensitive photosensitizer does not need to be added to the imageable layer. Of course, in such precursors, it is also possible to use a mixture of photoinitiators sensitive to various wavelength to obtain an imageable layer with the desired sensitivity.

Preferably, the free radical photoinitiators used in the present invention exhibit one or more absorption bands in the UV-violet range, with at least one of these bands trailing into the visible range of the electromagnetic spectrum or with a shoulder or one or more further minor bands in the visible range.

Such photoinitiators are well-known to the skilled person. Generally, these photoinitiators can be used at a concentration between about 0.5 to about 10 weight percent.

Examples of suitable free radical photoinitiators include triazine, thioxanthone, mercaptothioxanthone, cyanine, monomethine, coumarine, ketocoumarine, pyrromethene, and oxime ester photoinitiators, having maximum absorption bands between 300 and 450 nm.

Examples of triazine photoinitiators include those described in U.S. Pat. No. 5,496,903, incorporated herein by reference, which are of formula:

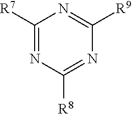

wherein R⁷, R⁸ and R⁹ each independently represent a trichloromethyl group, an optionally-substituted alkyl group having 1 to 10, preferably 1 to 4 carbon atoms, an aryl group having 6 to 15, preferably 6 to 10 carbon atoms, an aralkyl group having 7 to 25, preferably 7 to 14 carbon atoms, an alkoxy group having 1 to 10, preferably 1 to 4 carbon atoms, an alkenyl group having 2 to 15, preferably 2 to 10 carbon atoms, a piperidino group, a piperonyl group, an amino group, a dialkylamino group having 2 to 20, preferably 2 to 8 carbon atoms, a thiol group or an alkylthio group having 1 to 10, preferably 1 to 4 carbon atoms; with the proviso that at least one of R⁷ to R⁹ represents the trichloromethyl group.

Specific examples of these S-triazine include 2,4,6-tris(trichloromethyl)-S-triazine, 2-methyl-4,6-bis(trichloromethyl)-S-triazine, 2-methoxy-4,6-bis(trichloromethyl)-S-triazine, 2-phenyl-4,6-bis(trichloromethyl)-S-triazine, 2-(p-methoxyphenyl)-4,6-bis(trichloromethyl)-S-triazine, 2-(4-methylthiophenyl)-4,6-bis(trichloromethyl)-S-triazine, 2-(p-chlorophenyl)-4,6-bis(trichloromethyl)-S-triazine, 2-(4-methoxynaphthyl)-4,6-bis(trichloromethyl)-S-triazine, 2-piperonyl-4,6-bis(trichloromethyl)-S-triazine, 2-piperidino-4,6-bis(trichloromethyl)-S-triazine, 2-styryl-4,6-bis(trichloromethyl)-S-triazine, 2-(p-methoxystyryl)-4,6-bis(trichloromethyl)-S-triazine, 2-(3,4-dimethoxystyryl)-4,6-bis(trichloromethyl)-S-triazine, 2-(p-dimethylaminostyryl)-4,6-bis(trichloromethyl)-S-triazine and the like.

Preferred free radical photoinitiators are triazine photoinitiators, such as 2-(4′-methoxynaphthyl)-4,6-bis(trichloromethyl)-1,3,5-triazine (also called Triazine B), 2-(4′-ethoxynaphthyl)-4,6-bis(trichloromethyl)-1,3,5-triazine, and 2-(4′-ethoxystyryl)-4,6-bis(trichloromethyl)-1,3,5-triazine. These materials exhibit a strong absorption bands between 305 and 420 nm with a maximum absorption peak between 370 and 390 nm, which trails into the visible range of the electromagnetic spectrum. In fact, these compounds strongly absorb UV-violet laser radiation between 395 and 405 nm.

Other similar photoinitiators include those based on the polymers, copolymers, and oligomers described above. The photoinitiator can simply be attached to such polymers, copolymers, and oligomers. Alternatively, the polymers, copolymers, and oligomers can comprise supplementary repeat units having the photoinitiator as pendant group. Non-limiting examples polymers, copolymers, and oligomers are provided below. For conciseness, the whole description of these polymers, copolymers, and oligomers, already given above, is not repeated here.

Non-limiting examples of copolymers comprising a triazine pendant group include:

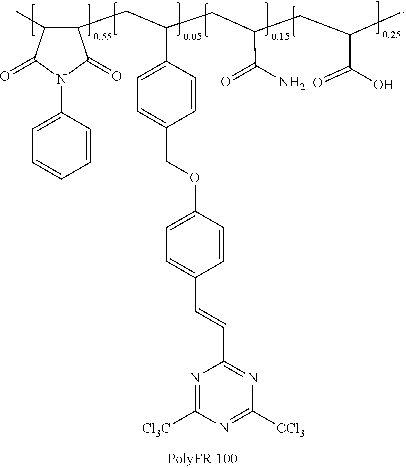

Non-limiting examples of copolymers comprising a triazine pendant group and a radical polymerizable functional group include:

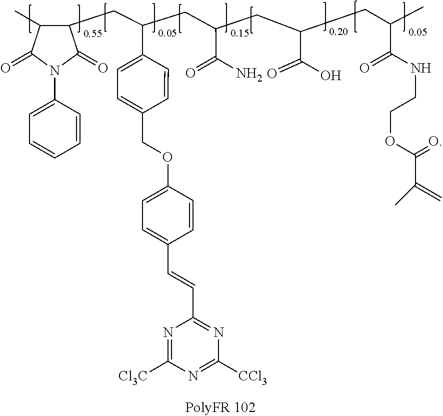

Non-limiting examples of polymeric nanoparticles comprising a triazine pendant group include the following, which is best used in NIR-sensitive precursors:

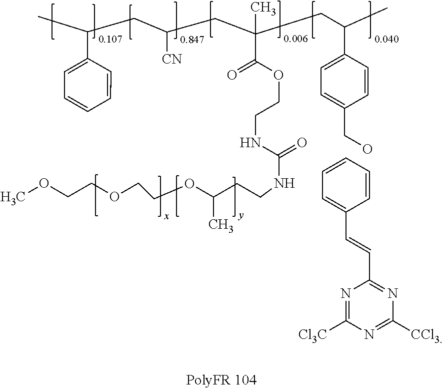

Non-limiting examples of radical polymerizable oligomers comprising a triazine pendant groups include:

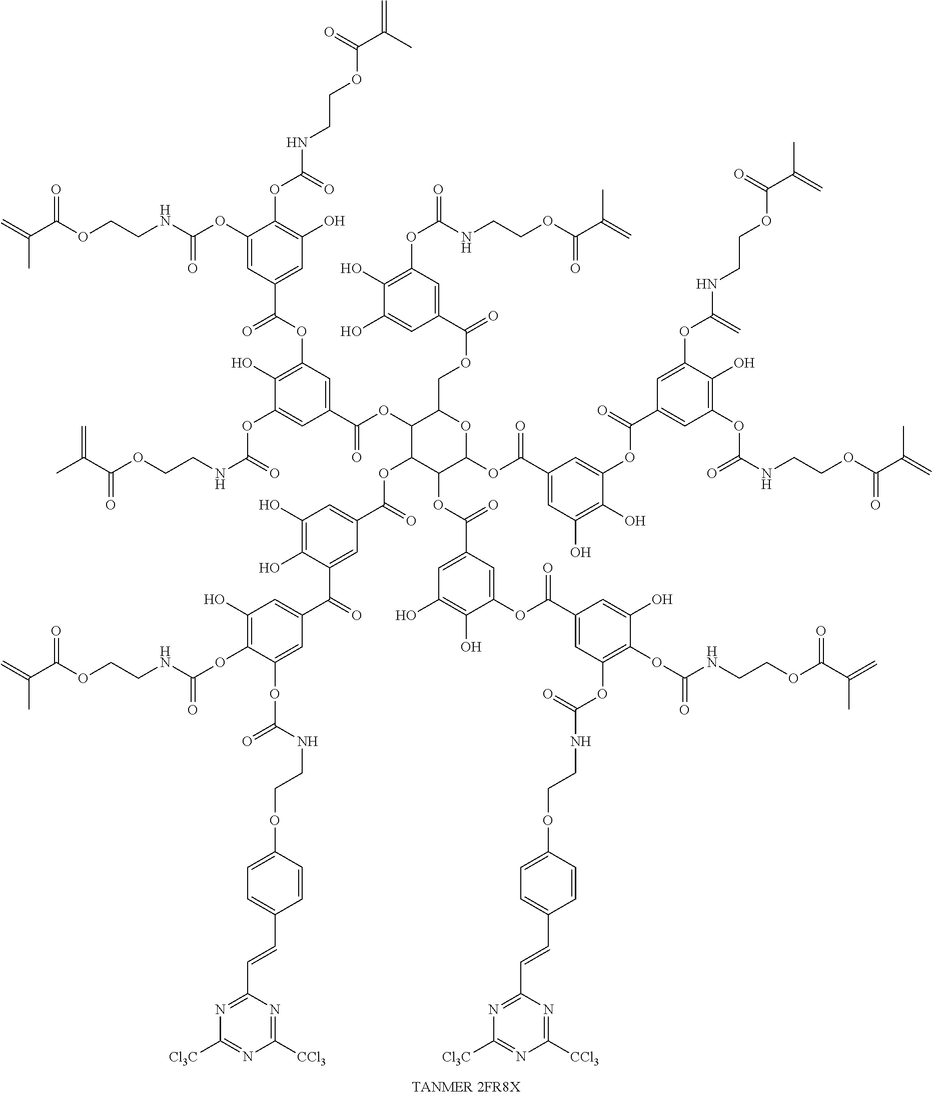

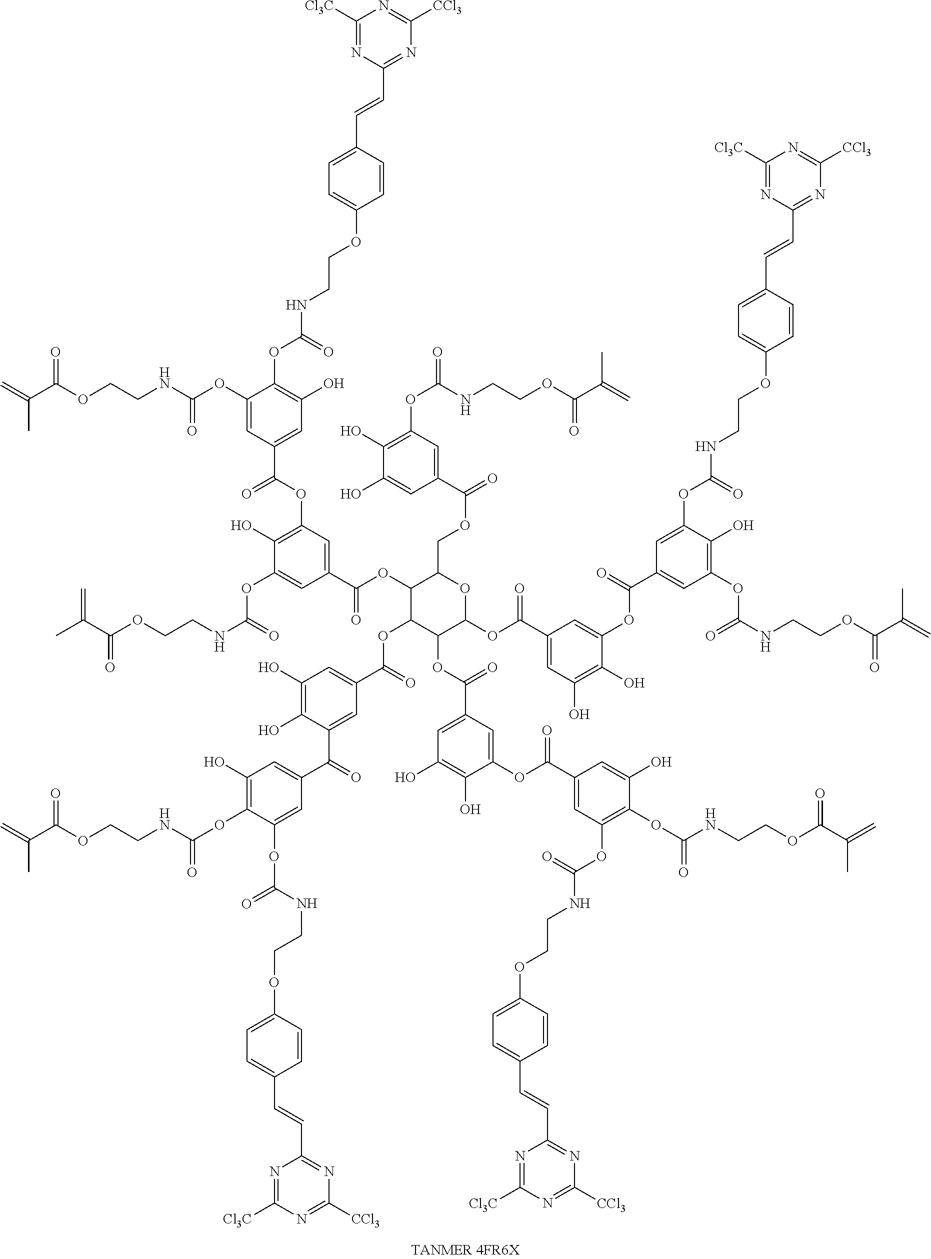

### Free Radical Coinitiators

The photoinitiating system comprises one or more free radical coinitiators. Such coinitiators are well-known to the skilled person. Any coinitiator typically used in negative working lithographic printing plate precursors can be used herein. Generally, the coinitiators can be used at a concentration between about 1 to about 30 weight percent.

Examples of typical coinitiators include aromatic ketones coinitiators, iodonium tetraphenyl borate salts coinitiators, and sulphonium tetraphenyl borate salts coinitiators.

U.S. Pat. No. 7,910,768, which is incorporated herein by reference, taught to prepare iodonium salts coinitiators, preferably iodonium tetraphenyl borate salts coinitiators. In particular, this patent describes iodonium salt comprising a positively charged iodine atom to which two aryl rings are attached, and a negatively charged counter ion. These iodonium salts comprise one or more functional groups that can undergo radical and/or cationic polymerization. More specifically, these iodonium salts may contain radical polymerizable groups, such as acrylate, methacrylate and vinyl ether. These radical polymerizable groups may be pendanted to the aryl rings of the salt via urethane and/or urea bonds. These salts may have the following general structures:

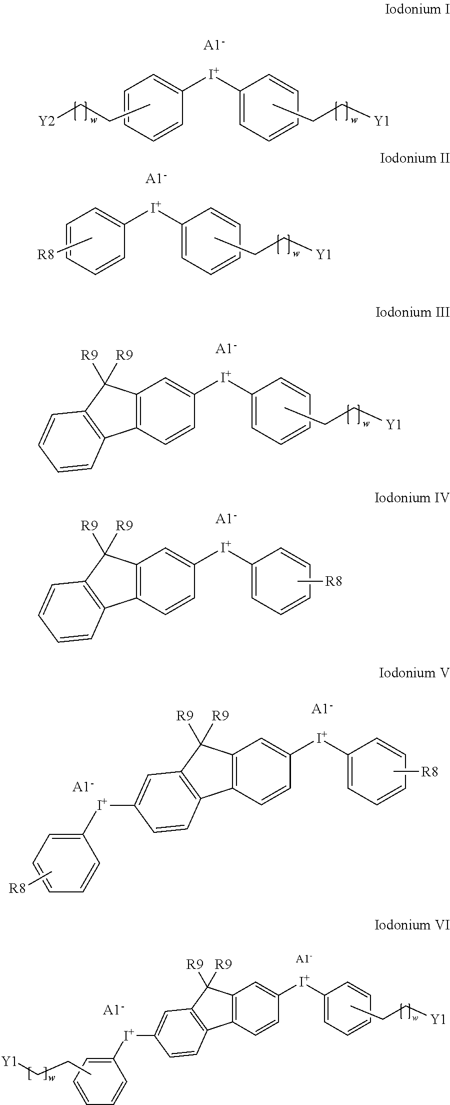

wherein:
A1 represents an anionic counter ion selected from tosylate, triflate, hexafluoroantimonate, tetrafluoroborate, tetraphenylborate and triphenyl-n-alkylborate;
w represents the number of repeat unit and may vary between 0 and 18;
R8 and R9 independently represent hydrogen, linear or branched C1-C18 alkyl, alkyl oxy, poly(ethylene oxide), poly(propylene oxide) and may comprise acrylate, methacrylate and vinyl ether terminated groups (In the case of Iodoniums IV and V, either R8, R9 or both R8 and R9 do comprise such acrylate, methacrylate and vinyl ether terminated groups); and
Y1 and Y2 independently represent urethane and/or urea containing compounds, which comprise single or multiple polymerizable functional groups, such as acrylate, methacrylate or vinyl ether.

Y1 and Y2 may have the following chemical structures:

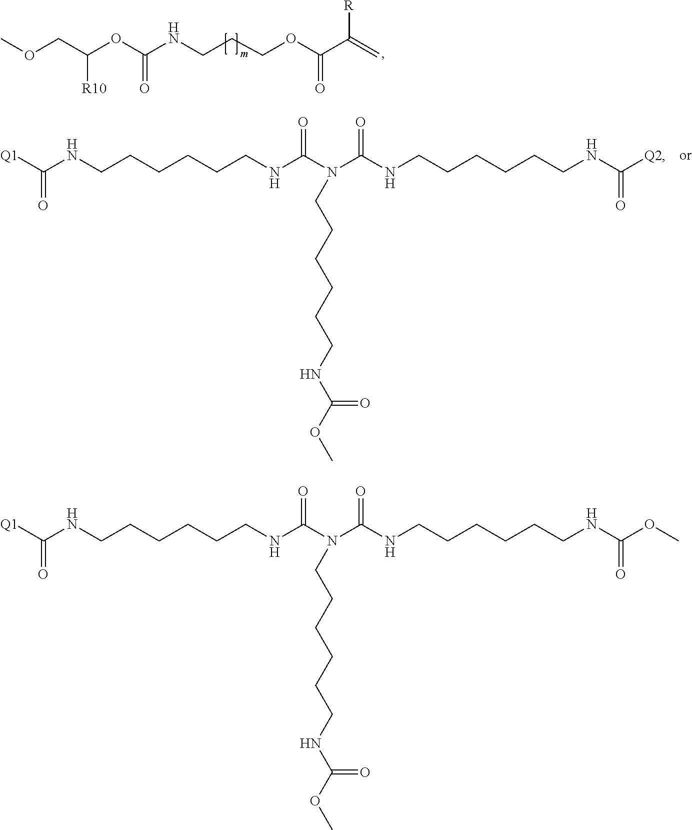

wherein:
m varies between 1 and 18,
R is hydrogen or methyl
R10 is hydrogen or a linear or branched C1-C18 alkyl chain; and
Q1 and Q2 independently represent an end compound comprising single or multiple polymerizable functional groups.

More specifically, Q1 and Q2 may independently have any of the following structures:

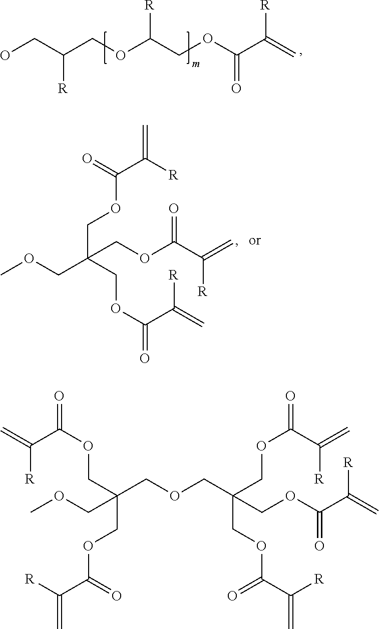

wherein R is hydrogen or methyl.

Preferred free radical coinitiators, that are also radical polymerizable oligomers, comprising iodonium tetraphenyl borate salts include the mixture of such materials commercially available from American Dye Source, Inc. (Quebec, Canada) under tradename Tuxedo® 06C051D. This mixture comprises:

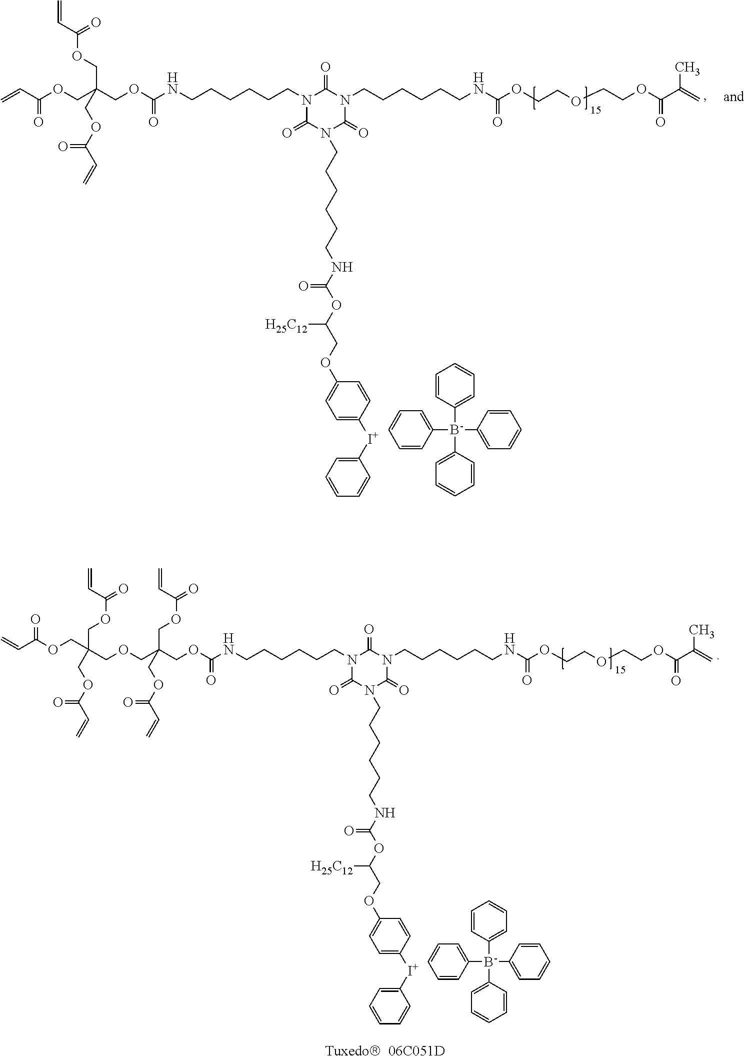

### Photosensitizers

The photoinitiating system comprises one or more photosensitizers.

As stated above, when imaging with UV-violet radiation, preferred photoinitiators also act as photosensitizers, so a separate photosensitizer is not required. Nevertheless, when needed, suitable photosensitizers for use in UV-violet-sensitive precursors are well-known to the skilled person and include triazine, thioxanthone, mercaptothioxanthone, cyanine, monomethine, coumarine, ketocoumarine, pyrromethene, and oxime ester photosensitizers, having maximum absorption bands between about 300 and about 450 nm.

When imaging with NIR lasers (emitting at a wavelength between 780 and 880 nm), the photoinitiating system comprises one or more photosensitizers having a strong absorption band between 780 and 880 nm (also called NIR dyes). Such photosensitizers are well-known to the skilled person. Any photosensitizer typically used in negative working lithographic printing plate precursors can be used herein. They can be used as is (as a small molecule) or attached for example to a radical polymerizable oligomer or radical polymerizable copolymer. Generally, the photosensitizers can be used at a concentration between about 1 and about 5 weight percent.

Examples of typical NIR photosensitizers include cyanine dyes, squaraine dyes, and arylimine dyes, in particular in the form of polymers comprising such dyes as pendant groups.

Preferred molecular NIR photosensitizers are the following, which are commercially available from American Dye Source, Inc. (Quebec, Canada):

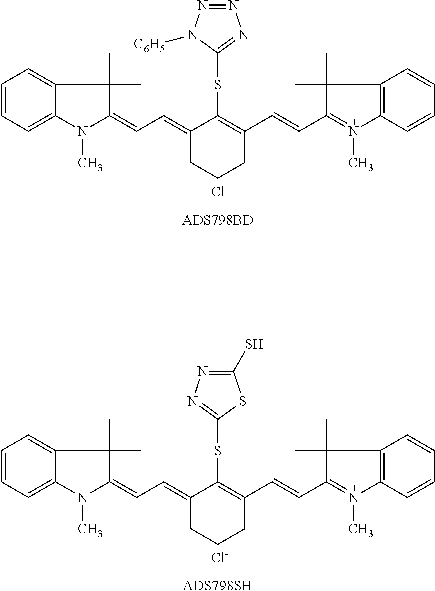

Preferred NIR photosensitizers, that are also radical polymerizable oligomers, include the following, which are commercially available from Mylan Group (Travinh, Vietnam):

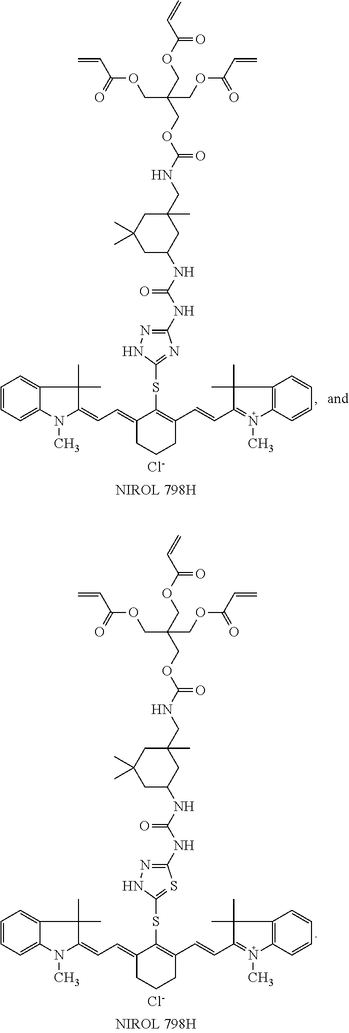

Suitable NIR photosensitizers, that are also radical polymerizable copolymers, include acetal copolymers comprising both NIR dyes and radical polymerizable functional groups as pendant groups; for example that described in U.S. Pat. No. 8,021,827 (Nguyen et al.), which is incorporated herein by reference. This patent describes NIR absorbing acetal copolymers that have a molecular weight greater than about 2,000 g/mol and are either be soluble in organic solvents or in aqueous solutions. Furthermore, they have the following general structure:

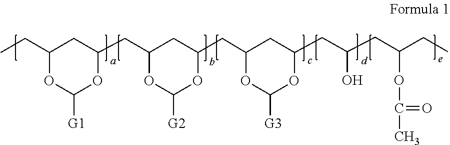

wherein:
G1 represents an optional processing segment that provides solubility in organic solvents such as alcohol, ketone, and ester;
G2 represents an optional thermal reactive segment;
G3 represents a radiation-absorbing segment that exhibits one or more strong absorption bands between 700 and 1100 nm. Optionally, this segment may also exhibit strong absorption bands between 400 and 700 nm;
a, b, c, d and e are molar ratios that can vary from 0.01 to 0.99; and
when the optional G1 and/or G2 segments are not present,

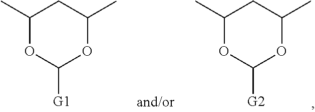

respectively are replaced by

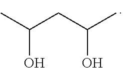

More specifically, the G1 processing segment may be a linear or branched alkyl or aryl compound containing cyano, hydroxy, dialkylamino, trialkylammonium salts, ethylene oxide, propylene oxide, methylbenzylsufonyl-carbamate or carboxylic acid and phosphoric acid functional groups.

The G2 thermal reactive segment may be a linear or branched alkyl or aryl compound and may contain a functional group capable of undergoing radical and/or cationic polymerization, such as acrylate, methacrylate, and vinyl ether. The G2 thermal reactive segment may have the following structures:

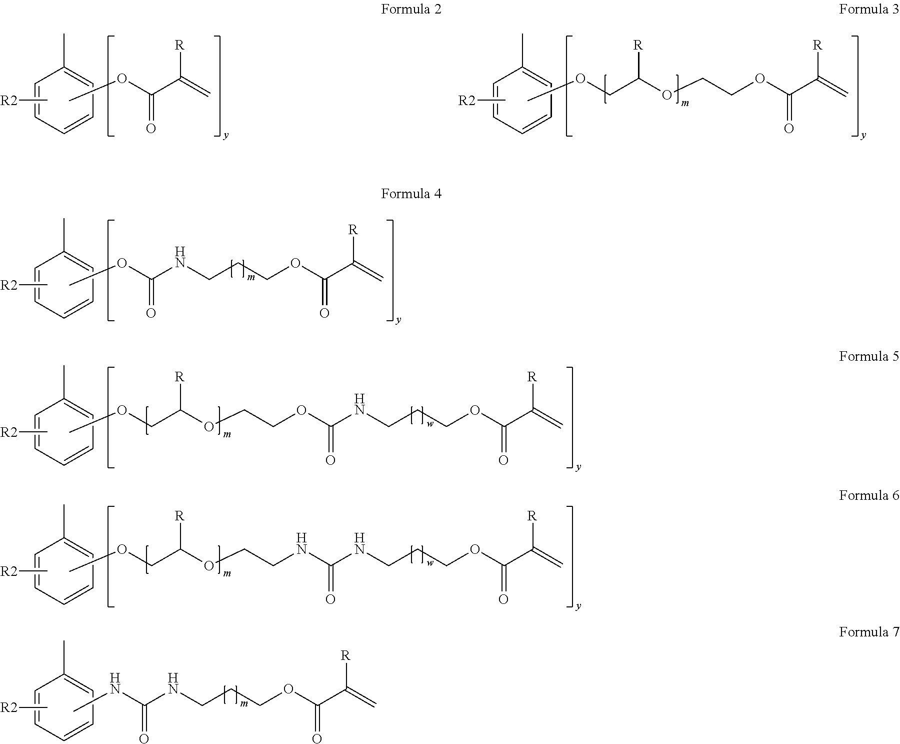

wherein:
R is hydrogen or methyl;
R2 is C1-C8 alkyl or alkoxy;
m and w represent the number of repeat and may vary between 0 and 50;
y is 1 or 2.

In another specific embodiment, the G2 segments may have pendant groups to those illustrated in formulas 2 to 7, but wherein the acrylate/methacrylate functional group is replaced by another radical polymerizable functional group.

The G3 segment may have the following structure:

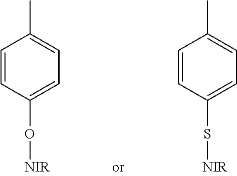

wherein NIR is a near-infrared absorbing chromophore (dye) that exhibits one or more strong absorption peaks between 700 and 1100 nm and may optionally exhibit one or more strong absorption peaks between 400 and 700 nm.

The acetal polymer may also comprise different G3 segments comprising different near-infrared absorbing chromophores.

The near-infrared absorbing chromophores (NIR dye) of these acetal polymers—and also of the present invention more generally—may be NIR absorbing organic compounds containing cyanine and/or arylimine functional groups. These chromophores may have the following structures:

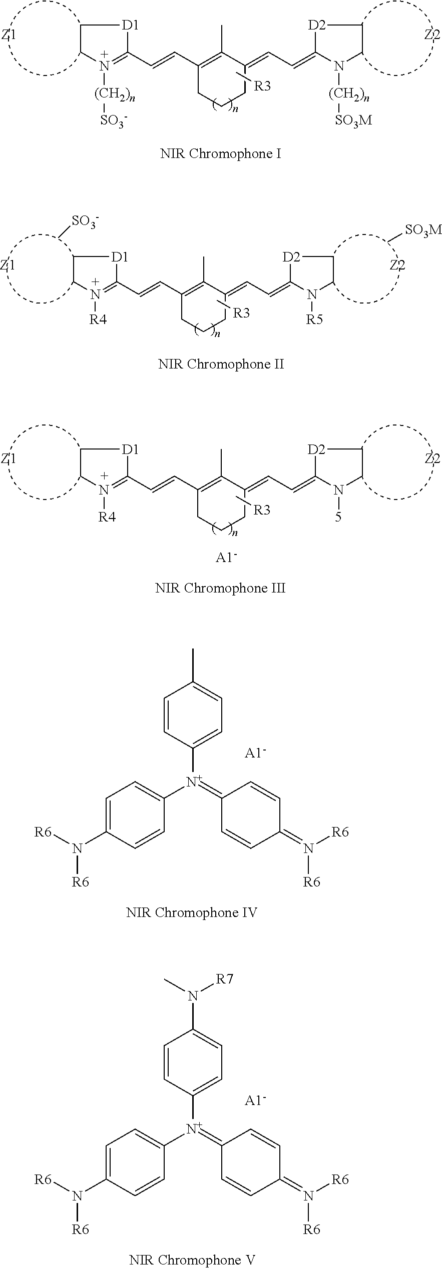

wherein:
D1 and D2 are identical or different and represent —O—, —S—, —Se—, —CH═CH—, and —C(CH₃)₂;
Z1 and Z2 are identical or different and represent one or more fused substituted or unsubstituted aromatic rings, such as phenyl and naphthyl;
h represents integer number from 2 to 8;
n represents 0 or 1;
M represents hydrogen or a cationic counter ion selected from Na, K, and tetraalkylammonium salts.
A1 represents an anionic counter ion selected from bromide, chloride, iodide, tosylate, triflate, trifluoromethane carbonate, dodecyl benzosylfonate and tetrafluoroborate, tetraphenylborate and triphenyl-n-butylborate.
R3 and R7 represent hydrogen or alkyl; and
R4, R5 and R6 are identical or different and represent alkyl, aryl alkyl, hydroxy alkyl, amino alkyl, carboxy alkyl, sulfo alkyl.

In a specific embodiment, R4, R5 and R6 may represent a polymerizable substituents having the following structure:

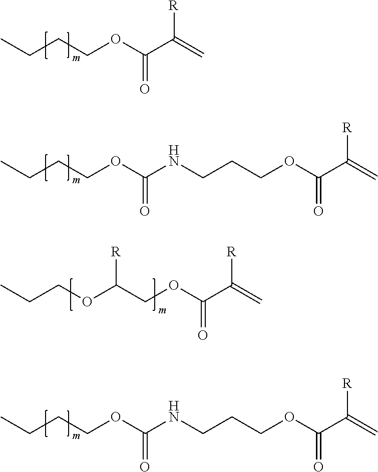

wherein:
m is a number of —CH₂— on the alkyl chain and may vary between 0 and 50; and
R is hydrogen or methyl.

The NIR absorbing acetal copolymers may be used in the coating of the present invention in quantities ranging from about 5 to 50% by solid weight.

Radical polymerizable NIR copolymers also include copolymeric nanoparticles comprising NIR chromophores as pendant group; in particular the particles described in U.S. Pat. No. 7,723,010 (Nguyen et al.), which is incorporated herein by reference. This patent describes polymeric particles having a particle size between about 60 nm and about 1000 nm and comprising a polymer. This polymer comprises (a) a hydrophobic backbone, (b) a NIR absorbing segment having attached thereto a NIR absorbing chromophore having an absorption peak between about 700 nm and about 1100 nm; and (c) a NIR transparent segment.

In embodiments, the polymeric particle may have a particle size between about 200 nm and 600 nm. Also, in embodiments, the polymer may have a molecular weight of about 3000 Dalton or more. In specific embodiments, the polymer may have the following structure:

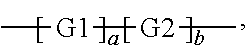

wherein:
G1 represents the absorbing segment;
G2 represents the transparent segment;
G1 and G2 form the hydrophobic backbone;
a and b independently represent molar ratios between 0.01 and 0.99; and
the chromophore is covalently or electrostatically attached to the hydrophobic backbone as a pendant group.

In embodiments, the absorbing segment may comprise:

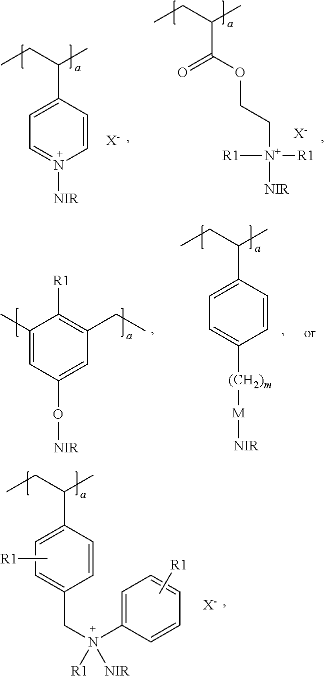

wherein:
NIR represents the chromophore;
R1 represents hydrogen or C1-C18 alkyl;
X represents a bromide, chloride, iodide, tosylate, triflate, trifluoromethane carbonate, dodecyl benzosulfonate, tetraphenylborate, alkyl-triphenylborate, tetrafluoroborate or hexafluoroantimonate anionic counter ion;
M represents oxygen, sulfur, or dialkylamino;
a represents a molar ratio between 0.01 and 0.99; and
m represents a number repeating units between 1 and 5.

In other embodiments, the absorbing segment may comprise a polyether linker covalently attaching the chromophore to the polymer backbone. More specifically, the absorbing segment may comprise:

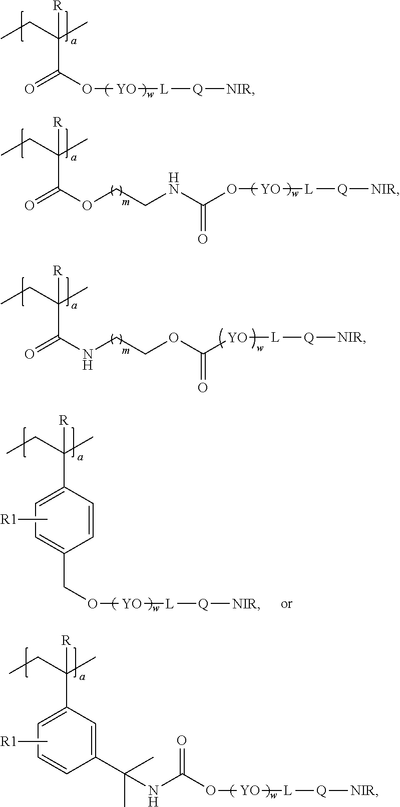

wherein:
a represents a molar ratio between 0.01 and 0.99;
R represents hydrogen or methyl;
R1 represents C1-C8 alkyl or C1-C8 alkyloxy;
w represents a number of repeating units between 10 and 50;
m represents a number of repeating units between 1 and 10;
Y represents a linear or branched C2-C4 alkyl;
Q represents a spacer group;
NIR represents the chromophore; and
L represents

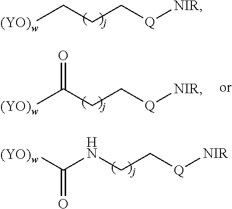

wherein the Q-NIR and the (YO)_{w} groups are indicated for clarity and j represents a number of repeating unit between 0 and 10.

In more specific embodiments, the spacer group may be:

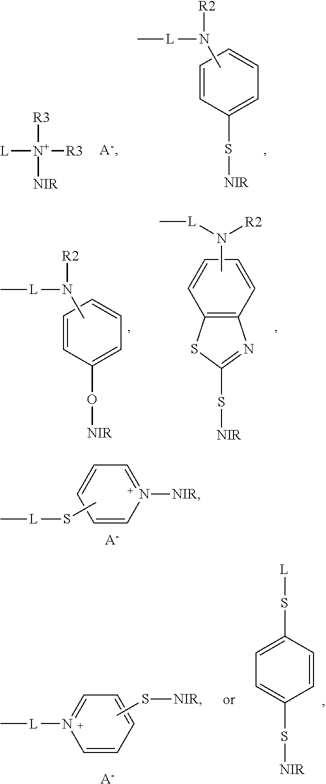

wherein the L and NIR groups are indicated for clarity, R2 represents C1-C8 alkyl or C1-C8 alkyloxy; R3 is the same as R2 or a phenyl ring substituted by H or R2; and A represents an anion. In embodiments, this anion may be bromide, chloride, iodide, tosylate, tetraphenylborate, alkyl triphenyl borate, tetrafluoro borate, or hexafluoroantimonate.

In specific embodiments, two polymer backbones of the polymer particles are cross-linked via two absorbing segments and one chromophore.

In embodiments of these polymeric particles—and of the present invention generally—, the NIR dye may be:

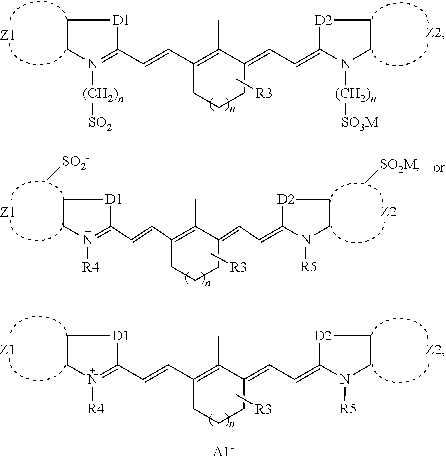

wherein:
D1 and D2 each independently represent —O—, —S—, —Se—, —CH═CH—, or —C(CH₃)₂;
Z1 and Z2 each independently represent one or more fused substituted or unsubstituted aromatic ring;
h represents an integer between 2 and 8;
n represents 0 or 1;
M represents hydrogen or a Na, K, or tetraalkylammonium salt cationic counter ion.
A1 represents a bromide, chloride, iodide, tosylate, triflate, trifluoromethane carbonate, dodecyl benzosylfonate, tetrafluoroborate, tetraphenylborate or triphenyl-n-butylborate anionic counter ion;
R3 represents hydrogen or alkyl; and
R4 and R5 each independently represent alkyl, aryl alkyl, hydroxy alkyl, amino alkyl, carboxy alkyl, sulfo alkyl, acetoxyl alkyl, polyether or a polymerizable substituent of formula:

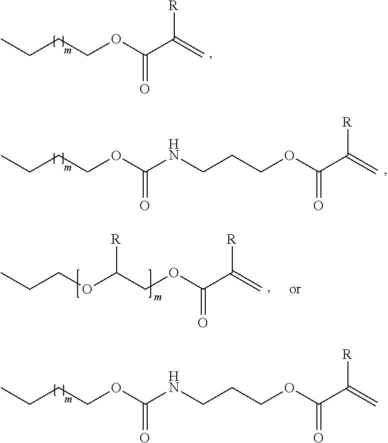

wherein m represents a number of repeating unit between 0 and 50 and R is hydrogen or methyl.

In embodiments, the transparent segment may comprise styrene, substituted styrene, alpha-methylstyrene, 4-vinylphenol, 3-vinylbenzaldehyde, acrylate ester, methacrylate ester, acrylonitrile, acrylamide, methacrylamide, vinyl halide, vinyl ester, vinyl ether, 9-vinylcarbazole, or vinyl phosphoric acid transparent monomeric units, and mixtures thereof.

In other embodiments, the transparent segment may comprise transparent monomeric units obtained by polymerizing polyether monomers of formula:

H₂C═C(R)—COO—(YO)_{w}—Y-T,

H₂C═C(R)—COO—CH₂CH₂—NHCO—O(CH₂CH₂O)_{W}—CH[CH₂—(OCH₂CH₂)_{W}—Y-T]₂,

or mixtures thereof, wherein:
R represents hydrogen or methyl;
Y represents C₂-C₄ alkyl;
w represents a number repeating unit between 5 and 50; and
T represents a hydroxy, alkoxy, aryloxy, carboxylic acid, sulfonic acid, or phosphoric acid terminating group and their salts.

In embodiments, the transparent segment may comprise:
poly(ethylene glycol) (meth)acrylate,
poly(propylene glycol) (meth)acrylate,
poly(ethylene glycol-block-propylene glycol) (meth)acrylate,
poly(ethylene glycol-block-caprolactone) (meth)acrylate,
poly(ethylene glycol) alkyl ether (meth)acrylate,
poly(propylene glycol) alkyl ether (meth)acrylate,
poly(ethylene glycol-block-propylene glycol) alkyl ether (meth)acrylate,
poly(ethylene glycol-block-caprolactone) alkyl ether (meth)acrylate transparent monomeric units, or mixtures thereof.

In embodiments, the transparent segment may comprise one or more transparent monomeric units obtained by polymerizing a monomer having two polymerizable functional groups, thereby crosslinking two polymer backbones via one transparent monomeric unit.

In more specific embodiments, the monomer having two polymerizable functional groups may be:
divinyl benzene,
poly(ethylene glycol) di(meth)acrylate,
poly(propylene glycol) di(meth)acrylate,
poly(ethylene glycol-ran-propylene glycol) di(meth)acrylate,
poly(propylene glycol)-block-polycaprolactone di(meth)acrylate,
poly(ethylene glycol)-block-polytetrahydrofuran di(meth)acrylate,
glycerol-ethoxylate-di(meth)acrylate,
glycerol ethoxylate di(meth)acrylate, or mixtures thereof.

Preferred NIR photosensitizers in the form of particles include those commercially available from Mylan Group (Travinh, Vietnam) under tradename PolyNP®795PD (180 nm in size):

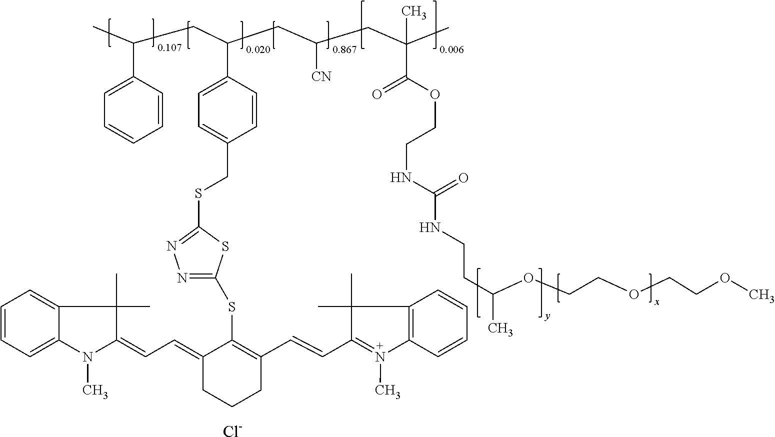

Other preferred NIR photosensitizers are radical polymerizable copolymers in the form of nanoparticles. An example of such preferred NIR photosensitizer are the following, which are commercially available from Mylan Group (Travinh, Vietnam):

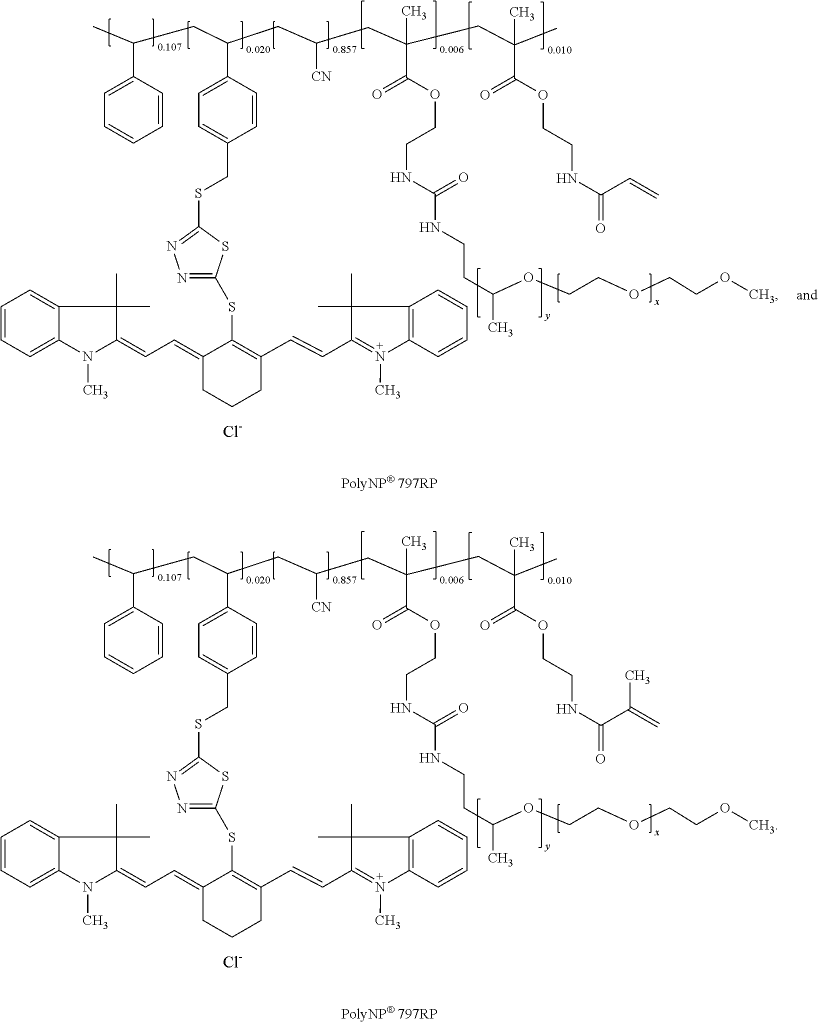

Other photosensitizers include the cyanine dyes described in U.S. Pat. No. 5,496,903, incorporated herein by reference, which are of formula

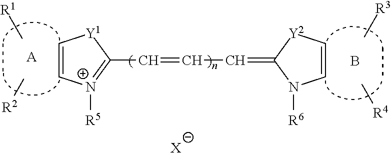

wherein ring A and ring B each independently represent a benzene ring or a naphthalene ring;
n is an integer of 2 to 5;
X— is Cl⁻, Br⁻, I⁻, ClO⁻, OH⁻, a carboxylate anion, a hydrogensulfate anion or an organoboron anion;
Y¹ and Y² each independently represent a sulfur atom, an oxygen atom, an ethylene group, a dimethylmethylene group or a selenium atom;
R¹ to R⁴ each independently represent a hydrogen atom, a chlorine atom, an alkyl group having 1 to 10, preferably 1 to 4 carbon atoms, a haloalkyl group having 1 to 10, preferably 1 to 4 carbon atoms, an ethylenyl group, a styryl group, an alkoxy group having 1 to 10, preferably 1 to 4 carbon atoms, a phenyl group, a naphthyl group, an alkylphenyl group having 7 to 16, preferably 7 to 10 carbon atoms, a hydroxyphenyl group, a halophenyl group, a nitrophenyl group, an aminophenyl group, a nitro group, an amino group or a hydroxyl group; and R⁵ and R⁶ each independently represent an alkyl group having 1 to 10, preferably 1 to 4 carbon atoms.

Specific examples of these cyanine dye include 3,3′-diethyl-2,2′-thiadicarbocyanine iodide, 3,3′-diethyl-2,2′-thiatricarbocyanine iodide, 3,3′-diethyl-2,2′-thiatricarbocyanine bromide, 3,3′-diethyl-6,6′-dimethoxy-2,2′-thiatricarbocyanine iodide, 3,3′-diethyl-5,5′,6,6′-tetramethyl-2,2′-thiatricarbocyanine iodide, 3,3′-diethyl-2,2′-oxatricarbocyanine iodide, 3,3′-diethyl-2,2′-thiadicarbocyanine bromide, 3,3′-diethyl-2,2′-thiatetracarbocyanine iodide, 3,3′-diethyl-2,2′-thiapentacarbocyanine iodide, 3,3′-dibutyl-2,2′-thiatricarbocyanine iodide, 3,3′-diethyl-2,2′-(4,5,4′,5′-dibenzo)thiadicarbocyanine iodide, 3,3′-diethyl-2,2′-(4,5,4′,5′-dibenzo)thiatricarbocyanine iodide, 3,3′-diethyl-2,2′-oxadicarbocyanine iodide, 3,3′-diethyl-2,2′-oxatricarbocyanine iodide, 1,3,3,1′,3′,3′-hexamethylindotricarbocyanine iodide, 1,3,3,1′,3′,3′-hexamethylindotricarbocyanine perchlorate, 1,3,3,1′,3′,3′-hexamethyl-2,2′-(4,5,4′,5′-dibenzo)indotricarbocyanineindoh e xacarbocyanine iodide and the like.

### Free Radical Scavengers

The photoinitiating system further comprises one or more free radical scavengers. Generally, the free radical scavengers can be used at a concentration between about 1 and about 5 weight percent.

Commonly used free radical scavengers are organic compounds comprising thiol functional group, such as 1H-1,2,4-triazole-3-thiol, 3-amino-1,2,4-triazole-5-thiol, 4-methyl-4H-1,2,4-triazole-3-thiol, 3-phenyl-1,2,4-triazole-5-thiol, 3-(1,1-dimethylethyl)-1,2,4-triazole-5-thiol, 5-amino-1,3,4-thiadiazole-2-thiol, 1,3,4-thiadiazole-2,5-dithiol, and 1,3,5-triazine-2,4,6-trithiol. These and other commonly known free radical scavengers can be used here. However, these molecules have disadvantages: they can sublimate when the precursor is oven dried (during production) and can surface bloom during storage, which causes pinholes after laser imaging and development with aqueous developers.

Therefore, there is provided herein free radical scavengers. These are oligomers, polymers, dendrimers comprising thiol groups (—SH) as well as radical polymerizable functional groups.

Further, the present inventor's made the surprising discovery that when such free radical scavengers additionally comprise carboxylic acid groups (—COOH), they are even more efficient scavenger. In fact, such scavengers allow producing imageable layer exhibiting faster imaging speeds and excellent adhesion of the imaged area to the aluminum substrate.

These free radical scavengers can be of formula:

(Pₘ-L)ₙ-T_{q}, (FORMULA 1)

wherein:
P is a radical polymerizable functional group or a substituent formed by joining two or more radical polymerizable functional groups together, for example 1 to 5 such groups,
L is a linker having a valence equal to m+q;
T is a thiol group, or a substituent comprising a thiol group and optionally further comprising a carboxylic acid group, wherein said substituent has a valence equal to n;
m is an integer between 1 to 5, preferably 1 or 2,
n is an integer between 1 to 5, preferably 1 or 2, and
q is an integer between 1 to 5, preferably 1 or 2.

Preferred such formulas include:
P-L-T (the linker is bivalent and attached to one P group and one T group),
Pₘ-L-T (the linker is multivalent and attached one T group and to m, preferably two, P groups, which can be the same or different from one another,
P-L-T_{q} (the linker is multivalent and attached to one P group and q, preferably two, T groups, which can be the same or different from one another, and
(P-L)ₙ-T (the T group is multivalent and attached to n, preferably two, P-L moieties, which can be the same or different from one another).

In preferred embodiments, P is:
—X,
—C—(CH₂—X)₃, or
—C(CH₂—X)₂(CH₂—O—CH₂—C—(CH₂—X)₃),
   in which X is a radical polymerizable functional group, preferably

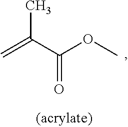

methacrylate, acrylamide, methacrylamide, alkylacrylate, alkylmethacrylate, alkylacrylamide, alkylmethacrylamide, vinyl ether, allyl, or styryl.

In most preferred embodiment, P is:

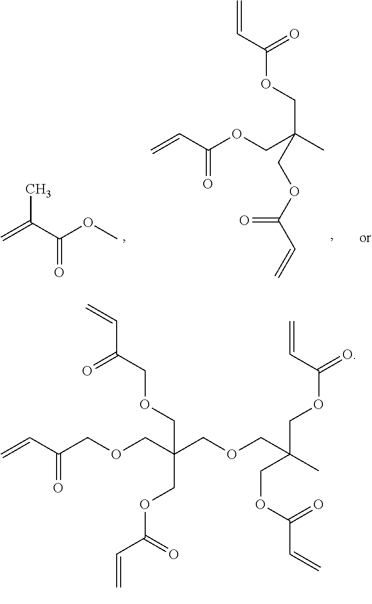

In preferred embodiments, T is:

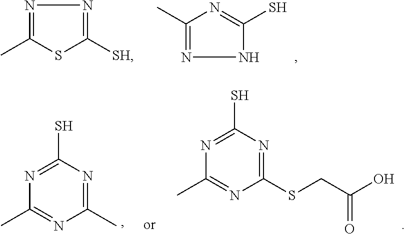

In preferred embodiments, L is a (linear, branched, or alicyclic) alkylene (bivalent) or alkylyne (trivalent) group comprising one or more following functional groups:
—NH—C(═O)—S—,
—S—C(═O)—NH—
—NH—C(═O)—NH—,
—NH—C(═O)—O—,
—O—C(═O)—NH—,
—S—,

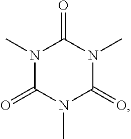

—NH—C(═O)—, and
—C(═O)—NH—.
   These functional groups being located at either or both ends of the alkylene/alkylyne group and/or in between two carbon atoms of the alkylene/alkylyne group.

Non-limiting examples of linkers include:

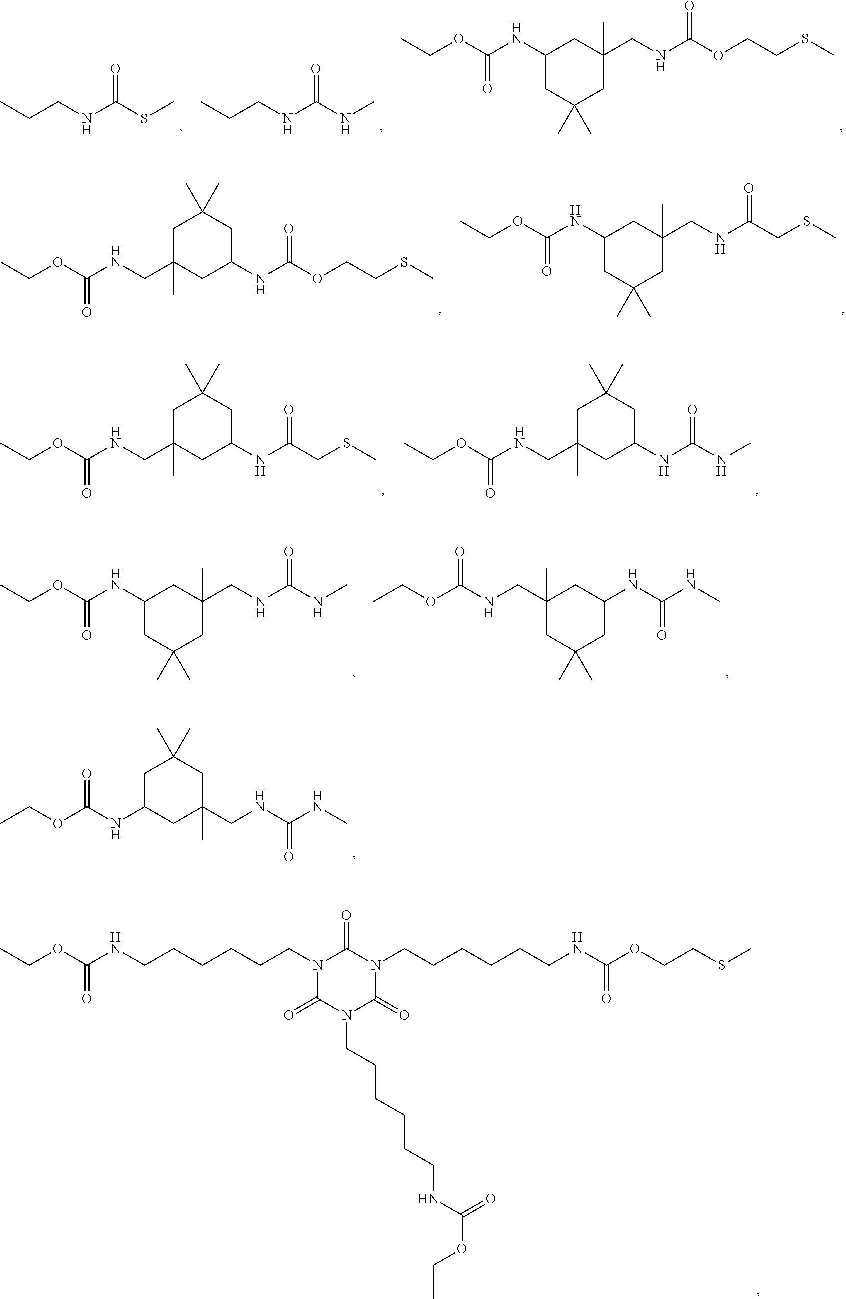

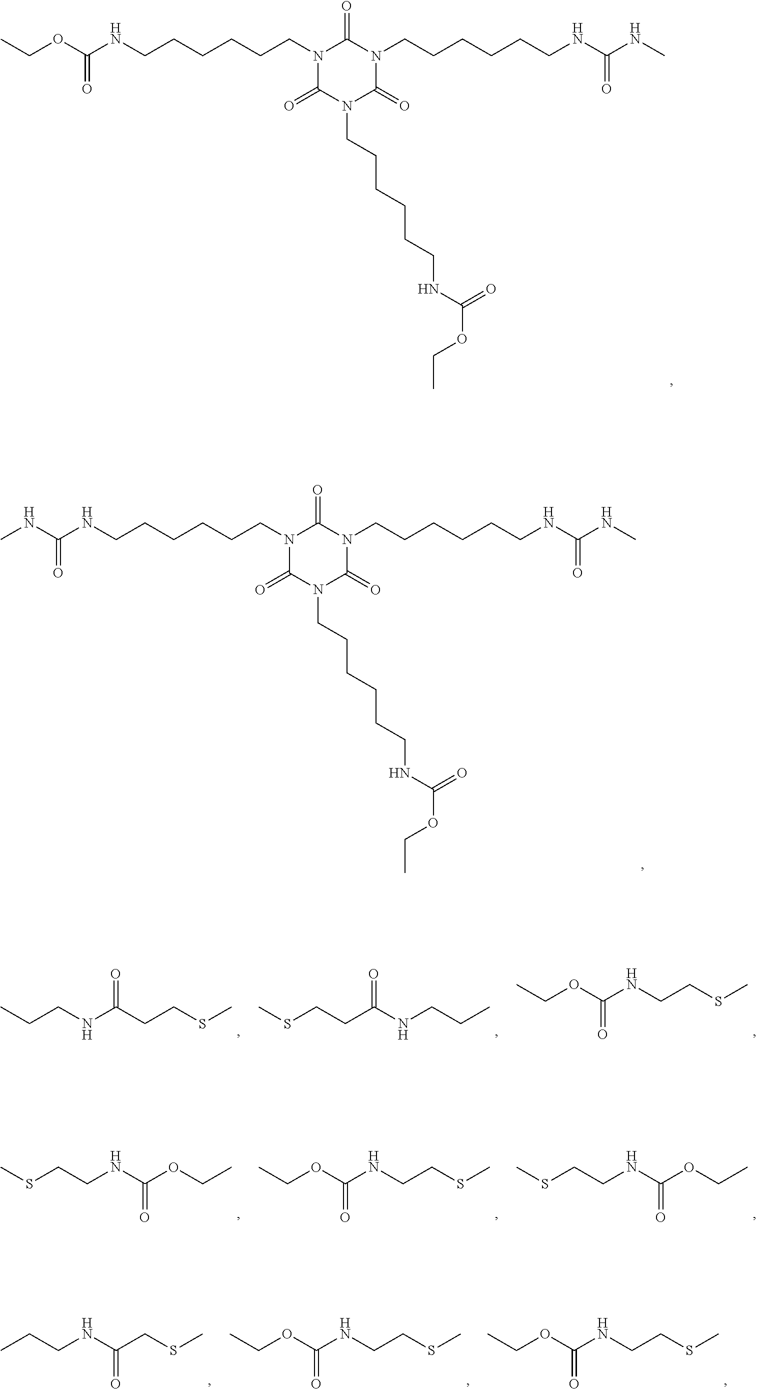

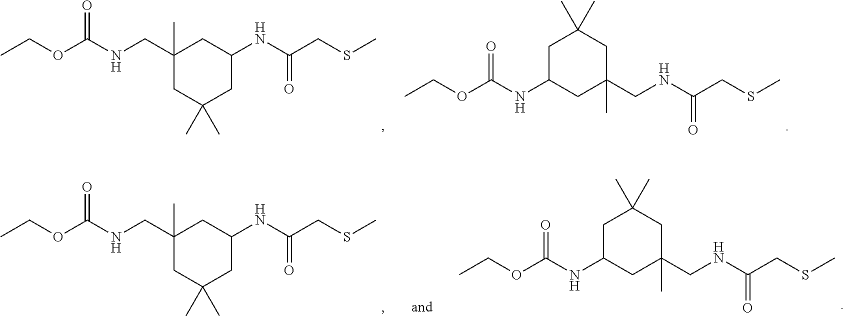 [SMILES: CCOC(=O)NCC1(C)CC(NC(=O)CSC)CC(C)(C)C1 ; CCOC(=O)NC1CC(C)(C)CC(C)(CNC(=O)CSC)C1 ; CCOC(=O)NCC1(C)CC(NC(=O)CSC)CC(C)(C)C1 ; CCOC(=O)NC1CC(C)(C)CC(C)(CNC(=O)CSC)C1]

Exemplary chemical structures of preferred free radical scavengers include:

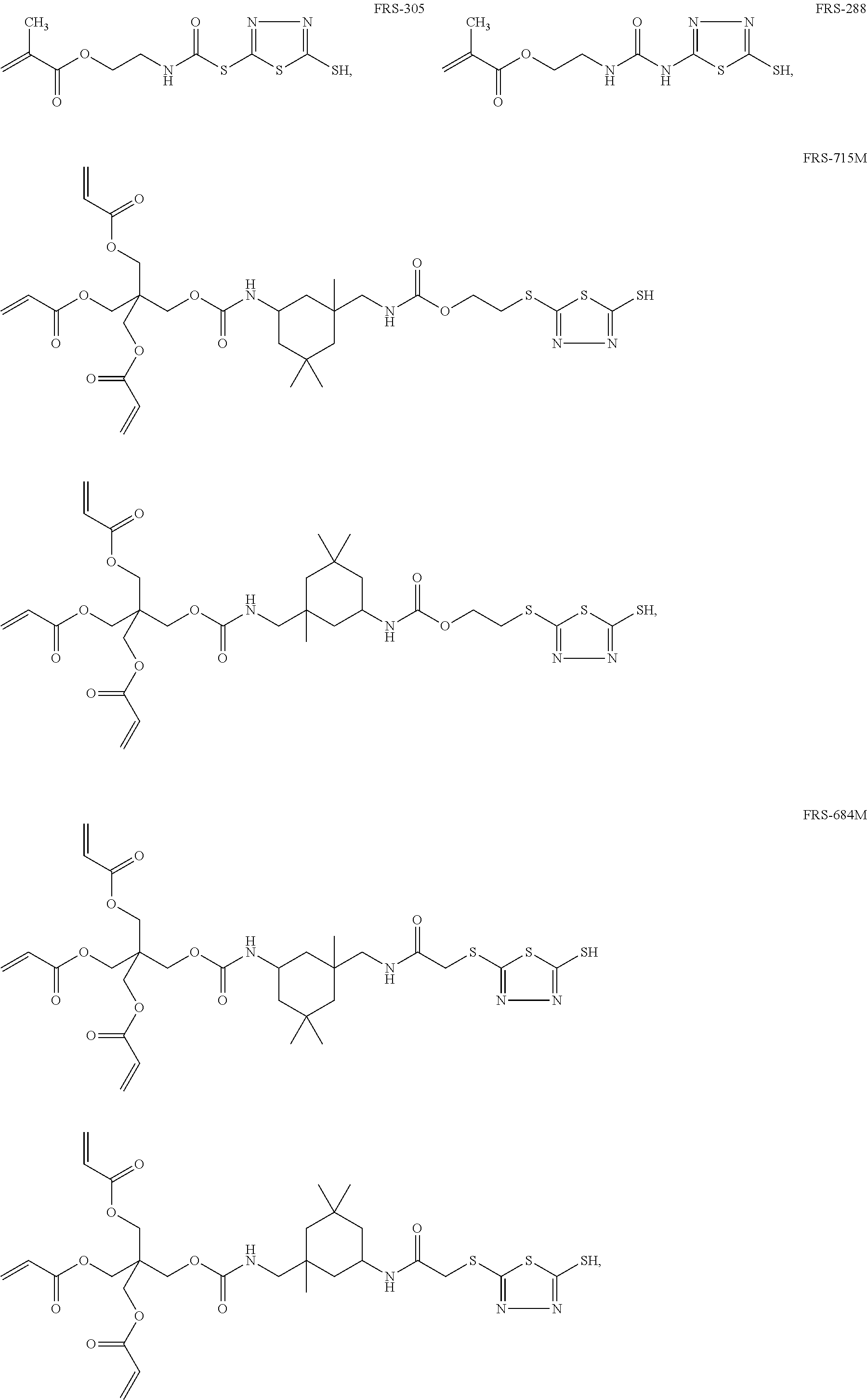 [SMILES: C=C(C)C(=O)OCCNC(=O)Sc1nnc(S)s1 ; C=C(C)C(=O)OCCNC(=O)Nc1nnc(S)s1 ; C=CC(=O)OCC(COC(=O)C=C)(COC(=O)C=C)COC(=O)NC1CC(C)(C)CC(C)(CNC(=O)OCCSc2nnc(S)s2)C1 ; C=CC(=O)OCC(COC(=O)C=C)(COC(=O)C=C)COC(=O)NCC1(C)CC(NC(=O)OCCSc2nnc(S)s2)CC(C)(C)C1 ; C=CC(=O)OCC(COC(=O)C=C)(COC(=O)C=C)COC(=O)NC1CC(C)(C)CC(C)(CNC(=O)CSc2nnc(S)s2)C1 ; C=CC(=O)OCC(COC(=O)C=C)(COC(=O)C=C)COC(=O)NCC1(C)CC(NC(=O)CSc2nnc(S)s2)CC(C)(C)C1]

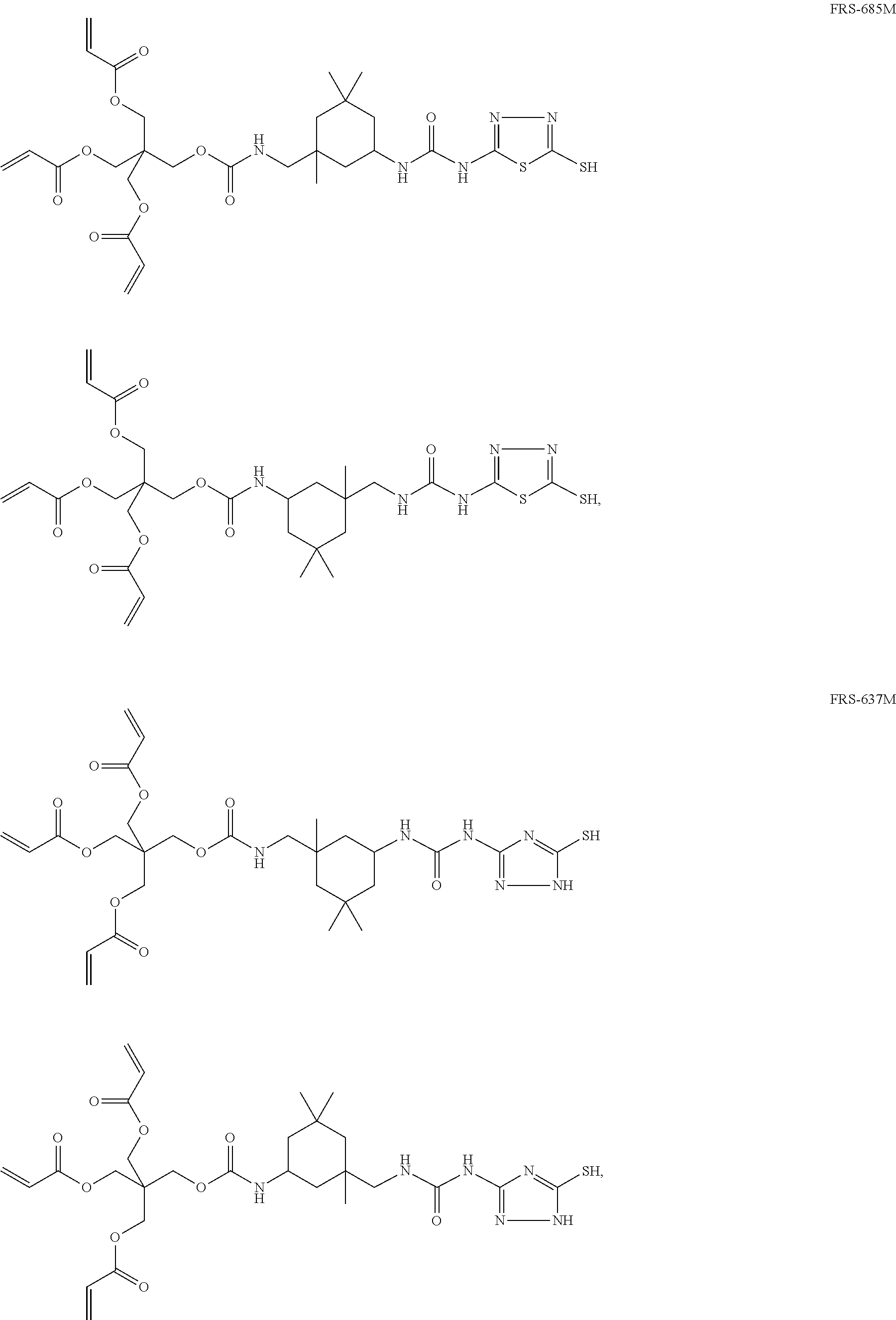 [SMILES: C=CC(=O)OCC(COC(=O)C=C)(COC(=O)C=C)COC(=O)NCC1(C)CC(NC(=O)Nc2nnc(S)s2)CC(C)(C)C1 ; C=CC(=O)OCC(COC(=O)C=C)(COC(=O)C=C)COC(=O)NC1CC(C)(C)CC(C)(CNC(=O)Nc2nnc(S)s2)C1 ; C=CC(=O)OCC(COC(=O)C=C)(COC(=O)C=C)COC(=O)NCC1(C)CC(NC(=O)Nc2n[nH]c(S)n2)CC(C)(C)C1 ; C=CC(=O)OCC(COC(=O)C=C)(COC(=O)C=C)COC(=O)NC1CC(C)(C)CC(C)(CNC(=O)Nc2n[nH]c(S)n2)C1]

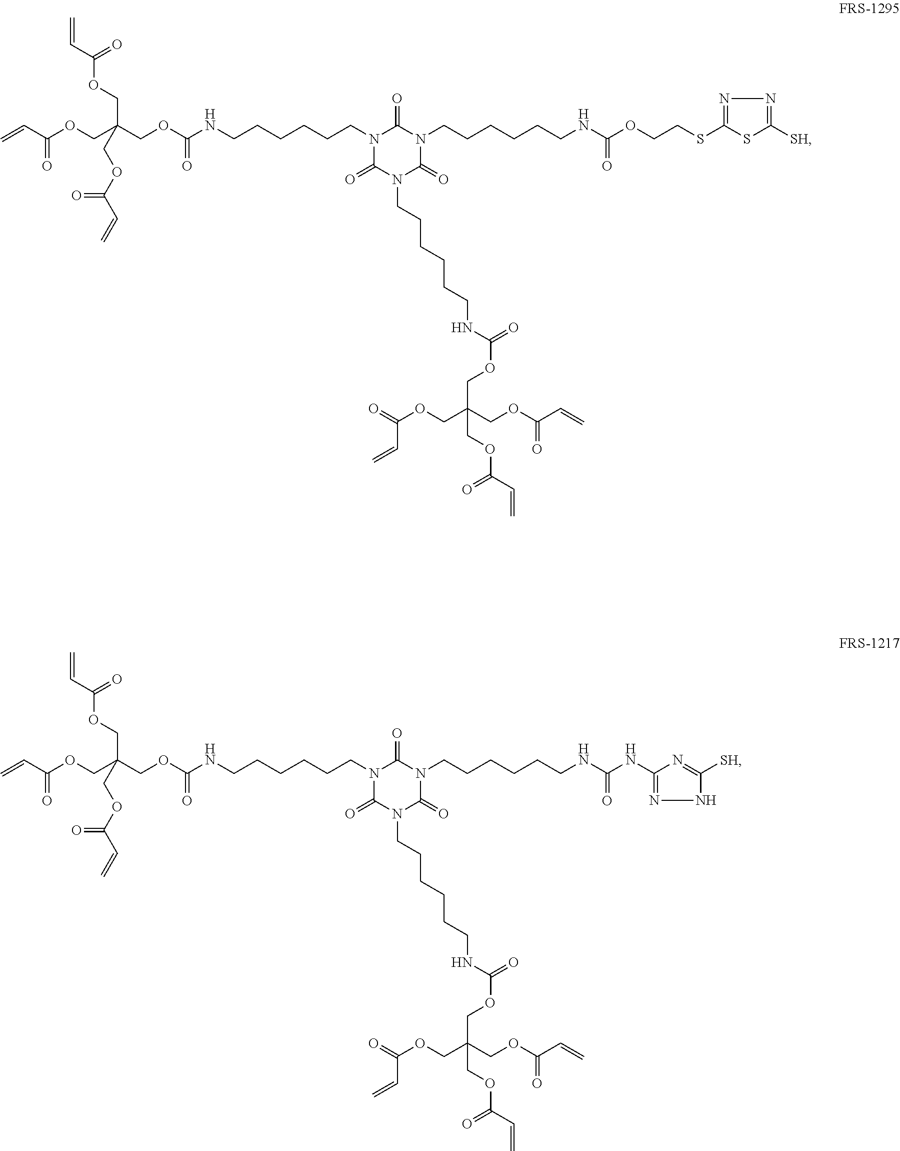 [SMILES: C=CC(=O)OCC(COC(=O)C=C)(COC(=O)C=C)COC(=O)NCCCCCCn1c(=O)n(CCCCCCNC(=O)OCCSc2nnc(S)s2)c(=O)n(CCCCCCNC(=O)OCC(COC(=O)C=C)(COC(=O)C=C)COC(=O)C=C)c1=O ; C=CC(=O)OCC(COC(=O)C=C)(COC(=O)C=C)COC(=O)NCCCCCCn1c(=O)n(CCCCCCNC(=O)Nc2n[nH]c(S)n2)c(=O)n(CCCCCCNC(=O)OCC(COC(=O)C=C)(COC(=O)C=C)COC(=O)C=C)c1=O]

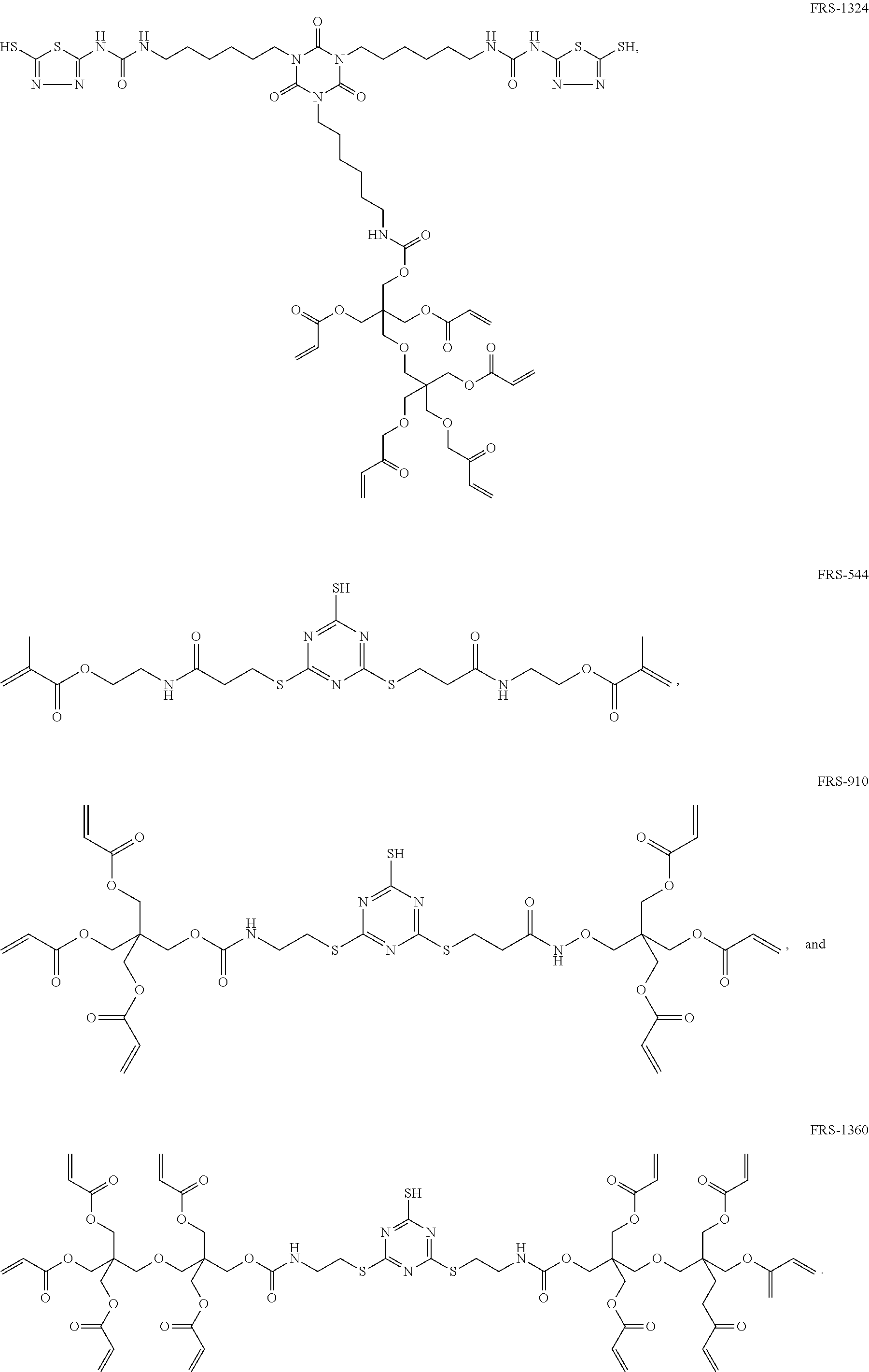

Exemplary chemical structures of preferred free radical scavengers comprising carboxylic acid groups include:

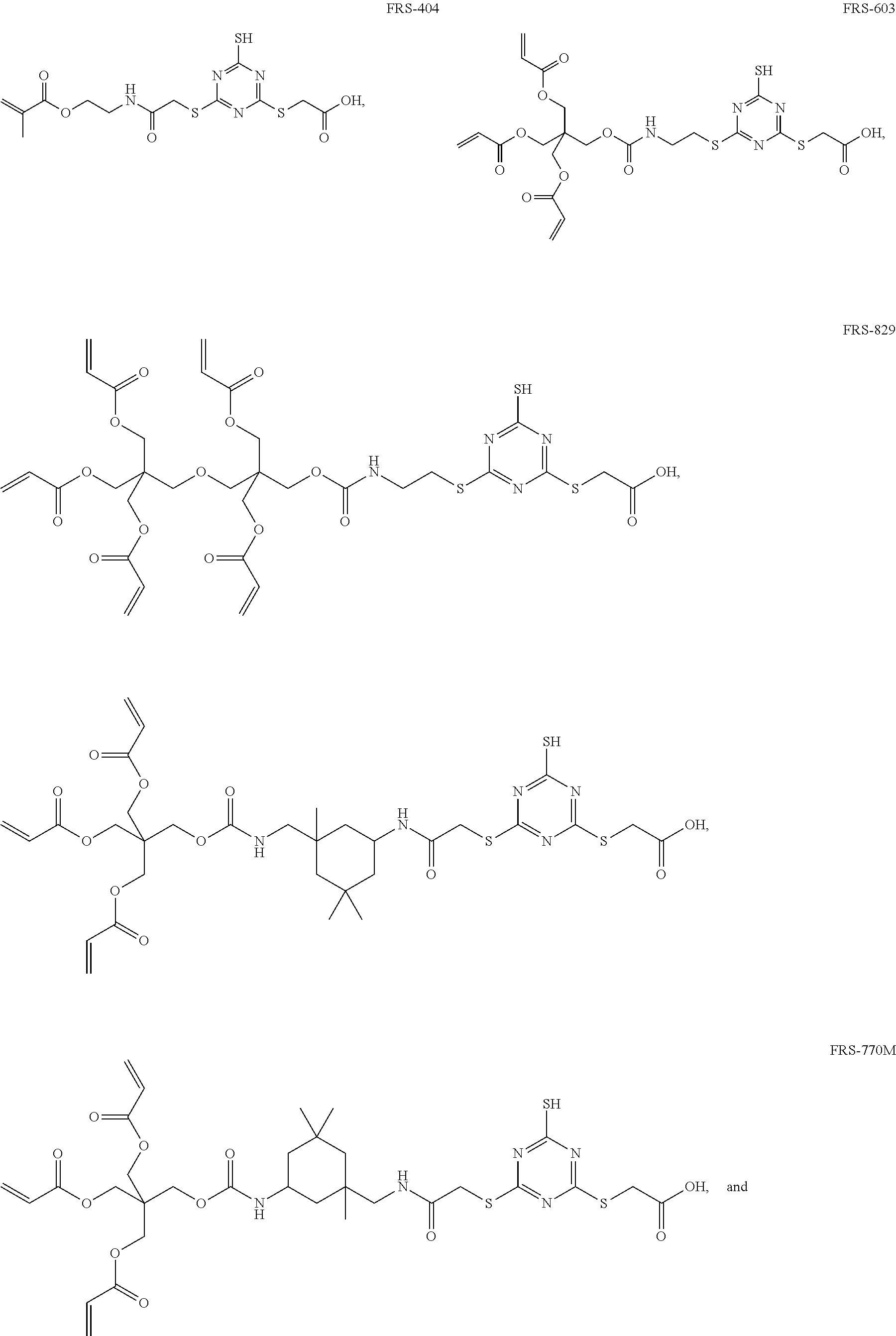 [SMILES: C=C(C)C(=O)OCCNC(=O)CSc1nc(S)nc(SCC(=O)O)n1 ; C=CC(=O)OCC(COC(=O)C=C)(COC(=O)C=C)COC(=O)NCCSc1nc(S)nc(SCC(=O)O)n1 ; C=CC(=O)OCC(COCC(COC(=O)C=C)(COC(=O)C=C)COC(=O)NCCSc1nc(S)nc(SCC(=O)O)n1)(COC(=O)C=C)COC(=O)C=C ; C=CC(=O)OCC(COC(=O)C=C)(COC(=O)C=C)COC(=O)NCC1(C)CC(NC(=O)CSc2nc(S)nc(SCC(=O)O)n2)CC(C)(C)C1 ; C=CC(=O)OCC(COC(=O)C=C)(COC(=O)C=C)COC(=O)NC1CC(C)(C)CC(C)(CNC(=O)CSc2nc(S)nc(SCC(=O)O)n2)C1]

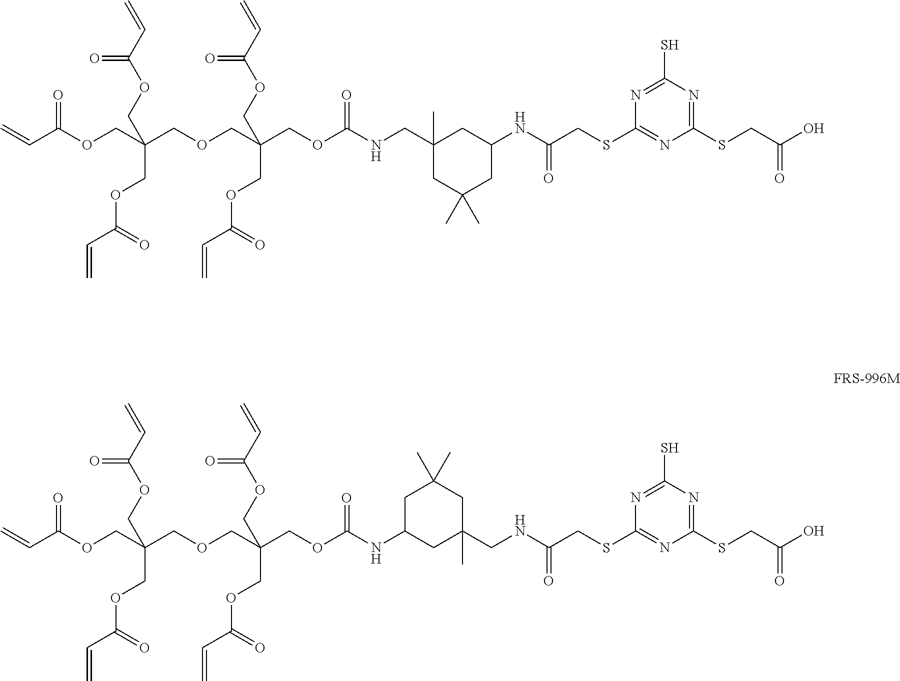 [SMILES: C=CC(=O)OCC(COCC(COC(=O)C=C)(COC(=O)C=C)COC(=O)NCC1(C)CC(NC(=O)CSc2nc(S)nc(SCC(=O)O)n2)CC(C)(C)C1)(COC(=O)C=C)COC(=O)C=C ; C=CC(=O)OCC(COCC(COC(=O)C=C)(COC(=O)C=C)COC(=O)NC1CC(C)(C)CC(C)(CNC(=O)CSc2nc(S)nc(SCC(=O)O)n2)C1)(COC(=O)C=C)COC(=O)C=C]

In other embodiments, the free radical scavengers may be incorporated into the radical polymerizable copolymers described above. This can be done, for example, by adding a supplementary repeat unit having as a pending group the T group described above.

Examples of such free radical scavengers, that are also radical polymerizable copolymers, in dispersed form (PolyXP 120S, 130S and 132S) and in the form of discrete particles (PolyNP 120S), which are preferred in NIR photopolymerizable imageable layer, include:

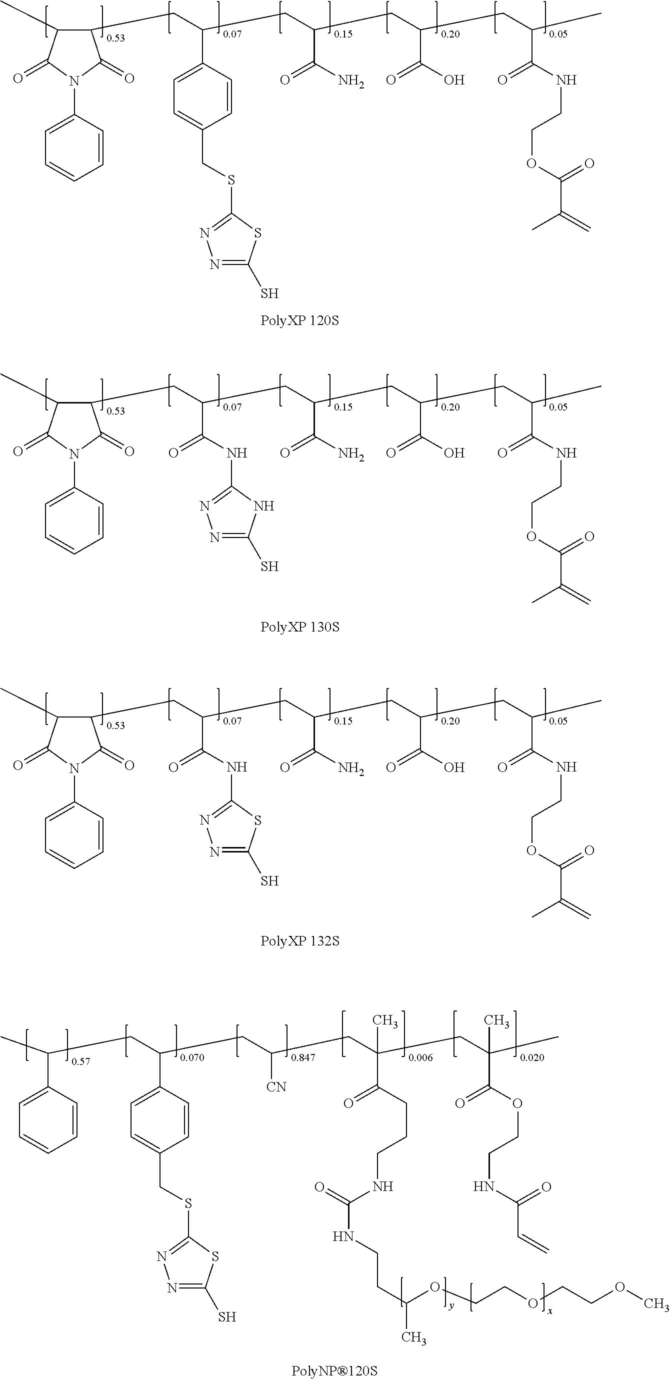

### Free Radical Stabilizers

The photoinitiating system further comprises one or more free radical stabilizer. Such free radical stabilizers are well-known to the skilled person. Any free radical stabilizer typically used in lithographic printing plate precursors can be used herein. Generally, the free radical stabilizers can be used at a concentration between about 1 and about 5 weight percent.

A preferred free radical stabilizer is 9-vinyl carbazole. It can be used at a concentration between 1 to 5 weight percent.

### Visible Colorants

The imageable layer of this invention further comprises one or more visible colorants. Visible colorants are well-known to the skilled person. Any colorant typically used in lithographic printing plate precursors can be used herein. Generally, the visible colorants can be used at a concentration between about 0.5 to about 10 weight percent.

Visible colorants may be dyes (molecules) or pigment (particles), both being dispersed in the imageable layer. Pigments are generally commercially available dispersed in a liquid.

Examples of typical visible dyes include Victoria blue BO, crystal violet, malachite green and their derivatives. Preferred visible dyes are basic violet 3 and Victoria blue BO.

A preferred pigment dispersion is a phthalocyanine blue 15 pigment dispersion in PolyXP 120S. This dispersion is sold under tradename PolyBlue 15A (by Mylan Group, Travinh, Vietnam) and can be used at a concentration between 3 to 10 weight percent.

### Visible Light Reflective Pigment

The imageable layer may optionally further comprises a visible light reflective pigment, i.e. a pigment that reflect visible light. Such visible light reflective pigment was found to advantageously and surprisingly increase the crosslinking of the outer surface of the imageable layer upon exposure to visible light and to prevent background staining. Such pigment can be used in the formulation at a concentration between 1 and 5 weight percent.

Non-limiting examples of visible light reflective pigment include titanium dioxide, zinc oxide, and aluminum oxide.

An example of visible light reflecting pigment that can be used is titanium dioxide dispersed in oligomers comprising radical polymerizable functional groups (see above for examples such oligomers). A preferred titanium dioxide dispersion is commercially available from Penn Color (Doylestown, Pa., USA) under tradename 9W1100. It comprises 75% titanium oxide pigment dispersed in dipropylene glycol diacrylate.

### Film Forming Surfactants

The imageable layer may optionally further comprises one or more film forming surfactant. The purpose of this surface is to improve the wetting of the coating composition on the substrate and thus ease film formation. Such surfactants are well-known to the skilled person. Any surfactant typically used in lithographic printing plate precursors can be used herein. Generally, the colorants can be used at concentrations ranging between about 0.1 and about 6.0 weight percent.

A preferred adhesion agent is BYK 307. This particular surfactant can be used at a concentration ranging between about 0.1 and about 1.0 weight percent.

### Adhesion Promoting Agents

The imageable layer may optionally further comprises one or more adhesion promoting agents.

Such agents are well-known to the skilled person. Any adhesion promoting agent typically used in lithographic printing plate precursors can be used herein. Examples of typically agents include phosphoric acid containing molecules, oligomers and polymers. Generally, these adhesion promoting agents can be used at concentrations ranging between about 0.5 and about 5.0 weight percent.

A preferred adhesion agent is a phosphate ester polypropylene glycol methacrylate sold under tradename Sipomer® PAM-200. It can be used at a concentration ranging between 1 to 5 weight percent.

### Substrate

The negative-working lithographic printing plate precursor of the invention comprises a hydrophilic substrate. Any substrate known by the skilled person to be useful for such purpose can be used.

A preferred substrate is a hydrophilic grained and anodized aluminum sheet; preferably of a thickness between about 100 and about 400 μm.

The manufacture of such substrate is carried by an electrolytic process that is well-known to the skilled person. This electrolytic process can be carried out on a continuous production line with a web process or sheet-fed process. This process typically comprises degreasing the aluminum substrate in an alkaline solution, electrograining in acidic solution, neutralization in an alkaline solution, anodization in acid solution, post anodization treatment with hydrophilic agents, drying with hot air, and ready for coating. More specifically, the aluminum can be first be degreased. In embodiments, this step comprises washing the aluminum with, for example, an aqueous alkaline solution containing sodium hydroxide (3.85 g/l) and sodium gluconate (0.95 g/l) at 65° C. to remove any organic oil and crease from its surface; neutralizing with, for example, aqueous hydrochloric acid (2.0 g/l); and finally washing with water to remove the excess of hydrochloric acid solution. The clean aluminum then undergoes electrolytic graining, for example in an aqueous electrolyte containing an aqueous solution of hydrochloric acid (8.0 g/l) and acetic acid (16 g/l), using carbon electrodes at 25° C. The current and charge density may be 38.0 A/dm² and 70.0 C/dm², respectively. After graining, the aluminum undergoes desmuting, which removes unwanted impurities before anodization. This can be accomplished, for example, with an aqueous sodium hydroxide solution (2.5 g/l), followed by neutralizing with an aqueous sulfuric acid solution (2 g/l); and washing with water to remove the excess acid. The aluminum then undergoes anodizing thus producing an aluminum oxide layer. Anodization can take place, for example, in an aqueous electrolyte containing sulfuric acid (140 g/l) at 25° C.; the current and charge density being adjusted to produce an aluminum oxide layer having a thickness between about 2.5 and about 3.0 g/m². The aluminum oxide layer is then washed with water and treated to enhance the hydrophilicity of its surface. This can be achieved, for example with an aqueous solution containing sodium dihydrophosphate (50 g/l) and sodium fluoride (0.8 g/l) at 75° C. followed by washing with water at 50° C.

At this step, the substrate can be reacted with:
an aqueous solution containing sodium dihydrogenphosphate (50 g/l) and sodium fluoride (0.8 g/l) at 75° C., thereby producing a phosphate fluoride coating on the substrate, or
an aqueous solution containing soldium silicate (30 g/l) at 75° C. was, thereby producing a sodium silicate coating on the substrate.
   Both coating desirably enhance the hydrophilicity of the substrate. The sodium silicate coating is generally preferred as it increases the adhesion of the imageable layer on the substrate. However, when this coating is used, it tends to become stained when a visible dye is used. So it is best used when the imageable layer contains a visible pigment instead. When using a visible dye, the phosphate fluoride coating can generally be used without staining.

Another alternative is to treat the substrate with an aqueous solution containing polyvinyl phosphoric acid (30 g/l) at 75° C., thereby producing polyvinyl phosphoric acid hydrophilic coating on the substrate.

The aluminum/aluminum oxide layers are then dried, for example with hot air at 110° C. in an oven. A specific example of such manufacture process is described in the section entitled “Manufacturing Process” below.

This aluminum sheet can be used and coated as is. Alternatively this aluminum sheet can be laminated onto various other materials.

In embodiments, the aluminum sheet is laminated on a sheet of plastic sheet or a coated paper sheet. This reduces, or may even eliminate, the need for interleaving paper, which is generally for packaging to prevent the precursor from sticking to each other. This would also significantly reduce production costs as it allows using a thinner sheet of (expensive) aluminum.

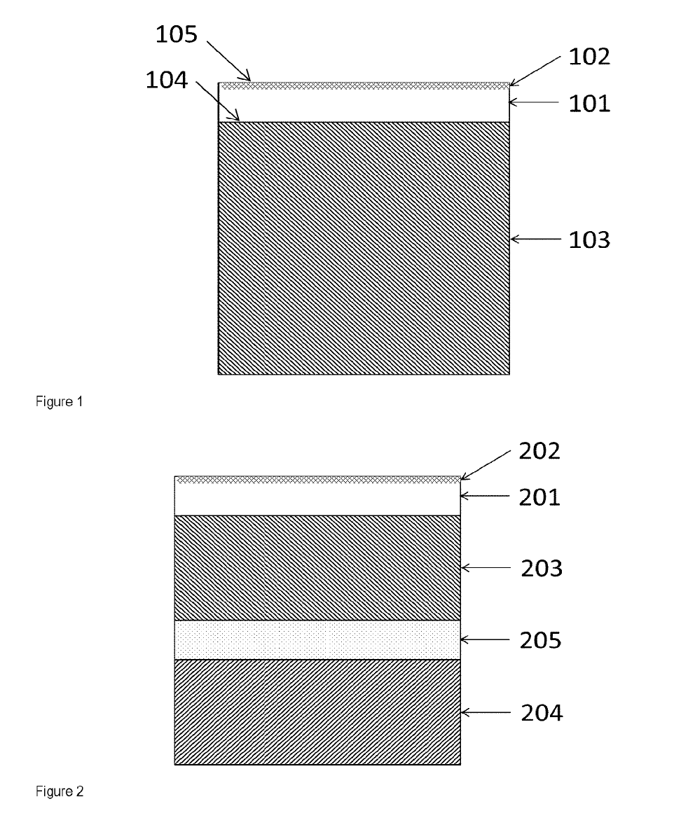

FIG. 2 is a cross-sectional view of the negative working precursor of the invention coated on an aluminum sheet laminated on a plastic sheet. In FIG. 2,
[201] is the imageable layer (preferably having a thickness preferably between about 0.8 and about 3.0 μm);
[202] is the crosslinked portion of the imageable layer (preferably having a thickness preferably between about 0.08 and about 0.30 μm);
[203] is the hydrophilic grained and anodized aluminum sheet (preferably having a thickness preferably between about 100 and about 400 μm);
[204] is a plastic or paper sheet (preferably having a thickness preferably between about 30 and about 300 μm); and
[205] is an adhesive layer (preferably having a thickness preferably between about 1 and about 50 μm).

FIG. 3 shows the cross-sectional scheme of the negative working precursor of the invention coated on an aluminum sheet laminated on a coated paper sheet. In FIG. 3:
[301] is the imageable layer (preferably having a thickness preferably between about 0.8 and about 3.0 μm);
[302] is the crosslinked portion of the imageable layer (preferably having a thickness between about 0.08 and about 0.30 μm); and
[303] is the hydrophilic grained and anodized aluminum sheet (preferably having a thickness between about 100 and about 400 μm);
[304] is a paper sheet (preferably having a thickness preferably between about 30 and about 300 μm);
[305] is a polymeric protective coating; and
[306] is an adhesive layer (preferably having a thickness between 1 and 50 μm).

US patent application publication no. 2011/0277653 and U.S. patent application Ser. No. 14/249, both incorporated herein by reference, describe laminated substrates that can be used herein.

More particularly, US patent application publication no. 2011/0277653 provides a lithographic printing plate substrate comprising (a) a base layer, (b) a layer of a first adhesive covering one side of the base layer except for at least two opposite edges thereof, and (c) an aluminum layer laminated onto the layer of first adhesive and said opposite edges of the base layer, the aluminum layer thereby being sealed with the base layer at said opposite edges of the base layer.

The substrate may also comprise strips of a second adhesive covering said opposite edges of the base layer. Furthermore, the aluminum layer is laminated onto the layer of first adhesive and the strips of second adhesive. Therefore, it can be said that the aluminum layer is sealed with the base layer through this second adhesive. The second adhesive is typically insoluble and non-dispersible in water and fountain solutions so as to reduce risks of de-lamination of the substrate and therefore allow longer runs on press. The second adhesive may be solvent-based. In other words, it is an adhesive prepared with a solvent that is not aqueous, for example an organic solvent. In embodiments, the second adhesive is an urethane adhesive.

The exact nature of the base layer material is not crucial. The material is chosen based on cost and handling characteristics. It is sufficient that the base layer, together with the other layers, of the substrate, the base layer provides the desired structural strength. In embodiments, the base layer is between about 50 and about 400 μm thick.

The base layer may be, for example, a plastic layer, a composite layer, a cellulose-based layer such as cardstock or paper, or a non-woven fabric layer. When the base layer is a plastic layer, it can be a solid plastic layer, a multi-laminate layer, or a plastic foam layer. The base layer may comprise a thermoplastic resin, such as a petroleum based thermoplastic resin or a biomass based thermoplastic resin. Example of such resins include polystyrene (PS), polyethylene (PE), polypropylene (PP), polyester (PET), polyamide (PA), polyvinyl chloride (PVC), polyetheretherketone (PEEK), polyimide (PI), polyvinylacetate (PVA), polyalkylacrylate (PAAA), polyalkylmethacrylate (PAMA), polylactide, polybutahydroburate, polysuccinamate, cellulosic polymers, copolymers thereof, and mixtures thereof. These thermoplastic resins, and any plastic used as a base layer, may comprise one or more fillers. The amount of fillers in the resins may be between about 5 to about 85% by weight. The filler may be an inorganic filler, such as, for example, calcium carbonate, silica, alumina, titanium oxide, aluminosilicate, zeolite and fiberglass. The filler may also be an organic carbohydrate flour, such as that obtained from biomass and natural fibers, such as starch, sawdust, rice husks, rice straw, wheat straw, and sugarcane bagasse. The filler may also be carbon black or another similar material.

The base layer may further comprise pigments or colorants. These allow, for example, identifying a given product or a given brand. The base layer may also comprise polymer processing additives, such as antioxidants and flowing agents for example.

The base layer may be produced by melt extrusion, possibly with one or more of the other layers of the substrate.

The layer of first adhesive provides for the adhesion of the aluminum layer to the rest of the substrate during processing and use. As such, the exact nature of the layer of first adhesive is not critical. In embodiment, the layer of first adhesive is a plastic layer. In embodiments, the layer of first adhesive comprises a thermoplastic resin, preferably one that is soluble or dispersible in a processing liquid. The layer of first adhesive may be between about 1 and about 100 μm thick.

The layer of first adhesive may be produced by melt extrusion (possibly by co-extrusion with one or more of the other layers of the substrate). In this case, the thermoplastic resins may be, for example, linear polyvinyl alcohols, branched polyvinyl alcohols (for example that described in US2009/0286909, which is incorporated herein by reference), polyethylene oxide (such as that available under tradenames POLYOX™ from Dow Industrial Specialty Polymers and that available from Sumitomo Seika, Japan), polyamides (such as that described in U.S. Pat. No. 5,324,812 and U.S. Pat. No. 6,103,809), water soluble polyesters (such as that available under tradename Zypol from Zydex Industries, India), acrylic acid copolymers, and methacrylic acid copolymers.

Alternatively, the layer of first adhesive may be produced by coating (for example the aluminum layer) with a polymeric solution following by drying (for example in an oven using hot air or NIR heating tubes). In that case, the polymeric solution may be an homogeneous solution or an emulsion of, for example, a polyvinyl alcohol, polyethylene oxide, an acrylic acid copolymer, a methacrylic acid copolymer, an urethane polymer, an urea polymer, an amide polymer, an ester polymer, copolymers thereof or a mixture thereof.

In embodiments, the substrate further comprises an outer layer covering the other side of the base layer (i.e. the side not covered by the layer of first adhesive and mounted on and facing the lithographic press cylinder). This layer may be between about 1 and about 50 μm thick. This layer may be a plastic layer. In embodiments, the outer layer comprises a thermoplastic resin. In embodiments, the thermoplastic resin is polyethylene, polypropylene, polymethylmethacrylate, polyethylene phthalate, polystyrene, polyvinyl chloride, a copolymer thereof or a mixture thereof.

In embodiments, the outer layer is produced by melt extrusion, possibly with one or more of the other layers of the substrate as explained below. Like the base layer, the outer layer may comprise, in embodiments, pigments, colorants, fillers (such as that described above for the base layer), and/or polymer processing additives such as antioxidants and flowing agents.

U.S. patent application Ser. No. 14/249,458 provides a laminated lithographic printing plate precursor comprising:
an aluminum layer having a first side and a second side, a first aluminum oxide layer coating the first side of the aluminum layer, (together the aluminum sheet discussed above)
optionally a second aluminum oxide layer coating the second side of the aluminum layer,
an imageable layer coating the first aluminum oxide layer,
an adhesive layer adhering to the second side of the aluminum layer or to said second aluminum oxide layer when the second aluminum oxide layer is present, and
a base layer coating the adhesive layer,
the adhesive layer being accessible to and insoluble in oleophilic inks and alkaline or acidic aqueous fountain solutions used during printing with the printing plate, and alkaline or acidic aqueous developers used during development of the printing plate, and
   the adhesive layer being:
soluble in an alkaline aqueous processing liquid, when said developers and said fountain solutions are acidic,
soluble in an acidic aqueous processing liquid, when said developers and said fountain solutions are alkaline,
meltable, or
when said second aluminum oxide layer is present, a dry adhesive compliant layer having a hardness of 60 Shore-A or less,
thereby allowing delamination of the printing plate in view of recycling after printing.

Generally, these printing plate precursors have a total thickness between 100 μm and 600 μm, preferably between 100 and 400 μm.

Together, the aluminum layer, the first aluminum oxide layer and the imageable layer in U.S. patent application Ser. No. 14/249,458 embody a rather conventional lithographic printing plate. However, the aluminum layer can be thinner than in conventional printing plates because the base layer provides structural support to the printing plates of the present invention. For example, the aluminum layer may be between about 20 and about 300 μm thick, preferably between about 20 and about 200 μm thick. However, the aluminum may also be thicker, such as between about 100 and about 300 μm thick. The hardness of the aluminium layer is typical of that in conventional plates. For example, it can be between H16 and H18.

The base layer may be between about 10 and about 350 μm thick, preferably between about 10 to about 300 μm, more preferably between about 50 to about 300 μm, most preferably between 100-200 μm, such as between 100-150 μm. The exact nature of the base layer material is not crucial. The base layer may be a plastic layer, a composite layer, a cellulose-based layer such as cardstock or paper, or a non-woven fabric layer. When the base layer is a plastic layer, it can be a solid plastic layer, a multi-laminate layer, or a plastic foam layer. In embodiments, the base layer comprises a thermoplastic resin, such as a petroleum based thermoplastic resin or a biomass based thermoplastic resin. Example of such resins include polystyrene (PS), polyolefins such as polyethylene (PE) and polypropylene (PP) (including oriented PP, such biaxially oriented PP (or BOPP)), polyesters, such as polyethylene terephthlate (PET), polyamide (PA), polyvinyl chloride (PVC), polyetheretherketone (PEEK), polyimide (PI), polyvinylacetate (PVA), polyalkylacrylate (PAAA), polyalkylmethacrylate (PAMA), polylactide, polybutahydroburate, polysuccinamate, cellulosic polymers, copolymers thereof, and mixtures thereof. I

These thermoplastic resins, and any plastic used as a base layer, may comprise one or more fillers. The amount of fillers in the resins may be between about 5 to about 85% by weight, for example between about 10 and about 30/%, and more specifically about 20%. The filler may be an inorganic filler, such as, for example, calcium carbonate, silica, alumina, titanium oxide, aluminosilicate, zeolite and fiberglass. The filler may also be an organic carbohydrate flour, such as that obtained from biomass and natural fibers, such as starch, sawdust, rice husks, rice straw, wheat straw, and sugarcane bagasse. The filler may also be carbon black or another similar material.

In embodiments, the base layer may further comprise pigments or colorants. The base layer may also comprise polymer processing additives, such as antioxidants and flowing agents for example.

In embodiments, the base layer is paper coated with a polymer layer on at least one side (it is not necessary to coat the paper on the side facing the adhesive layer). The polymer layer can be a polybutyrate or polyacetal layer.

The adhesive layer provides for the adhesion of the base layer to the aluminum layer base layer during use of the printing plate (including development and printing). The adhesive layer is not soluble in the developers, fountain solutions and developers. The adhesive layer should indeed be insoluble or show little solubility in these liquids otherwise the printing plate would risk delamination during development and/or printing. Therefore, if the printing plate is for use with alkaline developers and/or alkaline fountain solutions, the adhesive should be insoluble in alkaline aqueous solutions, and if the printing plate is for use with acidic developers and/or acidic fountain solutions, the adhesive layer should be insoluble in acidic aqueous solutions. Also, the adhesive should not be soluble in the inks used for printing (these inks are oleophilic as explained above).

The adhesive layer can be of various natures. It can be a layer of a drying adhesive, i.e. an adhesive that hardens by drying. It can also be a layer of a hot-melt adhesive, i.e. an adhesive that hardens by cooling. Finally, the adhesive layer can be dry adhesive compliant layer that adhere to the second aluminum oxide layer as discussed below. Such dry adhesives are disclosed in International patent publication no. WO 2012/155259 (Nguyen et al.), which is incorporated herein by reference.

The drying adhesives that can be used in the adhesive layer are solvent based adhesives, which typically comprise one or more ingredients (typically polymers) dissolved in a solvent. As the solvent evaporates, the adhesive hardens. Thus, the drying adhesives for use in the adhesive layer should be soluble in such solvent (water based or not) so they can be applied to the base layer. Further, once dried, these adhesives should not be soluble in the oleophilic inks used with the printing plate. This can be achieve by selecting adhesives that are soluble in aqueous solutions rather than in oleophilic solvents.

In addition, however, these adhesives should not be soluble in the aqueous developers, and fountain solutions that will be used with the printing plate, while being soluble in the aqueous processing liquid to be used for delamination (see below for more details on recycling). This is achieved this by selecting the nature of the processing liquid in function of the nature of the developers and/or fountain solutions used during use of the printing plate. If the developers and/or fountain solutions are acidic, then the processing liquid will be alkaline. If the developers and/or fountain solutions are alkaline, then the processing liquid will be acidic. In other words, the drying adhesive must be either (A) soluble in alkaline aqueous solution, but insoluble in acidic aqueous solutions, or (B) soluble in acidic aqueous solution, but insoluble in alkaline aqueous solutions.

All of the above can be achieved by polymers that have a relatively low Tg (glass transition temperature), for example between about 10 and about 60° C., preferably between about 15 and about 20° C., so they are tacky. Such polymers should comprise sufficient polar functional groups (alcohols, carboxyls, amides, and the like) that provide solubility in aqueous solutions and limit solubility in oleophilic media. Such polymers include acrylate, urethane, urea, epoxy, or ester polymers. Preferred polymers are acrylate polymers as they are economical and are easy to modify.

Further, these polymers should comprise either sufficient acidic functional groups (such as —COOH) that provide solubility in alkaline aqueous solutions or sufficient basic functional groups (such as amines) that provide solubility in acidic aqueous solutions depending on its desired solubility characteristics.

An example of a polymer that is soluble at an acidic pH, but insoluble at alkaline pH, is a copolymer of alkyl acrylate monomers with dialkylamino alkyl acrylate monomers. The presence of dialkylamino alkyl acrylate monomers, which contain a basic amino group, provides solubility in acidic aqueous solutions. The solubility of the copolymer can thus be fine-tuned by adjusting the ratio of this monomer compared to the other monomers. Examples of dialkylamino alkyl acrylate monomers include dimethylamino-ethyl-acrylate, diethylamino-ethyl-acrylate, and dibutylamino-ethyl-acrylate. Examples of alkyl acrylate monomers include ethyl acrylate and methyl acrylate. A specific example of such a copolymer is a copolymer of methyl acrylate (5-15% by weight), ethyl acrylate (50-80% by weight), and dimethylamino ethyl acrylate (5-20% by weight). The percentages value being based on the total weight of the copolymer. Such a polymer is, for example, sold under the tradename Elastak™ 1020.

An example of an adhesive that is soluble at an alkaline pH, but insoluble at acidic pH, is a copolymer of alkyl acrylate monomers with acrylic acid monomers. The presence of acrylic acid monomers, which contain acidic groups, provides solubility in alkaline aqueous solutions. The solubility of the copolymer can thus be fine-tuned by adjusting the ratio of this monomer compared to the other monomer. Examples of alkyl acrylate monomers include the same as above. A specific example of such a copolymer is a copolymer of methyl acrylate (5-15% by weight), ethyl acrylate (50-80% by weight), and acrylic acid (5-20% by weight). The percentages value being based on the total weight of the copolymer. Such a polymer is, for example, sold under the tradename Elastak™ 1000.

In both cases above, the Tg of the copolymers is controlled by the ratio of various monomers. For example, pure poly(methylacrylate) has a Tg of about 10° C., pure poly(ethylacrylate) has a Tg of about −21° C., pure poly (dimethylamino ethyl acrylate) has a Tg of about 19° C., while pure poly(acrylic acid) has a Tg of about 105° C.

The hot-melt adhesives that can be used in the adhesive layer are thermoplastics applied in molten form that solidify on cooling to form adhesive bonds between the aluminum layer and the base layer. Again, once cooled, these adhesives should not be soluble in the oleophilic inks used with the printing plate. In addition, the hot-melt adhesives should not be soluble in the developers and fountain solutions that will be used with the printing plate.

Examples of suitable hot-melt adhesives include ethylene-vinylacetate polymer, polyamide, polyolefin, reactive polyurethane, and ethylene-acrylic ester-maleic anhydride terpolymers. In particular, the adhesives sold under the tradenames:
Lotader™ (including product 3210, a random terpolymer of ethylene, acrylic ester and maleic anhydride) from Arkema, USA),
Dorus™ (including product KS 351, an ethylene-vinylacetate polymer from Henkel, USA), Macromelt® (including product TPX 16-344 UBK™, a polyamide) from Henkel, USA, and
Affinity™ (including product GA1875, a polyolefin elastomer) from Dow, USA
   are noted.

A sub-class of hot-melt adhesive are reactive hot-melt adhesives, which after solidifying, undergo further curing e.g., by moisture, by ultraviolet radiation, electron irradiation, or by other methods.

Examples of such adhesives include the reactive urethane adhesives sold under tradenames:
Suprasec® from Huntsman, USA,
Purmelt® (including product QR-6205) from Henkel, USA,
Terorehm® (including product MC9520 and MC9530, moisture curing polyurethanes from Henkel, USA, and
Mor-Melt™ (including product R5003, a moisture curing polyurethane) from Dow, USA.

In embodiments of all of the above types of adhesives, the adhesive layer is between about 10 and about 300 μm thick, preferably between about 10 and about 100 μm, most preferably between about 10 and 50 μm. In embodiments, the adhesive layer is about 20 μm thick.

When a dry adhesive is used, the backside of the aluminum layer (i.e. the side opposite the image forming layer) must be covered by a “second” aluminum oxide layer. Such aluminum oxide layer, prepared by graining and anodization as described below, comprises nano- and micro-pores that are involved in the dry adhesion. The base layer is covered by the adhesive layer, which in this case is a dry adhesive compliant layer. Such a dry adhesive compliant layer will reversibly adhere to the aluminum oxide layer.

The dry adhesive compliant layer is not soluble in the oleophilic inks, developers and fountain solutions that will be used with the printing plate. It should be noted however that it is not necessary that the dry adhesive compliant layer be soluble in a processing liquid as the dry adhesion means that the base layer bearing the dry adhesive compliant layer can very simply be peeled off the second aluminum oxide layer, which allows delaminating without using any processing liquid.

The dry adhesive compliant layer has a relatively low modulus so that it is able to deform and conform to the pores in the “second” aluminum oxide layer. In embodiments, the compliant material or surface has a hardness of 60 Shore-A or less, preferably 55, 50, 45, 40, 35, 30, or 25 Shore-A or less. In these or other embodiments, the compliant material or surface has a hardness of 20, 25, 30, 35, 40, 45, 50, or 55 Shore-A or more

In embodiments, the compliant surface is made of a polymer, non-limiting examples of which include thermoplastic polymers, thermoplastic elastomers, and crosslinked elastomers.

Suitable polymers include, but are not limited to, natural polyisoprene, synthethic polyisoprene, polybutadiene, polychloroprene, butyl rubber, styrene-butadiene rubber, nitrile rubber, ethylene propylene rubber, epichlorohydrin rubber, polyacrylic rubber, silicone rubber, fluorosilicone rubber, fluoroelastomers, perfluoroelastomers, polyether block amides, chlorosulfonated polyethylene, ethylene-butadiene copolymer elastomers, ethylene-vinyl acetate, silicone elastomer, polyurethane elastomer, aminopropyl terminated siloxane dimethyl polymers, styrene-ethylene/propylene-styrene (SEPS) thermoplastic elastomer, styrene-ethylene/butylene-styrene (SEBS) thermoplastic elastomer, styrene-isoprene-styrene (SIS) thermoplastic elastomer, styrene-butadiene-styrene (SBS) thermoplastic elastomer, and/or styrene-ethylene/butylene-styrene grafted with maleic anhydride thermoplastic elastomer.

In embodiments, the compliant material making the dry adhesive compliant layer is an elastomer having a hardness between 40 and 55 Shore D.

The table below shows non-limiting examples of thermoplastic elastomers together with some of their physical properties. The thermoplastic elastomers are listed with their hardness (Shore A), elongation at break (%), and/or tensile strength (psi). Kraton thermoplastic elastomers are available through Kraton Polymers in Houston, Tex.

| | | | |
|---|---|---|---|
| | | Elongation | Tensile |
| | Hardness | at break | strength |
| Name | (Shore A) | (%) | (psi) |

KRATON ® D SIS - Styrenic block copolymers based on styrene and isoprene

| | | | |
|---|---|---|---|
| KRATON ® D1114 P Polymer | 42 | 1300 | 4600 |
| (Clear, linear triblock copolymer based on styrene and | | | |
| isoprene with a polystyrene content of 19%.) | | | |
| KRATON ® D1160 B Polymer | 48 | 1300 | 4640 |
| (Clear linear triblock copolymer based on styrene and | | | |
| isoprene with bound styrene of 18.5% mass.) | | | |
| KRATON ® D1161 B Polymer | 30 | 1300 | 4060 |
| (Clear, linear block copolymer based on styrene and | | | |
| isoprene with a polystyrene content of 15%.) | | | |
| KRATON ® D1163 P Polymer | 25 | 1400 | 1500 |
| (Clear, linear triblock copolymer based on styrene and | | | |
| isoprene, with a polystyrene content of 15%) | | | |

KRATON ® D SBS - Block copolymers composed of blocks of styrene and
butadiene

| | | | |
|---|---|---|---|
| KRATON ® D4141 K Polymer | 50 | 1300 | 2750 |
| (31% styrene) | | | |
| KRATON ® D4150 K Polymer | 45 | 1400 | 2800 |
| (Linear triblock copolymer based on styrene and butadiene | | | |
| with a polystyrene content of 31%.) | | | |
| KRATON ® D4158 K Polymer | 41 | 1110 | 1330 |
| (Oiled, radial copolymer based on styrene and butadiene | | | |
| with a polystyrene content of 31%.) | | | |

KRATON ® G SEBS/SEPS - Styrenic block copolymers with a hydrogenated
midblock of styrene-ethylene/butylene-styrene (SEBS) or styrene-ethylene/
propylene-styrene (SEPS)

| | | | |
|---|---|---|---|
| KRATON ® G1645 M Polymer | 35 | 600 | 1500 |
| (Linear triblock copolymer based on styrene and | | | |
| ethylene/butylene) | | | |
| KRATON ® G1657 M Polymer | 47 | 750 | 3400 |
| (Clear, linear triblock copolymer based on styrene and | | | |
| ethylene/butylene with a polystyrene content of 13%) | | | |
| KRATON ® G1702 H Polymer | 41 | <100 | 300 |
| (Clear, linear diblock copolymer based on styrene and | | | |
| ethylene/propylene with a polystyrene content of 28%. | | | |
| KRATON ® G4609 H Polymer | 22 | — | 800 |
| (White mineral oil extended linear triblock copolymer based | | | |
| on styrene and ethylene/butylene with a polystyrene | | | |
| content of 33%. Nominal oil content of the polymer is | | | |
| 45.5% w (90 parts/100 parts rubber (phr)). | | | |

KRATON ® FG - SEBS polymers with 1.0 to 1.7 wt. % maleic anhydride (MA)
grafted onto the rubber midblock

| | | | |
|---|---|---|---|
| KRATON ® FG1924 G Polymer | 49 | 750 | 3400 |
| (Clear, linear triblock copolymer based on styrene and | | | |
| ethylene/butylene with a polystyrene content of 13%.) | | | |

The table below shows non-limiting examples of crosslinked elastomers together with some of their physical properties. The crosslinked elastomers are listed with their hardness (Shore A), elongation at break (%), tensile strength (psi), and tear strength (kN/m). The silicone elastomers are available through Dow Corning.

| | | | Tensile | Tear |
|---|---|---|---|---|
| | Durometer | Elongation | Strength | Strength |
| Name | (Shore A) | (%) | (psi) | (kN/m) |
| Dow Corning ® 3631 | 19 | 800 | 725 | 16 |
| (Two-part, solvent free, heat-cured liquid | | | | |
| silicone rubber.) | | | | |
| Dow Corning ® D94-20P | 21 | 900 | 765 | N/A |
| (Two-part, 1:1 ratio, addition cure silicone | | | | |
| elastomer) | | | | |
| Dow Corning ® D94-30P | 33 | 800 | 1000 | 16.1 |
| (Two-part, 1:1 ratio, addition cure silicone | | | | |
| elastomer) | | | | |
| Silastic ® LC-20-2004 | 20 | 900 | 940 | 24 |
| (20 Durometer, 2 parts, 1 to 1 mix, | | | | |
| translucent, FDA 21 CFR 177.2600 and | | | | |
| BfR, XV, molding and injection molding | | | | |
| grade Liquid Silicone Rubber) | | | | |
| Silastic ® LC-9426 | 20 | 790 | 609 | 23 |
| (Two-part liquid silicone rubber) | | | | |
| Silastic ® 94-595 | 42 | 610 | 1450 | 34 |
| (40 Durometer, 2-part, 1 to 1 mix, | | | | |
| translucent Liquid Silicone Rubber) | | | | |
| Silastic ® 94-599 | 49 | 590 | 1595 | 32 |
| (47 Durometer, 2-part, 1 to 1 mix, | | | | |
| translucent, molding grade, Liquid Silicone | | | | |
| Rubber) | | | | |
| Silastic ® LC-9434 | 33 | 790 | 797 | 32 |
| (two-part liquid silicone rubber) | | | | |
| Silastic ® LC-9436 | 29 | 720 | 855 | 28 |
| (two-part liquid silicone rubber) | | | | |
| Silastic ® LC-9451 | 50 | 540 | 1102 | 30 |
| (two-part liquid silicone rubber) | | | | |
| Silastic ® LC-9452 | 50 | 560 | 1015 | 34 |
| (two-part liquid silicone rubber) | | | | |
| Silastic ® LC-9454 | 50 | 530 | 1044 | 29 |
| (two-part liquid silicone rubber) | | | | |
| DOW CORNING Class VI Elastomers C6-530 | 30 | 831 | 1189 | 27.5 |
| (heat cured elastomer raw materials) | | | | |
| DOW CORNING Class VI Elastomers C6-540 | 40 | 742 | 1293 | 41.9 |
| (heat cured elastomer raw materials) | | | | |
| Dow Corning ® S40 | 40 | 864 | 1250 | 31.2 |
| (Two-part platinum-catalyzed silicone | | | | |
| elastomer) | | | | |
| Dow Corning ® S50 | 48 | 610 | 1275 | 42.5 |
| (Two-part platinumcatalyzed silicone | | | | |
| elastomers) | | | | |
| Dow Corning ® D94-45M | 45 | 600 | 1050 | 45 |
| (Two-part, 1:1 ratio, addition cure silicone | | | | |
| elastomer) | | | | |

Another example of compliant material is QLE1031; a heat curable silicone elastomer available from Quantum Silicones, Virginia, USA.

In embodiments, the dry adhesive compliant layer is between about 5 and about 80 μm thick, preferably between about 10 and 50 μm.

### Method of Manufacture and Other Methods

In a related aspect, the present invention provides methods for manufacturing a negative-working lithographic printing plate precursor, in particular a precursor as described above. This method comprises the steps of:
a) providing a hydrophilic substrate coated with a NIR photopolymerizable or UV-violet photopolymerizable imageable layer, the imageable layer comprising a free radical photoinitiator sensitive to visible radiation, the imageable layer having an outer surface and a thickness,
b) uniformly, and partially or completely crosslinking the outer surface of the imageable layer down to a depth corresponding to at most about 70% of the thickness of the imageable layer.

In other related aspects, the present invention provides methods for:
creating an oxygen barrier on an imageable layer of a negative-working lithographic printing plate precursor,
protecting an imageable layer of a negative-working lithographic printing plate precursor from scratches,
reducing the tackiness of an imageable layer of a negative-working lithographic printing plate precursor,
reducing absorption of oxygen molecules from the air by an imageable layer of a negative-working lithographic printing plate precursor,
increasing the laser imaging speed of an imageable layer of a negative-working lithographic printing plate precursor, and
increasing the self-life of a negative-working lithographic printing plate precursor.

All these methods comprising the steps of:
a) providing a negative-working lithographic printing plate precursor comprising a hydrophilic substrate coated with a NIR photopolymerizable or UV-violet photopolymerizable imageable layer, the imageable layer comprising a free radical photoinitiator sensitive to visible radiation, the imageable layer having an outer surface and a thickness,
b) uniformly, and partially or completely crosslinking the outer surface of the imageable layer down to a depth corresponding to at most about 70% of the thickness of the imageable layer.

All the information provided above in regard of the negative-working lithographic printing plate precursor (including the imaging layer and the crosslinked portion thereof, the various components of the imageable layer, the substrate, etc.) also applies to these methods. This information is not repeated here.

In step a) of all the above methods, the hydrophilic substrate can be manufactured as described above. This can include, for example, graining and anodization of an aluminum sheet and optionally lamination to various substrates.

The hydrophilic substrate must be coated with a photopolymerizable imageable layer. The components of this layer have been described above. They can be dissolved (or suspended in the case of particles) in a coating solvent to produce a coating composition. Examples of suitable solvents include C₁-C₈ alcohol, C₄-C₈ ketone, C₃-C₅ cyclic ether, and C₄-C₈ ester, preferably propylene glycol methyl ether, methyl ethyl ketone, 1,3-dioxolane, and 1-methoxy-2-propanol.

The imageable layer is produced by coating this composition on the substrate and drying to evaporate the solvent. The coating can be carried using a slot-die coating head, a wire-wound rod, a roller, or micro-gravure. The drying can be carried out for example in an oven a temperature between 100 and 150° C.

In step b) of all the above methods, the outer surface of the imageable layer is crosslinked down to a certain depth. This is carried out by irradiating the imageable layer with visible light; more specifically, by exposing the imageable layer to a visible light source emitting between 400 and 700 nm.

The aim of the visible irradiation is to provide a rather low light intensity (compared to that used during imaging) to the outer surface of the imageable layer only, but across this entire surface. As such, the visible light source is a divergent light source, i.e. a light source that radiates light in all directions at once. It is not a focused intense laser beam such as that used during imaging, and which penetrates deep into the imageable layer to crosslink it down to the imageable layer/substrate interface. Non-limiting examples of visible light sources include LED visible light and fluorescent lamps. A preferred light source is the SmartView® Compact LED Light, Model SV-CLED-8 (available from Cognex Corporation, Singapore), which has an emission spectrum as shown in the Examples below.

The visible light source emits light at visible wavelengths that are partially absorbed by the imageable layer. In other words, the absorption spectra of the photoinitiators in the imageable layer and the emission spectrum of the visible light source at least partially overlap (i.e. overlap at one or more wavelengths). The extent of this overlap will influence the level and depth of crosslinking. All other things being equal, the greater the overlap, the faster the crosslinking. In other words, for any given visible wavelengths emitted by the light source, the greater the absorbance of the photoinitiator, the faster the crosslinking.

The intensity of the light source, the distance between the light source and the imageable layer, and the duration of the irradiation are variable (for a given imageable layer, but also between various imageable layer comprising different photoinitiators), but should be controlled so as to provide to desired level of crosslinking down to the desired depth. All other things being equal:
increasing the intensity of the light source,
decreasing the distance between the light source and the imageable layer, and/or
increasing the duration of the irradiation
   will increase the density of the crosslinks and/or the depth of crosslinking. For example, a 1.5-second irradiation with a SmartView® Compact LED Light, Model SV-CLED-8 having a luminous flux of 8500 lumens and a surface area of 0.1 m² (in other words 85000 lumens/m²), located 15 cm away from the imageable layer, usually crosslinks the outer surface of the imageable layer in a suitable manner (see the Examples).

If need, the exposure time can be increased by installing several, for example up to 10, visible light sources one after another on the production line.

Should an imageable layer be exposed too exposed to visible radiation, crosslinks will reach the imageable layer/substrate interface. This means that certain areas that should be removed during development will not be completely removed. This “dirty substrate” will translate into poor printing performances. If this is observed, the duration or intensity of the visible irradiation should simply be shortened.

Generally speaking, the intensity of the visible light source should usually vary between about 4,000 and about 16,000 lumen, the distance between the light source and the imageable layer will usually vary between about 5 and about 50 cm, and the duration of the irradiation will usually vary between about 1 and about 60 seconds. These values however should be adjusted for imageable layer with unusually large or small absorbance values at the visible wavelengths emitted by the light source. The Examples below show that when using a set-up in which the imageable layer receives 85,000 lumen/m², background staining does not occur before 50 seconds of irradiation. For reference, normal room light level is only between about 500 and about 1,000 lumen/m², which explains why the precursor can generally be handled under ambient light without background staining for at least 4 hours (depending on the intensity and type of the room light source).

For note, because of the generally lower absorption of visible light by the photoinitiating system (compared to UV-violet or NIR), and because of the visible light source is of lower intensity and is divergent (compared to a focused laser beam), the crosslinking involved at this step will be slower and less extensive than that occurring during imaging (because fewer free radicals will be produced) and located at the surface, rather than reaching the imageable layer/substrate interface.

### Definitions

The use of the terms “a” and “an” and “the” and similar referents in the context of describing the invention (especially in the context of the following claims) are to be construed to cover both the singular and the plural, unless otherwise indicated herein or clearly contradicted by context.

The terms “comprising”, “having”, “including”, and “containing” are to be construed as open-ended terms (i.e., meaning “including, but not limited to”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. All subsets of values within the ranges are also incorporated into the specification as if they were individually recited herein.

Similarly, herein a general chemical structure with various substituents and various radicals enumerated for these substituents is intended to serve as a shorthand method for referring individually to each and every molecule obtained by the combination of any of the radicals for any of the substituents. Each individual molecule is incorporated into the specification as if it were individually recited herein. Further, all subsets of molecules within the general chemical structures are also incorporated into the specification as if they were individually recited herein.

All methods described herein can be performed in any suitable order unless otherwise indicated herein or otherwise clearly contradicted by context.

The use of any and all examples, or exemplary language (e.g., “such as”) provided herein, is intended merely to better illuminate the invention and does not pose a limitation on the scope of the invention unless otherwise claimed.

No language in the specification should be construed as indicating any non-claimed element as essential to the practice of the invention.

Herein, the term “about” has its ordinary meaning. In embodiments, it may mean plus or minus 10% or plus or minus 5% of the numerical value qualified.

Unless otherwise defined, all technical and scientific terms used herein have the same meaning as commonly understood by one of ordinary skill in the art to which this invention belongs.

Herein, the terms “alkyl”, “alkylene”, “alkylyne”, and their derivatives (such as alkoxy, alkyleneoxy, etc.) have their ordinary meaning in the art. It is to be noted that, unless otherwise specified, the hydrocarbon chains of these groups can be linear or branched. Further, unless otherwise specified, these groups can contain between 1 and 18 carbon atoms, more specifically between 1 and 12 carbon atoms, between 1 and 6 carbon atoms, between 1 and 3 carbon atoms, or contain 1 or 2 carbon atoms.

Other objects, advantages and features of the present invention will become more apparent upon reading of the following non-restrictive description of specific embodiments thereof, given by way of example only with reference to the accompanying drawings.

### DESCRIPTION OF ILLUSTRATIVE EMBODIMENT

The present invention is illustrated in further details by the following non-limiting examples.

Unless state otherwise, in the Examples below, negative-working computer-to-plate (CTP) lithographic printing plates precursors were produced, imaged and developed into printing plates, and tested as follows.

The precursors presented in the Examples below could typically be handled for at least 4 hours under normal ambient light (depending on the intensity and type of light source) without background staining. Manufacturing Process

A raw aluminum alloy 1050-H18 web with a thickness of 150 μm was purchased from Sumitomo Corporation (Tokyo, Japan).

The aluminum web was subjected to the following electrolytic process at the speed of 12.5 meter per minute:
1. Washing with an aqueous alkaline solution containing sodium hydroxide (3.85 g/l) and sodium gluconate (0.95 g/l) at 65° C.;
2. Neutralizing with aqueous hydrochloric acid (2.0 g/l);
3. Washing with water;
4. Electrolytic graining in an aqueous electrolyte containing an aqueous solution of hydrochloric acid (8.0 g/l) and acetic acid (16 g/l), using carbon electrodes at 25° C. The current and charge density were 38.0 A/dm² and 70.0 C/dm², respectively;
5. Desmuting with an aqueous sodium hydroxide solution (2.5 g/l);
6. Neutralizing with an aqueous sulfuric acid solution (2 g/l);
7. Washing with water;
8. Anodizing in an aqueous electrolyte containing sulfuric acid (140 g/l) at 25° C.; the current and charge density were adjusted to produce an aluminum oxide layer having a thickness between 2.5 and 3.0 g/m²;
9. Washing with water;
10. Treating with:
   (a) an aqueous solution containing sodium dihydrogenphosphate (50 g/l) and sodium fluoride (0.8 g/l) at 75° C., thereby producing a phosphate fluoride hydrophilic coating on the substrate, or
   (b) an aqueous solution containing soldium silicate (30 g/l) at 75° C. was, thereby producing a sodium silicate (with a Si/Na ratio greater than about 2.0) hydrophilic coating on the substrate;
11. Washing with water at a temperature between 25 and 50° C.; and
12. Drying with hot air at 110° C.

Of note, the roughness of surface (Ra) of the thus treated aluminum web was between 0.4 and 0.6 μm.

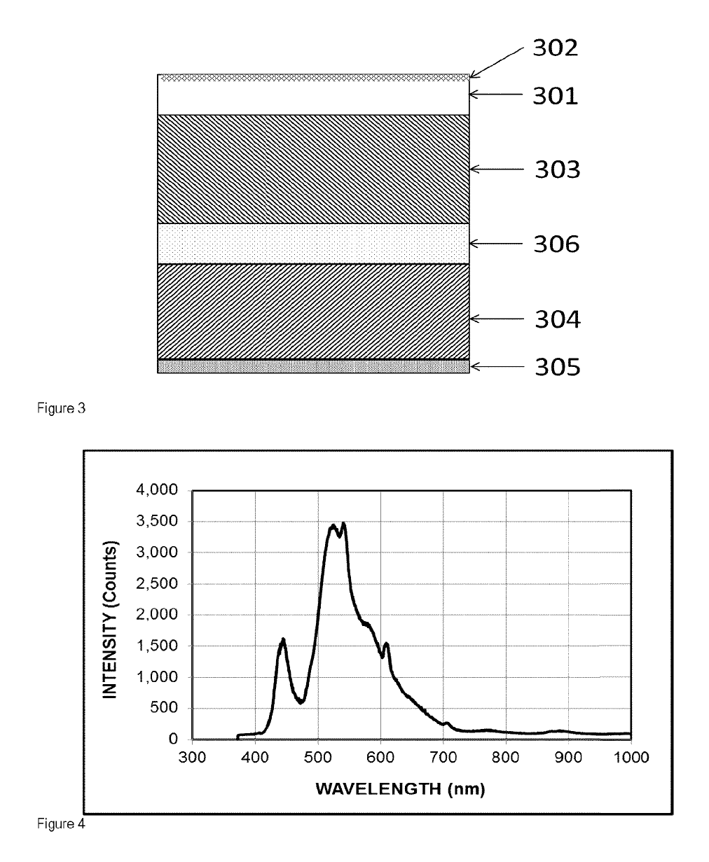

The produced aluminum substrate was then subjected to the following steps:
13. Coating the substrate with a coating solution/dispersion (of a composition as described in the Examples below) to produce a radiation sensitive imageable layer. The coating solution/dispersion was filtered through a 0.5 μm filter and then coated using a slot-die coating head.
14. Drying the radiation sensitive image layer at a temperature between 100 and 150° C. (specified in each Example below). The produced radiation sensitive imageable layer had a coating weight of 1.0 g/m².
15. Crosslinking the surface of the radiation sensitive imageable layer by exposing it to a visible laser light source. A SmartView® Compact LED Light, Model SV-CLED-8 (available from Cognex Corporation, Singapore), located 15 cm above the surface of the radiation sensitive imageable layer, was used for this purpose. FIG. 4 shows the emission spectrum of the SV-CLED-8 SmartView® Compact LED Light. This light source has a maximum luminous flux around 8,500 lumens and a surface of 0.1 m² (thus providing 85,000 lux (i.e. lumen/m²). Considering the production line speed (12.5 meter per minute), each area of the precursor was exposed for about 1.5 second.
16. Optionally, laminating the coated aluminum printing plate precursor on a plastic or paper sheet using an adhesive; and
17. Cutting to size.

### Comparative Tests

For comparison purposes, the precursors of the Examples below were also prepared without a crosslinked surface. These un-crosslinked precursors were produced in the manner described above, except that step 15 was omitted. This is shown in some figures as a crosslinking time equal to 0 seconds.

### Accelerated Aging Tests

For these tests, after production, the negative working precursors with and without the crosslinked surfaces were placed in an environmental control oven at 40° C. and 80% relative humidity (RH) for different duration. Then, the precursors were removed out from this environmental control oven and kept, under normal room conditions, in paper boxes to avoid exposure to the ambient light for one day.

### Laser Imaging Tests

For UV-violet laser imaging evaluation, the precursors were imaged by using a Cron Image Platesetter (Model UVP-4648EX, Hangzhou Cron Machinery & Electronics Co. Ltd., Hangzhou, China), equipped with forty eight (48) 405 nm solid state lasers (at the energy density specified in each Example below). They were then developed with a GSP50 developer available from Mylan Group (Travinh, Vietnam) using a Tungsung Processor (Model 88, available from Tungsung, Malacca, Malaysia) at 25° C. and 1.5 m/minute. The percent dot at different energy density was measured with a Techkon Spectroplate.

For near infrared (NIR) laser imaging evaluation, the precursors were imaged by using the Kodak Trendsetter (Model III, British Columbia, Canada) equipped with 830 nm solid state lasers at an energy density between 100 and 300 mJ/cm². They were then developed with a soap water solution (cleaning solution NP100), available from Mylan Group (Travinh, Vietnam) using a Tungsung Processor (Model 88, available from Tungsung, Malacca, Malaysia) at 25° C. and 1.5 m/minute.

The percent dot at different energy densities was measured with a Techkon Spectroplate. The dot gain depends on the imaging speed of the imageable layer. Here, dot gain is used to evaluate imaging speed. A higher dot gain means that photopolymerization due to laser irradiation occurs more quickly, i.e. that the imaging speed of the imageable layer is higher.

### Printing Tests

The imaged and developed printing plates were placed on a Heidelberg 48 press, a Heidelberg Quick Master 46-1 press, or a Heidelberg Speedmaster CD 74 UV (as noted in the Examples below), using (unless noted otherwise) a black ink (New Apex-G, available from DIC, Japan) and fountain solution (UF300, available from Mylan Group, Travinh, Vietnam).

### Scratch Tests

The various precursors described below were handled similarly during all operations, including imaging and printing. They were then inspected for scratches and fingerprints. The observations made are reported below.

### Example UV-1—UV-Violet Photopolymerizable Precursor Comprising a Conventional Free Radical Scavenger

A negative working CTP lithographic printing plate precursor with an imageable layer sensitive to UV-violet laser radiation was prepared as described above. The coating solution/dispersion had the following composition:

| Constituents | Function | Weight (Kg) |
|---|---|---|
| Hydroxy propyl cellulose | Binder | 3.50 |
| PolyXP 100 | Radical polymerizable | 42.2 |
| | copolymer | |
| Tanmer 10X | Radical polymerizable oligomer | 5.00 |
| Tuxedo ® 06C051D | Radical polymerizable oligomer | 38.0 |
| | Free radical coinitiator | |
| Triazine B | Free radical photoinitiator | 3.00 |
| | Photosensitizer | |
| 9-Vinyl Carbazole | Free radical stabilizer | 2.00 |
| 1H-1,2,4-triazole-3-thiol | Free radical scavenger | 1.00 |
| Basic Violet 3 | Visible colorant (dye) | 2.00 |
| Sipomer ® PAM-200 | Adhesion promoting agent | 3.00 |
| BYK 307 | Surfactant | 0.30 |
| 1-Methoxy-2-propanol | Solvent for coating | 2,000 |

The coating solution/dispersion was coated on an aluminum substrate that had been treated with a sodium dihydrogenphosphate and sodium fluoride (see step 10 a) above). The coated web was dried at a temperature of 110° C.

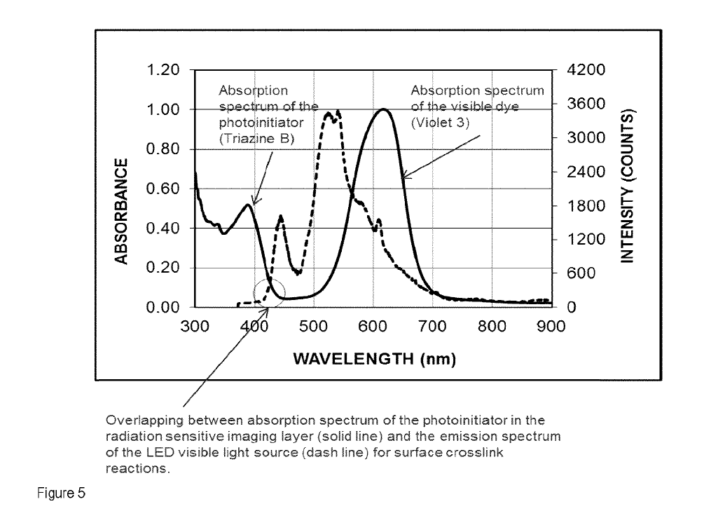

FIG. 5 shows the absorption spectrum of the produced radiation sensitive imageable layer (solid line) and the emission spectrum of the visible light source (dash line). In the absorption spectrum of the imageable layer, the band at around 390 nm which trails in the lower end of the visible range is due to the photoinitiator (which produces free radicals when excited). The strong band at about 620 nm is attributable to visible dye (which does not produce free radicals). The visible radiation that causes crosslinking is that at the visible wavelengths absorbed by the photoinitiator; that is between around 400 to 450 nm. This region, where the emission of the visible light sources and the absorption of the photoinitiator overlap is circled in the figure.

The precursor without a crosslinked surface was soft and slightly tacky, that is easy to scratch. In contrast, the precursor with a crosslinked surface was harder and not tacky.

The precursor with a crosslinked surface had an excellent surface scratching resistance for handling in transportation, storage and pre-press operation. It had no scratches or fingerprints. In contrast, the precursor without a crosslinked surface showed severe scratching and fingerprints after handling in the same manner.

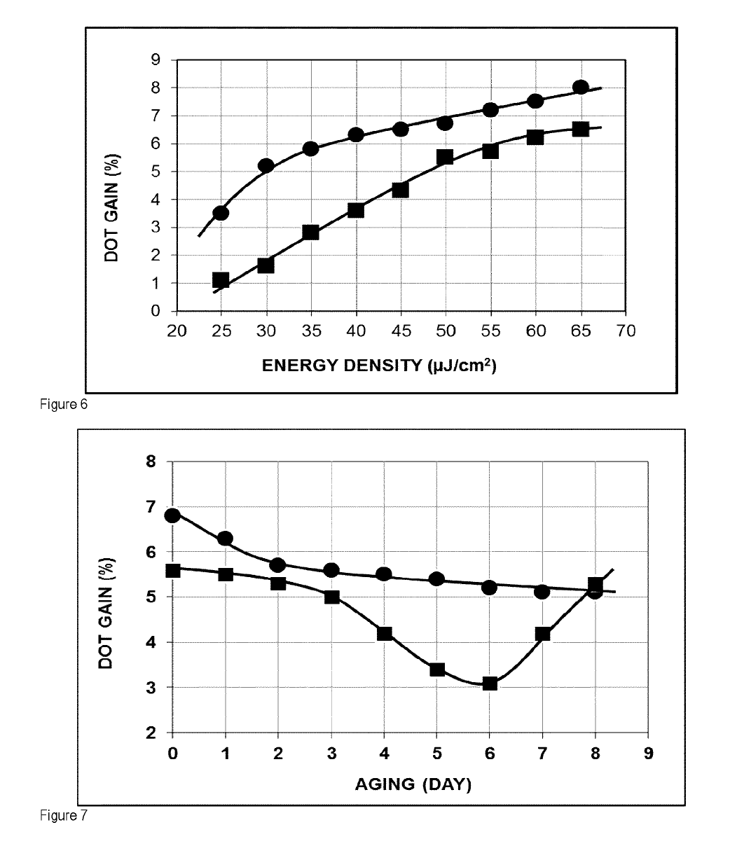

The precursor was imaged at energy densities varying between 25 and 65 μJ/cm². FIG. 6 shows the dot gains (measured at 50% dot from the target) measured at these energy densities for the printing plates with a radiation sensitive imaging layer with (circles) and without (squares) a crosslinked surface. This figure clearly shows that the printing plate with a crosslinked surface has significantly higher dot gain than the printing plate without a crosslinked surface. In other words, the crosslinked surface is a very effective oxygen barrier that prevents quenching of the free radicals by air oxygen molecules, and thus provides faster laser imaging speeds.

The imaged and developed printing plates were mounted on a Heidelberg 46-1 press. The printing plate with a crosslinked surface allowed printing over 10,000 copies with high resolution image and no deterioration, while the printing plate without a crosslinked surface only allowed printing under 6,000 copies of a lesser (but still good) quality.

Aging tests were also performed. More specifically, the precursors were first aged at 40° C. and 80% RH for different periods of time. FIG. 7 shows the dot gains (measured at 50% dot target) after imaging at 50 μJ/cm² of the precursor with (circles) and without (squares) a crosslinked surface. Both before and after aging and storage, the printing plate with a crosslinked surface produced higher dot gains (faster imaging speeds) than the printing plate without a crosslinked surface. The dot gain of the plate with a crosslinked surface decreased steadily, but slowly, for all 8 days and that, without staining background. In contrast, the dot gain of the plate without a crosslinked surface decreased drastically after only 3 days. Furthermore, the background was also severely stained. In fact, the printing plate could not be used for printing because of its dirty background. Again, these results clearly confirm that the crosslinked surface is a very effective oxygen barrier that provide fast laser imaging speed during laser imaging. This crosslinked surface is also a very effective barrier that reduces thermal fogging susceptibility.

### Example UV-2—Precursor Similar to Example UV-1, but Laminated on a PET Sheet

A negative working CTP lithographic printing plate precursor with an imageable layer sensitive to UV-violet laser radiation was prepared as reported in Example UV-1, except that after the radiation sensitive imageable layer had been crosslinked using the visible laser light source, the coated aluminum web was laminated on a bioriented polyethylene terephthalate (PET) film having a thickness of 130 μm using a solvent based adhesive (JK760, available from Henkel, Vietnam). (In other words, optional step 16 above was carried out.) The laminated printing plate precursor was then cut to size and ready for use.

The computer-to-plate precursor was imaged at the energy density 50 μJ/cm². The imaged and developed printing plate with a crosslinked surface was mounted on a Heidelberg 46-1 press and allowed printing over 10,000 copies with high resolution image and no deterioration. The laminated substrate performed well during all operations.

The performances of this precursor were compared with that of an identical precursor without a crosslinked surface. The test results were as follows:
the precursor without a crosslinked surface was soft and slightly tacky, while the precursor with a crosslinked surface was not tacky; the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 3 to 8% (crosslinked) vs around 1 to 7% (un-crosslinked) for the fresh plates);
the precursor with a crosslinked surface had longer shelf-life than the precursor without a crosslinked surface (for example, the substrate would get a dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=10,000 (crosslinked) vs under 6,000 (un-crosslinked)).

### Example UV-3—Precursor Similar to Example UV-1, but Laminated on a Polymer Coated Paper Sheet

A negative working CTP precursor sensitive to UV-violet laser radiation was prepared as reported in Example UV-1, except that after the radiation sensitive imageable layer had been crosslinked using the visible laser light source, the coated aluminum web was laminated on a polymer coated paper having a thickness of 130 μm using solvent based adhesive (JK760, available from Henkel, Vietnam). The precursor was then cut to size and ready for use.

The computer-to-plate precursor was imaged at an energy density 50 μJ/cm². The imaged and developed printing plate was mounted on a Heidelberg 48 press and allowed printing over 10,000 copies with high resolution image and no deterioration. The laminated substrate performed well during all operations.

The performances of this precursor were compared with that of an identical precursor without a crosslinked surface. The test results were as follows:
the precursor without a crosslinked surface was soft and slightly tacky, while the precursor with a crosslinked surface was harder and not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 3 to 8% (crosslinked) vs around 1 to 7% (un-crosslinked) for the fresh plates);
the precursor with a crosslinked surface had longer shelf-life than the precursor without a crosslinked surface (for example, the substrate get dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=10,000 (crosslinked) vs under 6,000 (un-crosslinked)).

### Example UV-4—Precursor Similar to Example UV-1, but with Post-Development UV Exposure

A negative working computer-to-plate precursor sensitive to UV-violet laser radiation was prepared according to Example UV-1. Then, after laser imaging and development as reported in Example UV-1, the plate was exposed to an array of LED light source having an emission wavelength at 395 nm and power 8 W/cm² (Model FireFlex 75X50WC, available from Phoseon Technology, USA) at the speed of 1 meter per minute (UV curing). Such UV-cured precursors are suitable for long run printing and use with UV curable inks.

The UV-cured plate was mounted on a Heidelberg 46-1 press to print over 100,000 copies with high resolution image and no deterioration. The UV-cured plate was also mounted on a Heidelberg Speedmaster CD 74 UV offset press to print over 20,000 copies with high resolution image using UV curable inks (Suncure, available from Sun Chemical).

The performances of this precursor were compared with that of an identical precursor without a crosslinked surface. The test results were as follows:
the precursor without a crosslinked surface was soft and slightly tacky, while the precursor with a crosslinked surface was harder and not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 3 to 8% (crosslinked) vs around 1 to 7% (un-crosslinked) for the fresh plates.
the precursor with a crosslinked surface had longer shelf-life than the precursor without a crosslinked surface (for example, the substrate get dirty background after 9 days (crosslinked) vs 6 days (un-crosslinked) in the oven at 40° C. and 80% humidity; and
the precursors with and without crosslinked surface (after post exposure with UV light) both allowed printing over 20,000 copies with high resolution image on papers.

### Example UV-5—Precursor Comprising PolyXP 120S as Free Radical Scavenger

A negative working computer-to-plate precursor comprising a UV-violet laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyXP 100 | Radical polymerizable | 32.2 |
| | copolymer | |
| Tanmer 10X | Radical polymerizable oligomer | 5.00 |
| Tuxedo ® 06C051D | Radical polymerizable oligomer | 38.0 |
| | Free radical coinitiator | |
| Triazine B | Free radical photoinitiator | 3.00 |
| | Photosensitizer | |
| 9-Vinyl Carbazole | Free radical stabilizer | 2.00 |
| PolyXP 120S | Free radical scavenger | 11.0 |
| Basic Violet 3 | Visible colorant (dye) | 2.00 |
| Sipomer ® PAM-200 | Adhesion promoting agent | 3.00 |
| BYK 307 | Surfactant | 0.30 |
| Dowanol PM | Solvent for coating | 2,000 |

The coating solution/dispersion was coated on a substrate that had been treated with a sodium dihydrogenphosphate and sodium fluoride (see step 10 a) above). The coated web was then dried at 110° C. using hot air.

The precursor was imaged at the energy density between 20 and 80 μJ/cm². The imaged and developed printing plate was mounted on the Heidelberg 48 press and allowed print over 10,000 copies with high resolution image and no deterioration.

The precursor with a crosslinked surface was subjected to the accelerated aging test at 40° C. and 80% RH. The results were similar to that obtained for the precursor of Example UV-1—no background staining after 8 days in the environmental chamber.

The performances of this precursor were compared with that of an identical precursor without a crosslinked surface. The test results were as follows:
the precursor without a crosslinked surface was soft and slightly tacky, while the precursor with a crosslinked surface was harder and not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 3 to 8% (crosslinked) vs around 1 to 7% (un-crosslinked) for the fresh plates.
the precursor with a crosslinked surface had longer shelf-life than the precursor without a crosslinked surface (for example, the substrate get dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=10,000 (crosslinked) vs under 6,000 (un-crosslinked)).

### Example UV-6—Precursor Comprising PolyBlue 15A as a Visible Colorant

A negative working computer-to-plate comprising a UV-violet laser radiation sensitive imageable layer having a crosslinked surface was produced with a coating solution/dispersion of the following composition:

| Constituents | Function | Weight (Kg) |
|---|---|---|
| Hydroxy propyl cellulose | Binder | 3.50 |
| PolyXP 100 | Radical polymerizable | 37.2 |
| | copolymer | |
| Tanmer 10X | Radical polymerizable oligomer | 5.00 |
| Tuxedo ® 06C051D | Radical polymerizable oligomer | 38.0 |
| | Free radical coinitiator | |
| Triazine B | Free radical photoinitiator | 3.00 |
| | Photosensitizer | |
| 9-Vinyl Carbazole | Free radical stabilizer | 2.00 |
| 1H-1,2,4-triazole-3-thiol | Free radical scavenger | 1.00 |
| PolyBlue 15A | Visible colorant (pigment) | 7.00 |
| Sipomer ® PAM-200 | Adhesion promoting agent | 3.00 |
| BYK 307 | Surfactant | 0.30 |
| Dowanol PM | Solvent for coating | 2,000 |

The coating solution/dispersion was coated on a substrate that had been treated with a sodium silicate solution (see step 10 b) above). The coated web was then dried at 110° C.

The plate was imaged at the energy density between 20 and 80 μJ/cm². The imaged and developed plate was mounted on the Heidelberg 48 press and allowed printing over 35,000 copies (because of the substrate treated with sodium silicate (compared to the previous examples)) with high resolution image and no deterioration.

The plate with a crosslinked surface was subjected to the accelerated aging test at 40° C. and 80% RH. The results were similar to that obtained for the precursor of Example UV-1—no background staining after 8 days in the environmental chamber.

The performances of this precursor were compared with that of an identical precursor without a crosslinked surface. The test results were as follows:
the precursor without a crosslinked surface was soft and slightly tacky, while the precursor with a crosslinked surface was harder and not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 3 to 8% (crosslinked) vs around 1 to 7% (un-crosslinked) for the fresh plates.
the precursor with a crosslinked surface had longer shelf-life than the precursor without a crosslinked surface (for example, the substrate get dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=35,000 (crosslinked) vs under 20,000 (un-crosslinked)).

### Example UV-7—Precursor Comprising PolyXP 1305 as Free Radical Scavenger

A negative working computer-to-plate precursor comprising a UV-violet laser radiation sensitive imageable layer having a crosslinked surface was produced using a coating composition of following composition:

| Constituents | Function | Weight (Kg) |
|---|---|---|
| Hydroxy propyl cellulose | Binder | 3.50 |
| PolyXP 100 | Radical polymerizable | 25.2 |
| | copolymer | |
| Tanmer 10X | Radical polymerizable oligomer | 5.00 |
| Tuxedo ® 06C051D | Radical polymerizable oligomer | 38.0 |
| | Free radical coinitiator | |
| Triazine B | Free radical photoinitiator | 3.00 |
| | Photosensitizer | |
| 9-Vinyl Carbazole | Free radical stabilizer | 2.00 |
| PolyXP 130S | Free radical scavenger | 10.0 |
| PolyBlue 15A | Visible colorant (pigment) | 7.00 |
| Sipomer ® PAM-200 | Adhesion promoting agent | 3.00 |
| BYK 307 | Surfactant | 0.30 |
| Dowanol PM | Solvent for coating | 2,000 |

The coating solution/dispersion was coated on a substrate that had been treated with a sodium silicate solution (see step 10 b) above). The coated web was then dried at 110.0 using hot air.

The computer-to-plate precursor was imaged at the energy density between 20 and 80 μJ/cm². The imaged and developed printing plate was mounted on the Heidelberg 48 press to print over 35,000 copies with high resolution image and no deterioration.

The precursor with crosslinked surface was subjected to the accelerated aging test at 40° C. and 80% RH. The results were similar to that obtained for the precursor of Example UV-1—no background staining after 8 days in the environmental chamber.

The performances of this precursor were compared with that of an identical precursor without a crosslinked surface. The test results were as follows:
the precursor without a crosslinked surface was soft and slightly tacky, while the precursor with a crosslinked surface was harder and not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 3 to 8% (crosslinked) vs around 1 to 7% (un-crosslinked) for the fresh plates.
the precursor with a crosslinked surface had longer shelf-life than the precursor without a crosslinked surface (for example, the substrate get dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=35,000 (crosslinked) vs under 20,000 (un-crosslinked)).

### Example UV-8—Precursor Additionally Comprising a Visible Light Reflective Pigment

A negative working computer-to-plate precursor comprising a UV-violet laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyXP 100 | Radical polymerizable | 25.2 |
| | copolymer | |
| Tanmer 10 | Radical polymerizable oligomer | 5.00 |
| Tuxedo ® 06C051D | Radical polymerizable oligomer | 38.0 |
| | Free radical coinitiator | |
| Triazine B | Free radical photoinitiator | 3.00 |
| | Photosensitizer | |
| 9-Vinyl Carbazole | Free radical stabilizer | 2.00 |
| PolyXP 130S | Free radical scavenger | 10.0 |
| PolyBlue 15A | Visible colorant (pigment) | 6.00 |
| 9W1100 White Pigment | Visible light reflecting pigment | 1.00 |
| Sipomer ® PAM-200 | Adhesion promoting agent | 3.00 |
| BYK 307 | Surfactant | 0.30 |
| Dowanol PM | Solvent for coating | 2,000 |

The coating solution/dispersion was coated on a substrate that had been treated with a sodium silicate solution (see step 10 b) above). The coated web was then dried at 110° C.

Compared to that of Example UV-7 (crosslinked and un-crosslinked), the crosslinked surface of the imageable layer was found to be harder. This indicates that the titanium dioxide pigment enhanced surface crosslinking reactions during exposure to the LED visible light. This was observed to further reduce tackiness and further increase physical resistance.

The precursor was imaged at the energy density between 20 and 80 μJ/cm².

FIG. 8 shows the dot gains measured when imaging this plate and that of Example UV-7 at 50 μJ/cm² (both crosslinked). The dot gain for the precursor comprising TiO₂ light reflective pigment was lower than that of Example UV-7. It decreased linearly with the period of exposure of the radiation imageable layer to the LED visible light. These results indicate that surface crosslinks reactions were more complete in the presence of the TiO₂ light reflective pigment. Therefore, less overall crosslink reactions occurred in the laser imaging step. Without TiO₂, the surface crosslink reactions were less complete. More surface crosslink reactions occurred during laser imaging. That is why the dot gain was higher for radiation imageable layer exposed to the LED visible light less than 60 seconds. For exposure times longer than 60 seconds, the dot gain of Example UV-7 is higher than that Example UV-8, however this was found to be mainly due to background staining as will be shown in the next figure. It is also due to the reflection of violet laser light (405 nm) by the titanium dioxide reflective pigment.

The precursor was developed with GSP50 developer at 25° C. at 1.5 meter per minute to produce high resolution image. The imaged and developed plate was mounted on the Heidelberg 46-1 press and allowed printing over 50,000 copies with high resolution image and no deterioration. The printing quality was higher than that of Example UV-7 (crosslinked and un-crosslinked).

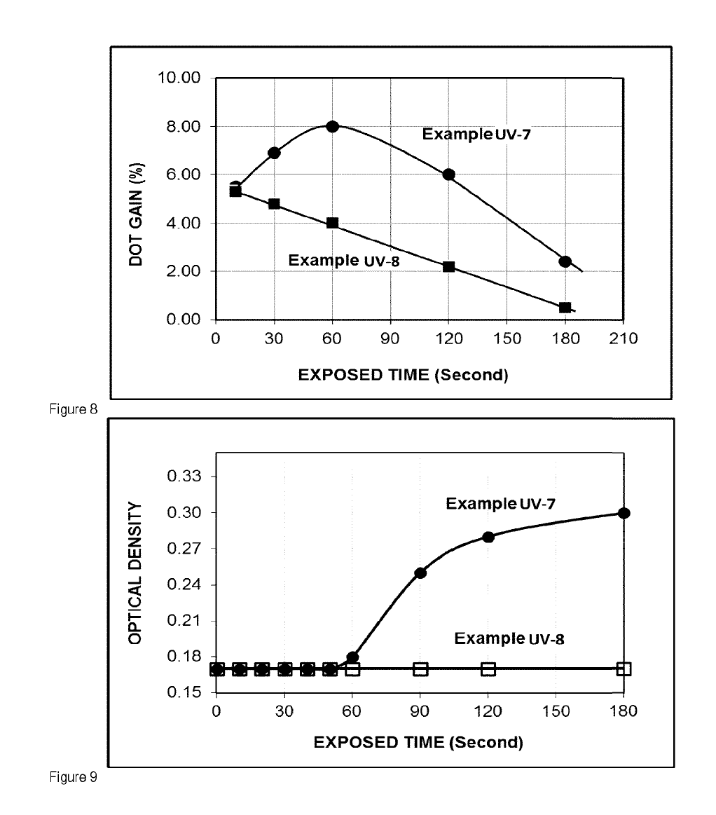

FIG. 9 shows the optical density of printed plates according to Examples UV-7 and UV-8, developed after crosslinked but without imaging, as a function of the duration of exposition to visible light for crosslinking. This figure shows that background staining start occurring only after about 50 second exposition in the absence of light reflective pigments (Example UV-7) and does not occur in the measured time period when such pigment is present (Example UV-8).

The precursor with the crosslinked surface was subjected to the accelerated aging test at 40° C. and 80% RH. There was no background staining after 8 days in the environmental chamber. During and after aging, the dot gain for this precursor was almost the same as of Example UV-7 (crosslinked).

### Example UV-9—Precursor Comprising an Oligomeric Photoinitiator and a Visible Light Reflective Pigment

A negative working computer-to-plate precursor comprising a UV-violet laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyXP 100 | Radical polymerizable | 25.2 |
| | copolymer | |
| Tanmer 10X | Radical polymerizable oligomer | 4.00 |
| Tuxedo ® 06C051D | Radical polymerizable oligomer | 38.0 |
| | Free radical coinitiator | |
| Tanmer 4FR6X | Free radical photoinitiator | 6.00 |
| | (oligomer) Photosensitizer | |
| 9-Vinyl Carbazole | Free radical stabilizer | 2.00 |
| 1H-1,2,4-triazole-3-thiol | Free radical scavenger | 1.00 |
| PolyBlue 15A | Visible colorant (pigment) | 6.00 |
| 9W1100 White Pigment | Visible light reflecting pigment | 1.00 |
| Sipomer ® PAM-200 | Adhesion promoting agent | 3.00 |
| BYK 307 | Surfactant | 0.30 |
| 1-Methoxy-2-propanol | Solvent for coating | 2,000 |

The coating solution/dispersion was coated on a substrate that had been treated with a sodium silicate solution (see step 10 b) above. The coated web was then dried at 110° C. Then, the web was exposed to the LED visible light at 85,000 lumen/m² for 5 seconds.

The precursor was imaged at the energy density between 20 and 80 μJ/cm², then developed with the GSP50 developer at 25° C. at 1.5 meter per minute to give high resolution image. The developed plate was placed on the Heidelberg 46-1 press and allowed printing over 20,000 copies with high resolution image and no deterioration.

The performances of this precursor were compared with that of an identical precursor without a crosslinked surface. As in Examples UV-6, the crosslinked precursor/plate performed better than the un-crosslinked precursor/plate in terms of tackiness, surface scratching resistance, imaging speed, shelf-life, and number of copies printed.

### Example UV-10—Precursor Comprising a Copolymer Photoinitiator and Visible Light Reflective Pigment

A negative working computer-to-plate precursor comprising a UV-violet laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyXP 100 | Radical polymerizable | 20.2 |
| | copolymer | |
| Tanmer 10X | Radical polymerizable oligomer | 5.00 |
| Tuxedo ® 06C051D | Radical polymerizable oligomer | 38.0 |
| | Free radical coinitiator | |
| PolyFR 102 | Copolymeric free radical | 15.0 |
| | photoinitiator Photosensitizer | |
| 9-Vinyl Carbazole | Free radical stabilizer | 2.00 |
| 1H-1,2,4-triazole-3-thiol | Free radical scavenger | 1.00 |
| PolyBlue 15A | Visible colorant (pigment) | 6.00 |
| 9W1100 White Pigment | Visible light reflecting pigment | 1.00 |
| Sipomer ® PAM-200 | Adhesion promoting agent | 3.00 |
| BYK 307 | Surfactant | 0.30 |
| 1-Methoxy-2-propanol | Solvent for coating | 2,000 |

The coating solution/dispersion was coated on a substrate that had been treated with a sodium silicate solution (see step 10 b) above). The coated web was then dried at 110° C. Then, the web was exposed to the LED visible light at 85,000 lumen/m² for 5 seconds.

The precursor was imaged at the energy density between 20 and 80 μJ/cm², then developed with the GSP50 developer at 25° C. and 1.5 meter per minute to give high resolution image. The developed plate was placed on the Heidelberg 46-1 press and allowed printing over 20,000 copies with high resolution image and no deterioration.

The performances of this precursor were compared with that of an identical precursor without a crosslinked surface. As in Examples UV-6, the crosslinked precursor/plate performed better than the un-crosslinked precursor/plate in terms of tackiness, surface scratching resistance, imaging speed, shelf-life, and number of copies printed.

### Example UV-11—Precursor for On-Press Development

A negative working computer-to-plate precursor comprising a UV-violet laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyNP ®150Y | Radical polymerizable | 41.5 |
| | copolymer (particles) | |
| Tuxedo ® 06C051D | Radical polymerizable oligomer | 32.0 |
| | Free radical coinitiator | |
| Triazine B | Free radical photoinitiator | 1.00 |
| 9-Vinyl Carbazole | Free radical stabilizer | 2.20 |
| 1H-1,2,4-triazole-3-thiol | Free radical scavenger | 1.00 |
| PolyBlue 15A | Visible colorant (pigment) | 5.00 |
| 9W1100 White Pigment | Visible light reflecting pigment | 1.00 |
| Sipomer ® PAM-200 | Adhesion promoting agent | 2.00 |
| BYK 307 | Surfactant | 0.10 |
| Dowanol PM | Solvent for coating | 2,000 |

The coating solution/dispersion was coated on a substrate that had been treated with a sodium silicate solution (see step 10 b) above). The coated web was then dried at 110° C. using hot air. Then, the web was exposed to the LED visible light at 85,000 lumen/m² for 5 seconds.

The precursor was imaged at the energy density between 20 and 80 μJ/cm², then preheated at 100° C. and at a speed of 1.5 meter per minute. The preheated plate was placed on the Heidelberg 46-1 press for development using ink and fountain solution. A clean image was obtained after 20 revolutions. It allowed printing over 30,000 copies with high resolution image and no deterioration.

The performances of this precursor were compared with that of an identical precursor without a crosslinked surface. The crosslinked precursor/plate performed better than the un-crosslinked precursor/plate in terms of tackiness, surface scratching resistance, imaging speed, shelf-life, and number of copies printed.

### Example UV-12—Precursor for On-Press Development Comprising a Copolymer Photoinitiator

A negative working computer-to-plate precursor comprising a UV-violet laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyNP ®150Y | Radical polymerizable | 26.5 |
| | copolymer (particles) | |
| Tuxedo ® 06C051D | Radical polymerizable oligomer | 32.0 |
| | Free radical coinitiator | |
| PolyFR 104 | Copolymer free radical | 15.0 |
| | photoinitiator (particles) | |
| 9-Vinyl Carbazole | Free radical stabilizer | 2.20 |
| 1H-1,2,4-triazole-3-thiol | Free radical scavenger | 1.00 |
| PolyBlue 15A | Visible colorant (pigment) | 5.00 |
| 9W1100 White Pigment | Visible light reflecting pigment | 1.00 |
| Sipomer ® PAM-200 | Adhesion promoting agent | 2.00 |
| BYK 307 | Surfactant | 0.10 |
| Dowanol PM | Solvent for coating | 2,000 |

The coating solution/dispersion was coated on a substrate that had been treated with a sodium silicate solution (see step 10 b) above). The coated web was then dried at 110° C. using hot air. Then, the web was exposed to the LED visible light at 85,000 lumen/m² for 5 seconds.

The precursor was imaged at the energy density between 20 and 80 μJ/cm², then preheated at 100° C. and at a speed of 1.5 meter per minute. The preheated plate was placed on the Heidelberg 46-1 press for development using ink and fountain solution. A clean image was obtained after 20 revolutions. It allowed printing over 30,000 copies with high resolution image and no deterioration.

The performances of this precursor were compared with that of an identical precursor without a crosslinked surface. The crosslinked precursor/plate performed better than the un-crosslinked precursor/plate in terms of tackiness, surface scratching resistance, imaging speed, shelf-life, and number of copies printed.

### Example NIR-1—NIR Photopolymerizable Precursor

A negative working computer-to-plate precursor comprising a NIR laser radiation sensitive imageable layer having a crosslinked surface was produced using a coating solution/dispersion of the following composition:

| Constituents | Function | Weight (Kg) |
|---|---|---|
| Hydroxy propyl cellulose | Binder | 3.50 |
| PolyNP ®150Y | Radical polymerizable | 30.0 |
| | copolymer (particles) | |
| Tuxedo ® 06C051D | Radical polymerizable oligomer | 34.0 |
| | Free radical coinitiator | |
| Triazine B | Free radical photoinitiator | 1.00 |
| 9-Vinyl Carbazole | Free radical stabilizer | 2.20 |
| PolyNP ®120S | Radical polymerizable | 10.0 |
| | copolymer (particles) | |
| | Free radical scavenger | |
| PolyNP ® 795PD | Photosensitizer (particles) | 11.3 |
| PolyBlue 15A | Visible colorant (pigment) | 5.00 |
| Sipomer ® PAM-200 | Adhesion promoting agent | 2.00 |
| BYK 307 | Surfactant | 0.30 |
| Dowanol PM | Solvent for coating | 2,000 |

The coating solution/dispersion was coated on a substrate that had been treated with a sodium silicate solution (see step 10 b) above). The coated web was then dried at 110° C. using hot air.

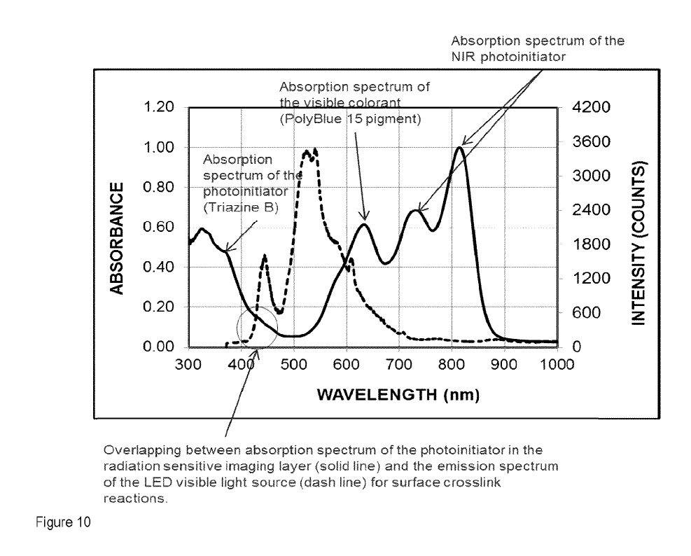

FIG. 10 shows the absorption spectrum of the NIR radiation sensitive imageable layer (solid line) and the emission spectrum of the visible light source (dash line). In the absorption spectrum of the imageable layer, the band at around 330 nm, which trails in the lower end of the visible range is due to the photoinitiator (which produces free radicals when excited). The strong band at about 630 nm is attributable to the visible colorant (PolyBlue 15 pigment, which does not produce free radicals). The stronger bands at 730 and 810 nm are attributable to the near infrared dye (used as a photosensitizer). The visible radiation that causes crosslinking is that at the wavelengths absorbed by the photoinitiator; that is between around 400 and 440 nm, This region where the emission of the visible light sources and the absorption of the triazine B photoinitiator (added to the NIR sensitive imageable layer to allow surface crosslinking with visible light) overlap is circled in the figure.

As with the other precursors above, the precursor with a crosslinked surface was less tacky and more physically resistant than that without a crosslinked surface.

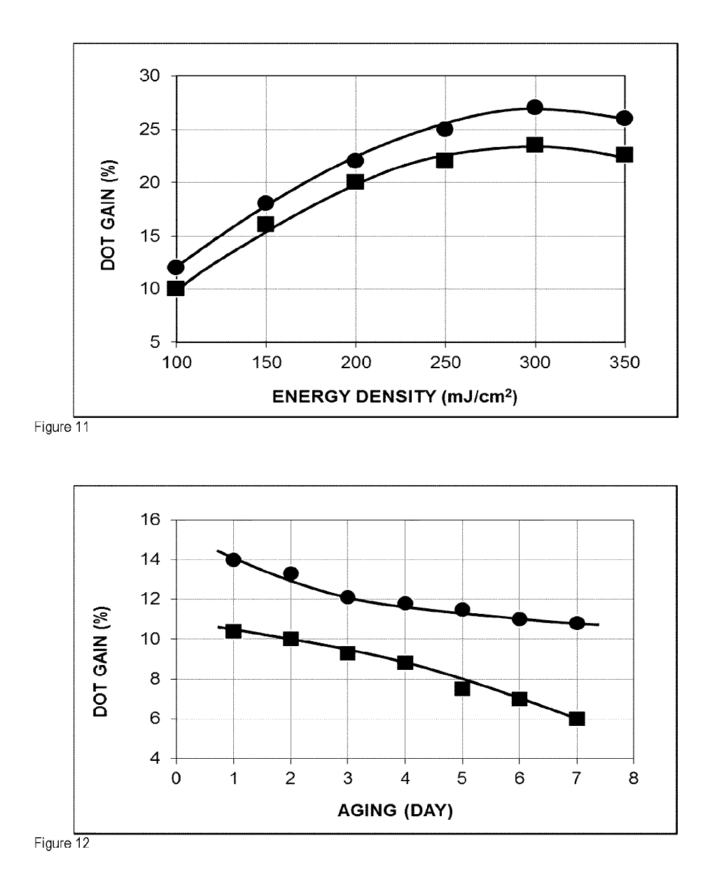

The precursor was imaged at an energy density between 100 and 350 mJ/cm². FIG. 11 shows the dot gains at different energy densities for the fresh (un-aged) NIR radiation sensitive computer-to-plates printing plate with (circles) and without (squares) a crosslinked surface. These results clearly indicate that, at these energy densities, the printing plate with a crosslinked surface has higher dot gain than the printing plate without it. These laser imaging results clearly confirm that the crosslinked surface is a very effective oxygen barrier that prevents quenching of the free radicals by the air oxygen molecules and thus provides fast laser imaging speeds.

The imaged and developed printing plate was mounted on the Heidelberg Quick Master 46-1 press and allowed printing over 20,000 copies with high resolution image and no deterioration, while the printing plate without a crosslinked surface only allowed printing 15,000 copies of a lesser (but still good) quality.

The precursor with the crosslinked surface was subjected to the accelerated aging test at 40° C. and 80% RH. There was no background staining after 10 days in the environmental chamber. FIG. 12 shows the dot gains at 120 mJ/cm² for the printing plates comprising a NIR laser radiation sensitive imageable layer with (circles) and without (squares) a crosslinked surface after aging at 40° C. and 80% RH for different duration. After aging and storage, the printing plate with a crosslinked surface produced higher dot gains than the printing plate without a crosslinked surface. The dot gain of the printing plate with a crosslinked surface decreased steadily, but slowly, for 7 days at 40° C. and 80% RH. In contrast, the printing plate without a crosslinked surface decreased more rapidly, especially after 3 days at 40° C. and 80% RH. Furthermore, after 10 days in the environment oven, the background of the printing plate with a crosslinked surface was clean, while the printing plate without a crosslinked surface was severely stained and could not be used for printing. Again, these results clearly confirm that the crosslinked surface is a very effective oxygen barrier, providing fast laser imaging speed during laser imaging. This crosslinked surface is also a very effective barrier that reduces thermal fogging susceptibility.

As will be shown in Example NIR-5 below, this precursor can also be imaged using UV-violet radiation.

### Example NIR-2—Precursor Similar to Example NIR-1, but Laminated on a PET Sheet

A negative working computer-to-plate precursor sensitive to NIR radiation was produced similarly to Example NIR-1, except that after the radiation sensitive imaging layer was crosslinked using the visible laser light source, the coated aluminum web was laminated on a bioriented polyethylene terephthalate film having a thickness of 130 μm using a solvent based adhesive (JK760, available from Henkel, Vietnam). The laminated precursor was then cut to size and ready for use.

The precursor was imaged at an energy density 200 mJ/cm². Development was carried out by washing the imaged precursor with water containing 0.20% of sodium lauryl sulphonate at 25° C. and 1.5 meter per minute.

The imaged and developed printing plate was mounted on a Heidelberg 46-1 press and allowed printing over 20,000 copies with high resolution image and no deterioration. The laminated substrate performed well during all operations.

The performances of this precursor were compared with that of an identical precursor without a crosslinked surface. The test results were as follows:
the precursor without a crosslinked surface was soft and slightly tacky, while the precursor with a crosslinked surface was harder and not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 11 to 14% (crosslinked) vs around 7 to 10% (un-crosslinked) for the fresh and aged plates;
the precursor with a crosslinked surface had longer shelf-life than the precursor without a crosslinked surface (for example, the substrate got a dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=20,000 (crosslinked) vs under 15,000 (un-crosslinked)).

As will be shown in Example NIR-5 below, this precursor can also be imaged using UV-violet radiation.

### Example NIR-3—Precursor Similar to Example NIR-1, but Laminated on a Polymer Coated Paper Sheet

A negative working computer-to-plate precursor sensitive to NIR radiation was produced similarly to Example NIR-1, except that after the radiation sensitive imaging layer was crosslinked using the visible laser light source, the coated aluminum web was laminated on a polymer coated paper having a thickness of 130 μm using a solvent based adhesive (JK670, available from Henkel, Vietnam). The laminated CTP was then cut to size and ready for use.

The precursor was imaged at an energy density 200 mJ/cm². Development was carried out by washing the imaged precursor with water containing small amount of NP100 at 25° C. and 1.5 meter per minute.

The imaged and developed printing plate was mounted on a Heidelberg 46-1 press and allowed printing over 10,000 copies with high resolution image and no deterioration. The laminated substrate performed well during all operations.

The performances of this precursor were compared with that of an identical precursor without a crosslinked surface. The test results were as follows:
the precursor without a crosslinked surface was soft and slightly tacky, while the precursor with a crosslinked surface was not tacky;
the precursor with a crosslinked surface had an excellent surface scratching resistance, while the precursor without a crosslinked surface did not;
the precursor with a crosslinked surface had faster imaging speed than the precursor without a crosslinked surface (for example, dot gain was around 11 to 14% (crosslinked) vs around 7 to 10% (un-crosslinked) for the fresh and aged plates);
the precursor with a crosslinked surface had longer shelf-life than the precursor without a crosslinked surface (for example, the substrate got a dirty background after 9 days (crosslinked) vs 6 days (un-crosslinked) in the oven at 40° C. and 80% humidity; and
the printing plate with a crosslinked surface allowed printing more copies of a higher quality than the printing plate without a crosslinked surfaces (number of copies=20,000 (crosslinked) vs under 15,000 (un-crosslinked)).

As will be shown in Example NIR-5 below, this precursor can also be imaged using UV-violet radiation.

### Example NIR-4—Precursor Additionally Comprising a Visible Light Reflective Pigment

A negative working computer-to-plate precursor comprising a NIR laser radiation sensitive imageable layer having a crosslinked surface was produced using a coating composition of the following composition:

| Constituent | Function | Weight (Kg) |
|---|---|---|
| Hydroxy propyl cellulose | Binder | 3.50 |
| PolyNP ®150Y | Radical polymerizable | 31.0 |
| | copolymer (particles) | |
| Tuxedo ® 06C051D | Radical polymerizable oligomer | 32.0 |
| | Free radical coinitiator | |
| Triazine B | Free radical photoinitiator | 1.00 |
| 9-Vinyl Carbazole | Free radical stabilizer | 2.20 |
| PolyNP ®120S | Radical polymerizable | 10.0 |
| | copolymer (particles) | |
| | Free radical scavenger | |
| PolyNP ® 795PD | Photosensitizer (particles) | 11.3 |
| PolyBlue 15A | Visible colorant (pigment) | 5.00 |
| 9W1100 White Pigment | Visible light reflecting pigment | 1.00 |
| Sipomer ® PAM-200 | Adhesion promoting agent | 2.00 |
| BYK 307 | Surfactant | 0.30 |
| Dowanol PM | Solvent for coating | 2,000 |

The coating solution/dispersion was coated on a substrate that had been treated with a sodium silicate solution (see in step 10 b) above). The coated web was then dried at 110° C.

The surface of the crosslinked imageable layer was found to be harder (more resistant) than that obtained in Example NIR-1 (crosslinked and un-crosslinked). This indicates that the titanium dioxide pigment enhanced surface crosslinking reactions during exposure to the LED visible light. This was observed to further increase physical resistance.

The computer-to-plate was imaged at the energy density between 100 and 350 mJ/cm² and washed with water comprising 0.2% sodium lauryl sulphonate at 25° C. at 1.5 meter per minute to produce high resolution image. The dot gain for this precursor was higher than that of Example NIR-1 (crosslinked and un-crosslinked).

The imaged and developed plate was mounted on a Heidelberg-46-1 press and allowed printing over 50,000 copies with high resolution image and no deterioration. The printing quality was higher than that of Example NIR-1 (crosslinked and un-crosslinked).

The precursor with the crosslinked surface was subjected to the accelerated aging test at 40° C. and 80% RH. There was no background staining after 8 days in the environmental chamber. During and after aging, the dot gain for this precursor was higher than that of Example NIR-1 (crosslinked and un-crosslinked).

As will be shown in Example NIR-5 below, this precursor can also be imaged using UV-violet radiation.

### Example NIR-5—Precursor for On-Press Development

A negative working computer-to-plate precursor comprising an imageable layer having a crosslinked surface, which is sensitive to NIR laser radiation, and as stated above is also sensitive to UV-violet radiation, was produced using a coating solution/dispersion of the following composition:

| Constituents | Function | Weight (Kg) |
|---|---|---|
| Hydroxy propyl cellulose | Binder | 3.50 |
| PolyNP ®150Y | Reactive Copolymer (particles) | 39.5 |
| Tuxedo ® 06C051D | Radical polymerizable oligomer | 32.0 |
| | Free radical coinitiator | |
| Triazine B | Free radical photoinitiator | 1.00 |
| 9-Vinyl Carbazole | Free radical stabilizer | 2.20 |
| 1H-1,2,4-triazole-3-thiol | Free radical scavenger | 1.00 |
| ADS798BD | Near Infrared Sensitizer | 2.00 |
| PolyBlue 15A | Visible colorant (pigment) | 5.00 |
| 9W1100 White Pigment | Visible light reflecting pigment | 1.00 |
| Sipomer ® PAM-200 | Adhesion promoting agent | 2.00 |
| BYK 307 | Surfactant | 0.10 |
| Dowanol PM | Solvent for coating | 2,000 |

The coating solution/dispersion was coated on a substrate that had been treated with a sodium silicate solution (see step 10 b) above). The coated web was then dried at 110° C. using hot air. Then, the web was exposed to the LED visible light at 85,000 lumen/m² for 5 seconds.

The precursor was imaged with a UV-Violet laser (405 nm) at an energy density between 20 and 80 ρJ/cm², then preheated at 100° C. and at a speed of 1.5 meter per minute. The preheated plate was placed on the Heidelberg 46-1 press for development using ink and fountain solution. A clean image was obtained after 20 revolutions. It allowed printing over 30,000 copies with high resolution image and no deterioration.

The precursor was also imaged with a NIR laser (830 nm) at an energy density between 80 and 300 mJ/cm², then placed on the Heidelberg 46-1 press for development using ink and fountain solution. A clean image was obtained after 20 revolutions. It allowed printing over 20,000 copies with high resolution image and no deterioration.

The performances of this precursor were compared with that of an identical precursor without a crosslinked surface. The crosslinked precursor/plate performed better than the un-crosslinked precursor/plate of this Example in terms of tackiness, surface scratching resistance, imaging speed, shelf-life, and number of copies printed.

### Example NIR-6—Precursor for On-Press Development

A negative working computer-to-plate precursor comprising an imageable layer having a crosslinked surface, which is sensitive to NIR laser radiation, and as stated above is also sensitive to UV-violet radiation, was produced using a coating solution/dispersion of the following composition:

| Constituents | Function | Weight (Kg) |
|---|---|---|
| Hydroxy propyl cellulose | Binder | 3.50 |
| PolyNP ®150Y | Reactive Copolymer (particles) | 29.5 |
| Tuxedo ® 06C051D | Radical polymerizable oligomer | 32.0 |
| | Free radical coinitiator | |
| PolyFR 104 | Free radical photoinitiating | 11.0 |
| | copolymer | |
| 9-Vinyl Carbazole | Free radical stabilizer | 2.20 |
| 1H-1,2,4-triazole-3-thiol | Free radical scavenger | 1.00 |
| ADS798BD | NIR photosensitizer | 2.00 |
| PolyBlue 15A | Visible colorant (pigment) | 5.00 |
| 9W1100 White Pigment | Visible light reflecting pigment | 1.00 |
| Sipomer ® PAM-200 | Adhesion promoting agent | 2.00 |
| BYK 307 | Surfactant | 0.10 |
| Dowanol PM | Solvent for coating | 2,000 |

The coating solution/dispersion was coated on a substrate that had been treated with a sodium silicate solution (see step 10 b) above). The coated web was then dried at 110° C. using hot air. Then, the web was exposed to the LED visible light at 85,000 lumen/m² for 5 seconds.

The precursor was imaged with a UV-Violet laser (405 nm) at an energy density between 20 and 80 ρJ/cm², then preheated at 100° C., and at a speed of 1.5 meter per minute. The preheated plate was placed on the Heidelberg 46-1 press for development using ink and fountain solution. A clean image was obtained after 20 revolutions. It allowed printing over 30,000 copies with high resolution image and no deterioration.

The precursor was also imaged with a NIR laser (830 nm) at an energy density between 80 and 300 mJ/cm2, then placed on the Heidelberg 46-1 press for development using ink and fountain solution. A clean image was obtained after 20 revolutions. It allowed printing over 20,000 copies with high resolution image and no deterioration.

The performances of this precursor were compared with that of an identical precursor without a crosslinked surface. The crosslinked precursor/plate performed better than the un-crosslinked precursor/plate of this Example in terms of tackiness, surface scratching resistance, imaging speed, shelf-life, and number of copies printed.

The scope of the claims should not be limited by the preferred embodiments set forth in the examples, but should be given the broadest interpretation consistent with the description as a whole.

### REFERENCES

The present description refers to a number of documents, the content of which is herein incorporated by reference in their entirety. These include, but are not limited to, the following documents:
U.S. Pat. No. 4,345,017,
U.S. Pat. No. 5,496,903,
U.S. Pat. No. 5,821,030,
U.S. Pat. No. 5,888,700,
U.S. Pat. No. 6,899,994,
U.S. Pat. No. 7,261,998,
U.S. Pat. No. 7,732,118,
U.S. Pat. No. 7,955,776,
U.S. Pat. No. 6,830,862,
U.S. Pat. No. 7,723,010,
U.S. Pat. No. 7,910,768,
U.S. Pat. No. 8,021,827,
U.S. Pat. No. 8,323,867,
U.S. Pat. No. 8,491,993 (Nguyen et al.),
US patent publication no. 2011/0277653,
US patent publication no. 2012/0137929,
U.S. patent application Ser. No. 14/249,458, and
International patent publication no. WO 2012/155259.

1-34. (canceled)

35. A free radical scavenger of formula:
(Pₘ-L)ₙ-T_{q},
wherein:
P is a radical polymerizable functional group or a substituent formed by joining two or more radical polymerizable functional groups together;
L is a linker having a valence equal to m+q;
T is a thiol group, or a substituent comprising a thiol group and optionally further comprising a carboxylic acid group, wherein said substituent has a valence equal to n;
m is an integer between 1 to 5;
n is an integer between 1 to 5; and
q is an integer between 1 to 5.

36. The free radical scavenger of claim 35 being of formula:
P-L-T,
Pₘ-L-T,
P-L-T_{q}, or
(P-L)ₙ-T.

37. The free radical scavenger of claim 36, being P-L-T.

38. The free radical scavenger of claim 36, being Pₘ-L-T, wherein m is 2.

39. The free radical scavenger of claim 36, being P-L-T_{q}, wherein q is 2.

40. The free radical scavenger of claim 36, being (P-L)ₙ-T, wherein n is 2.

41. The free radical scavenger of claim 35, wherein P is:
—X,
—C—(CH₂—X)₃, or
—C(CH₂—X)₂(CH₂—O—CH₂—C—(CH₂—X)₃),
in which X is a radical polymerizable functional group.

42. The free radical scavenger of claim 35, wherein the radical polymerizable functional group is acrylate, methacrylate, acrylamide, methacrylamide, alkylacrylate, alkylmethacrylate, alkylacrylamide, alkylmethacrylamide, vinyl ether, allyl, or styryl.

43. The free radical scavenger of claim 35, wherein P is:

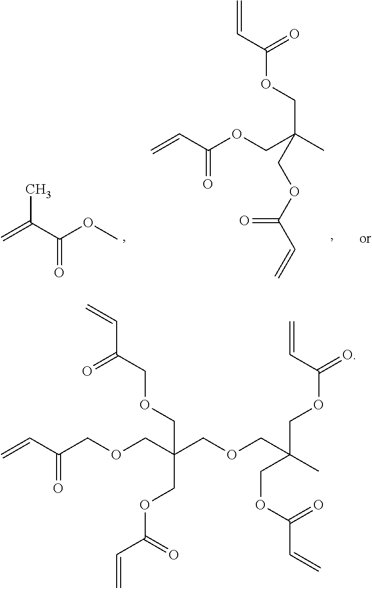

44. The free radical scavenger of claim 35, wherein T is:

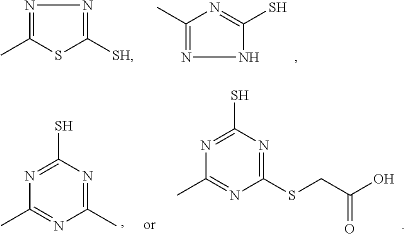

45. The free radical scavenger of claim 35, wherein L is an linear, branched or alicyclic alkylene or alkylyne group comprising, at either end thereof or in between any two carbon atoms thereof, one or more of the following functional groups:
—NH—C(═O)—S—,
—S—C(═O)—NH—
—NH—C(═O)—NH—,
—NH—C(═O)—O—,
—O—C(═O)—NH—,
—S—, 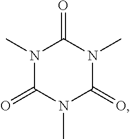
—NH—C(═O)—, or
—C(═O)—NH—.

46. The free radical scavenger of claim 35, wherein L is:

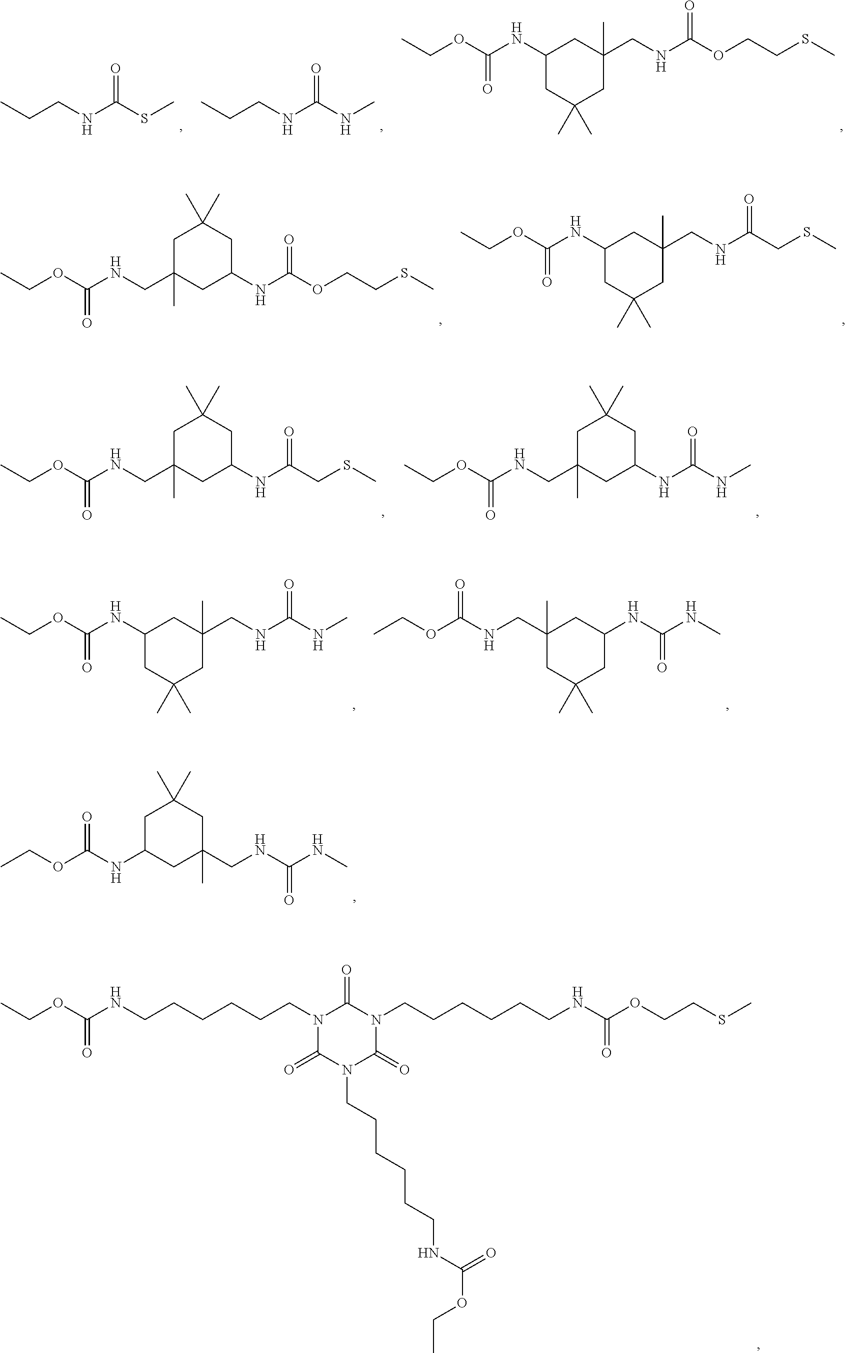

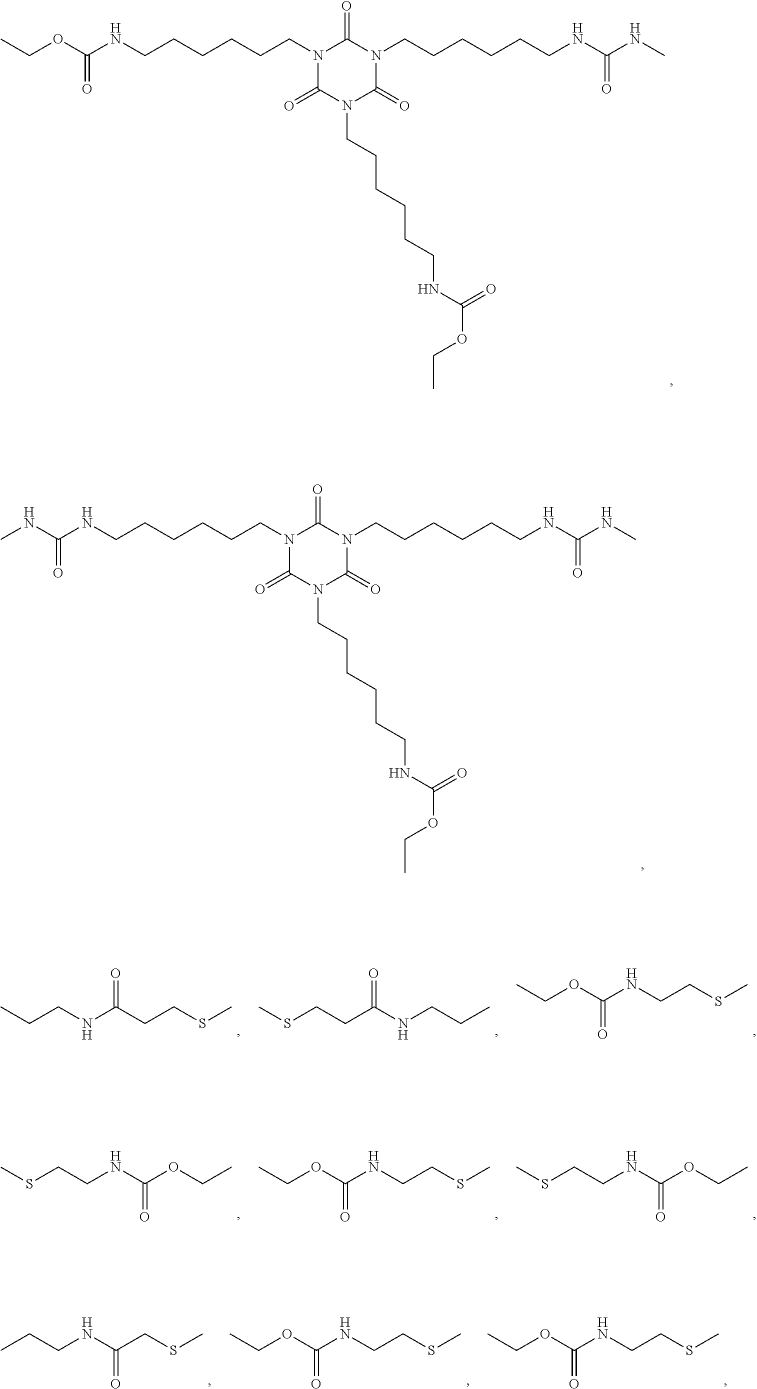

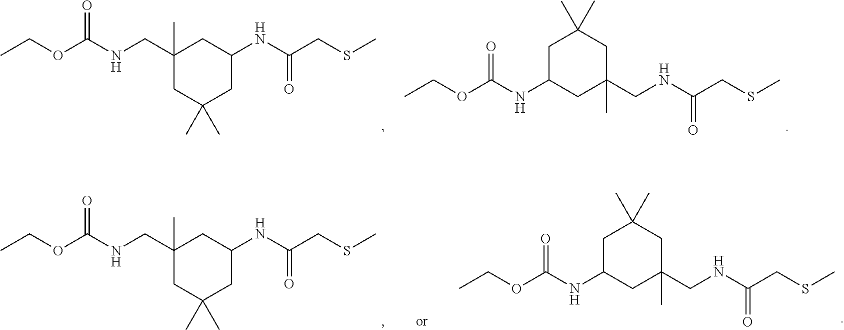 [SMILES: CCOC(=O)NCC1(C)CC(NC(=O)CSC)CC(C)(C)C1 ; CCOC(=O)NC1CC(C)(C)CC(C)(CNC(=O)CSC)C1 ; CCOC(=O)NCC1(C)CC(NC(=O)CSC)CC(C)(C)C1 ; CCOC(=O)NC1CC(C)(C)CC(C)(CNC(=O)CSC)C1]

47. The free radical scavenger of claim 35 being:

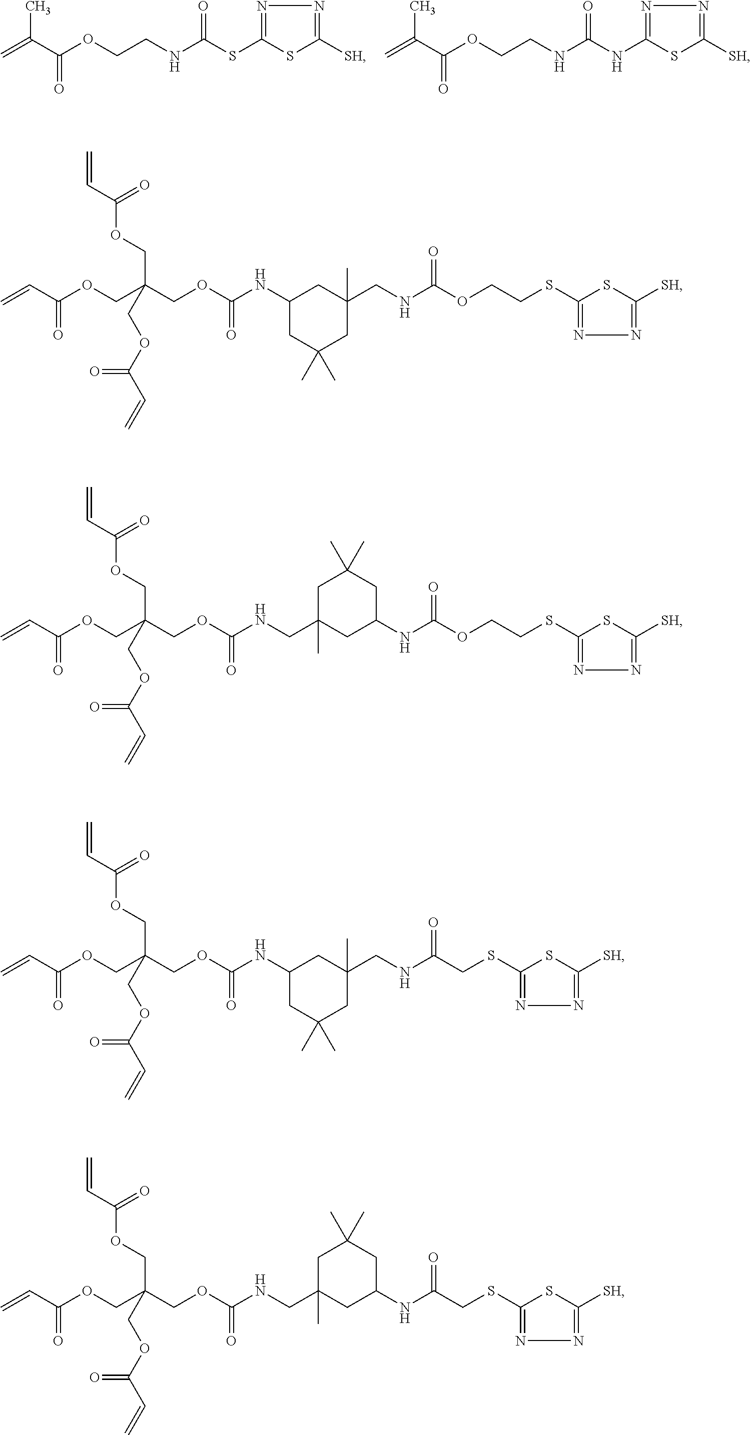

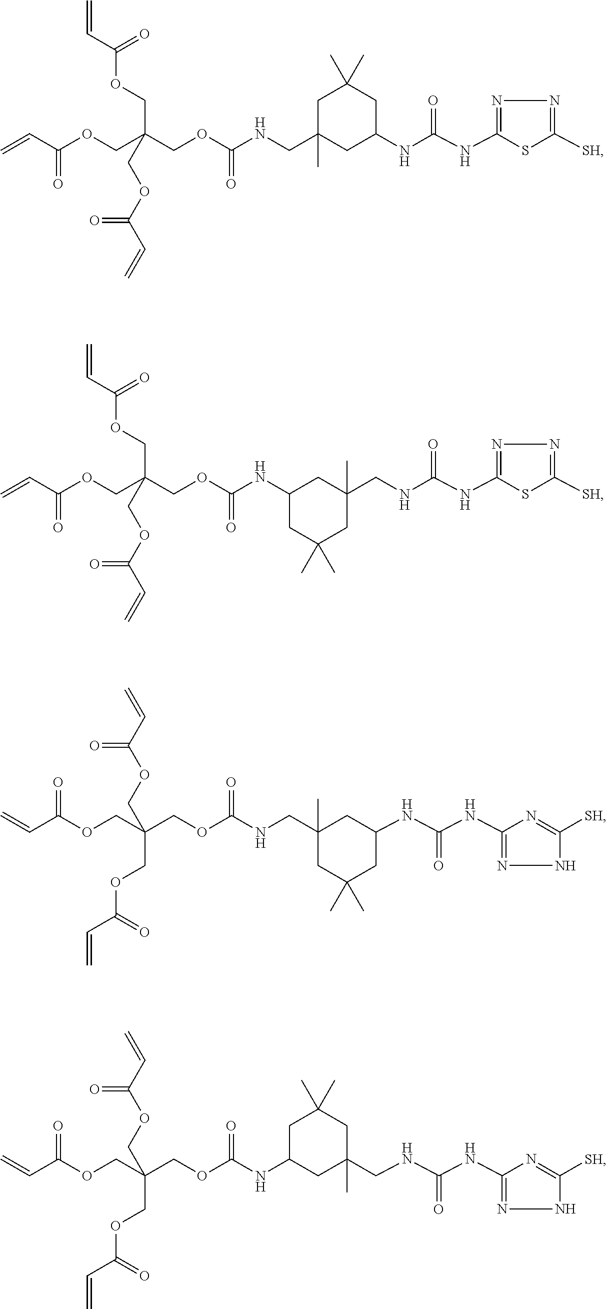 [SMILES: C=CC(=O)OCC(COC(=O)C=C)(COC(=O)C=C)COC(=O)NCC1(C)CC(NC(=O)Nc2nnc(S)s2)CC(C)(C)C1 ; C=CC(=O)OCC(COC(=O)C=C)(COC(=O)C=C)COC(=O)NC1CC(C)(C)CC(C)(CNC(=O)Nc2nnc(S)s2)C1 ; C=CC(=O)OCC(COC(=O)C=C)(COC(=O)C=C)COC(=O)NCC1(C)CC(NC(=O)Nc2n[nH]c(S)n2)CC(C)(C)C1 ; C=CC(=O)OCC(COC(=O)C=C)(COC(=O)C=C)COC(=O)NC1CC(C)(C)CC(C)(CNC(=O)Nc2n[nH]c(S)n2)C1]

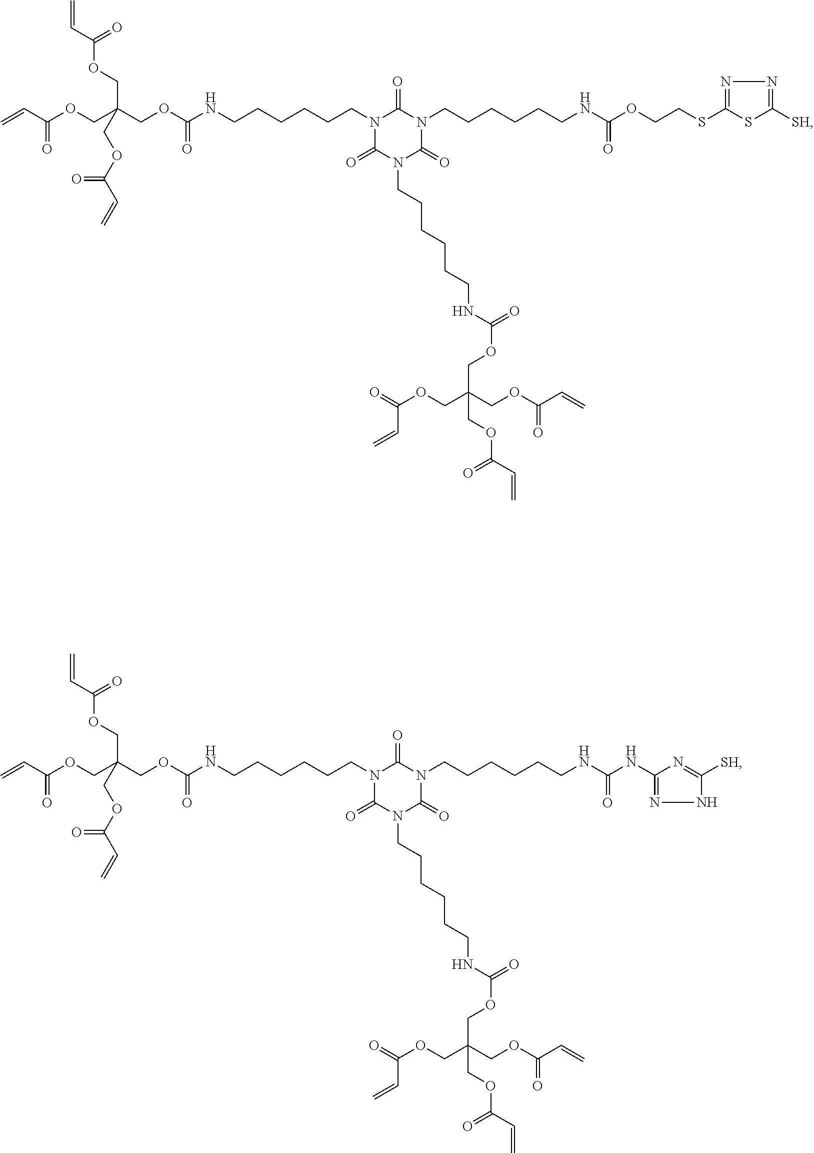 [SMILES: C=CC(=O)OCC(COC(=O)C=C)(COC(=O)C=C)COC(=O)NCCCCCCn1c(=O)n(CCCCCCNC(=O)OCCSc2nnc(S)s2)c(=O)n(CCCCCCNC(=O)OCC(COC(=O)C=C)(COC(=O)C=C)COC(=O)C=C)c1=O ; C=CC(=O)OCC(COC(=O)C=C)(COC(=O)C=C)COC(=O)NCCCCCCn1c(=O)n(CCCCCCNC(=O)Nc2n[nH]c(S)n2)c(=O)n(CCCCCCNC(=O)OCC(COC(=O)C=C)(COC(=O)C=C)COC(=O)C=C)c1=O]

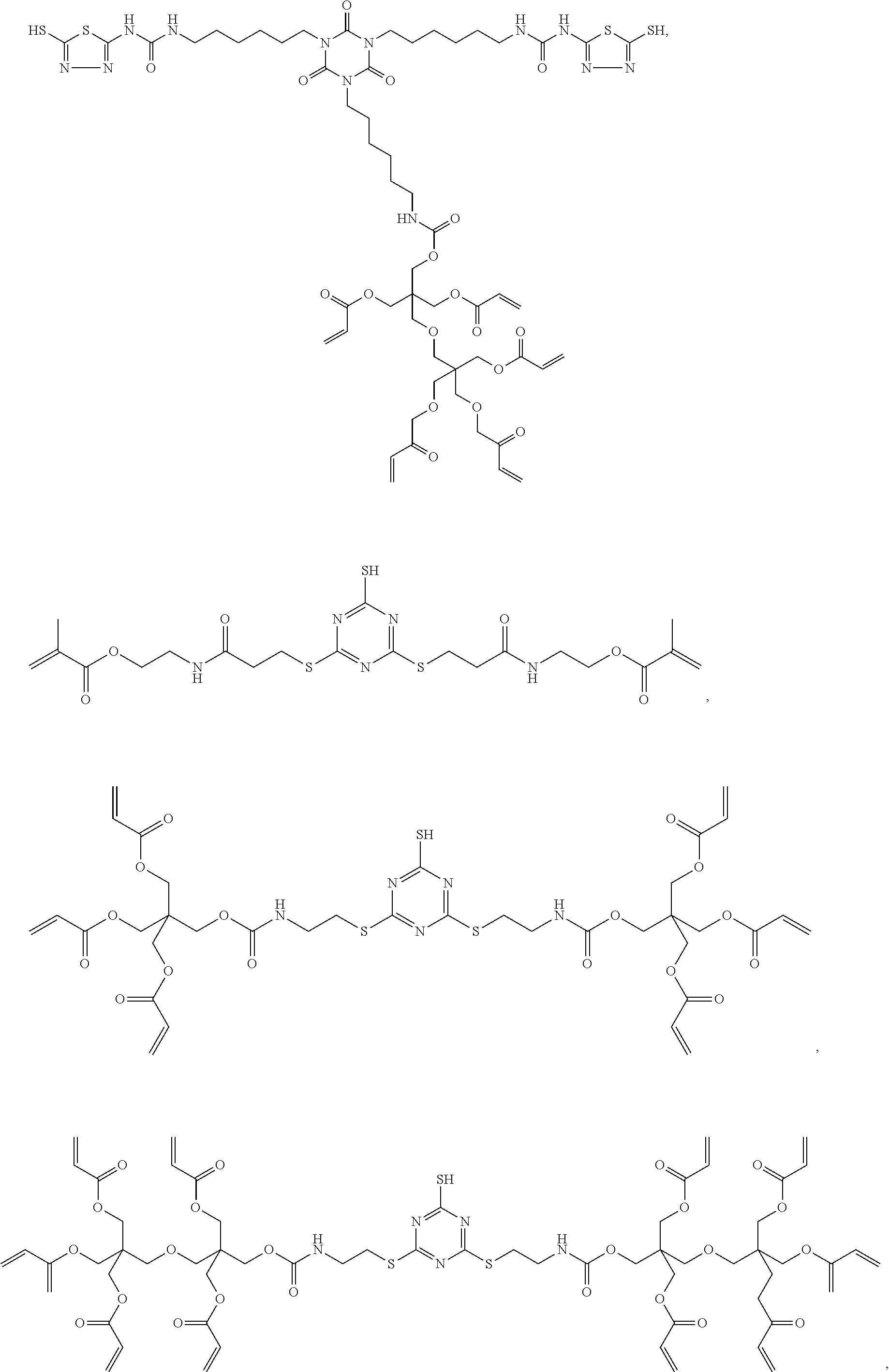

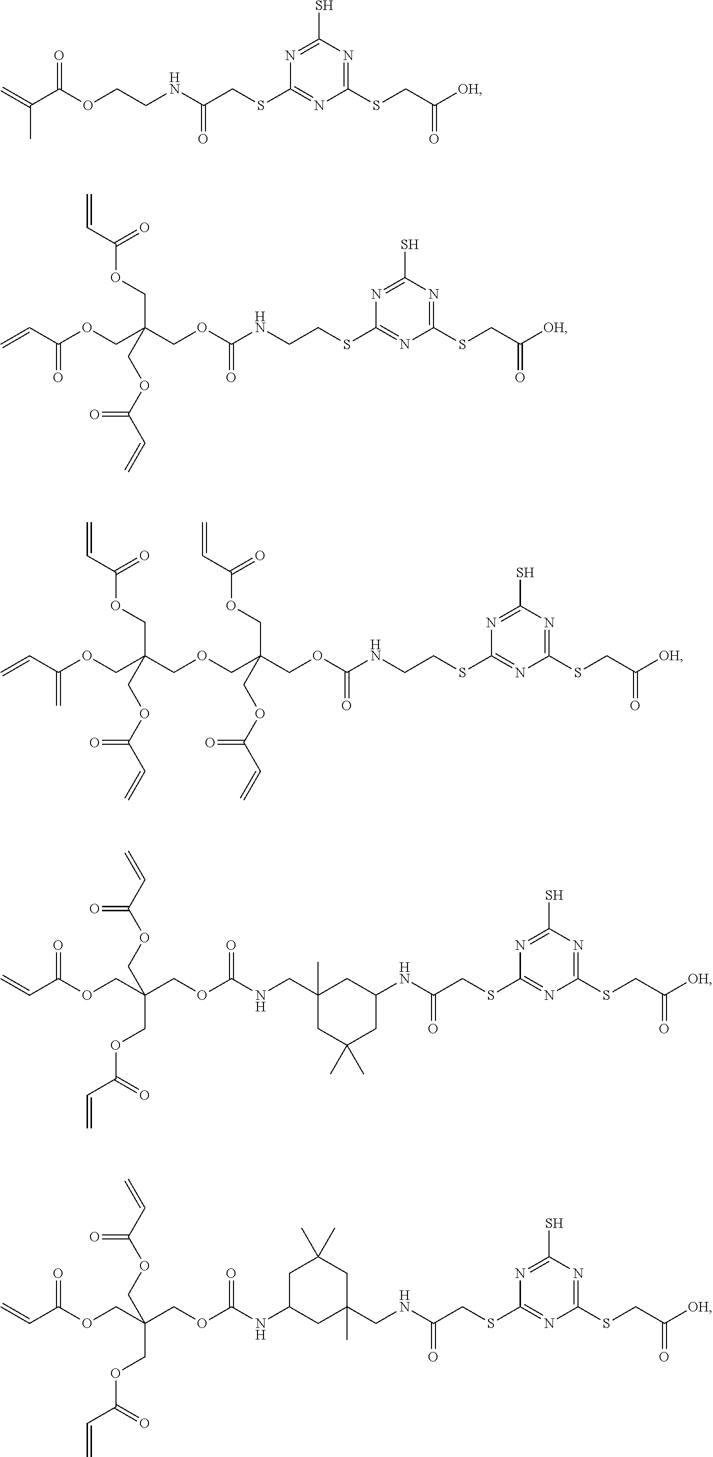 [SMILES: C=C(C)C(=O)OCCNC(=O)CSc1nc(S)nc(SCC(=O)O)n1 ; C=CC(=O)OCC(COC(=O)C=C)(COC(=O)C=C)COC(=O)NCCSc1nc(S)nc(SCC(=O)O)n1 ; C=CC(=C)OCC(COCC(COC(=O)C=C)(COC(=O)C=C)COC(=O)NCCSc1nc(S)nc(SCC(=O)O)n1)(COC(=O)C=C)COC(=O)C=C ; C=CC(=O)OCC(COC(=O)C=C)(COC(=O)C=C)COC(=O)NCC1(C)CC(NC(=O)CSc2nc(S)nc(SCC(=O)O)n2)CC(C)(C)C1 ; C=CC(=O)OCC(COC(=O)C=C)(COC(=O)C=C)COC(=O)NC1CC(C)(C)CC(C)(CNC(=O)CSc2nc(S)nc(SCC(=O)O)n2)C1]

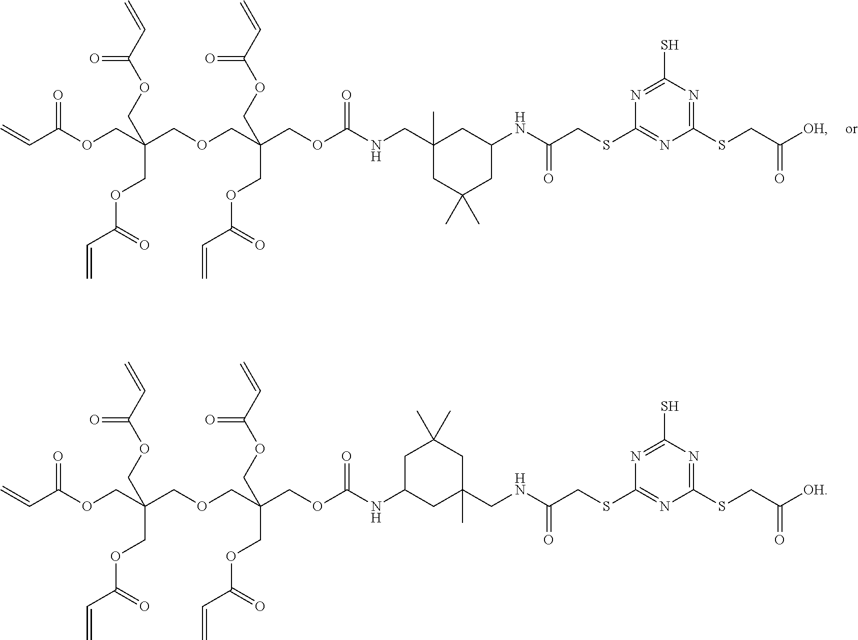 [SMILES: C=CC(=O)OCC(COCC(COC(=O)C=C)(COC(=O)C=C)COC(=O)NCC1(C)CC(NC(=O)CSc2nc(S)nc(SCC(=O)O)n2)CC(C)(C)C1)(COC(=O)C=C)COC(=O)C=C ; C=CC(=O)OCC(COCC(COC(=O)C=C)(COC(=O)C=C)COC(=O)NC1CC(C)(C)CC(C)(CNC(=O)CSc2nc(S)nc(SCC(=O)O)n2)C1)(COC(=O)C=C)COC(=O)C=C]

48. The free radical scavenger of claim 35, wherein L is a copolymer, with P and T being attached as pendant groups to different repeat units.

49. The free radical scavenger of claim 48, comprising:
two or more of the following repeat units: 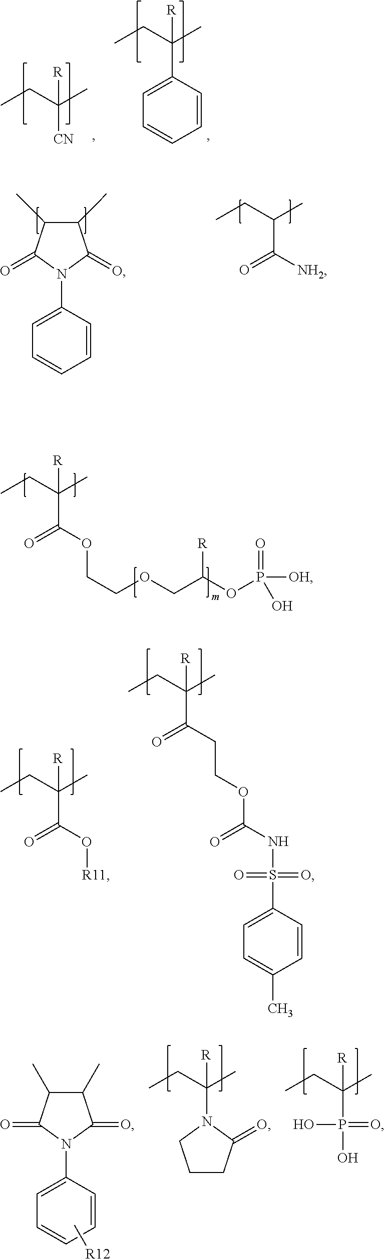 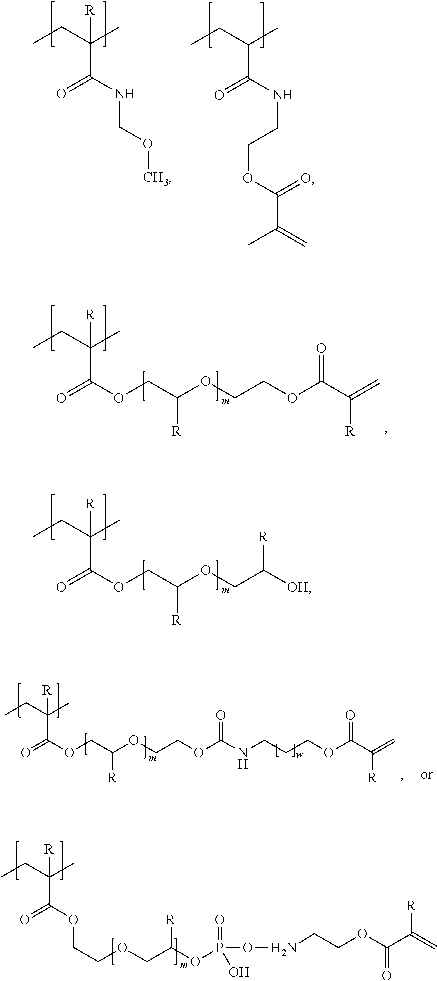
wherein:
m and w may vary between 0 and 50;
R is hydrogen or methyl;
R11 is H or linear and branched alkyl chain; and
R12 is alkyl, hydroxyl, or carboxylic acid,
with the proviso that at least one of said two or more repeat units comprises a radical polymerizable functional group,
and an additional repeat unit to which T is attached as a pendant group.

50. The free radical scavenger of claim 48 being: 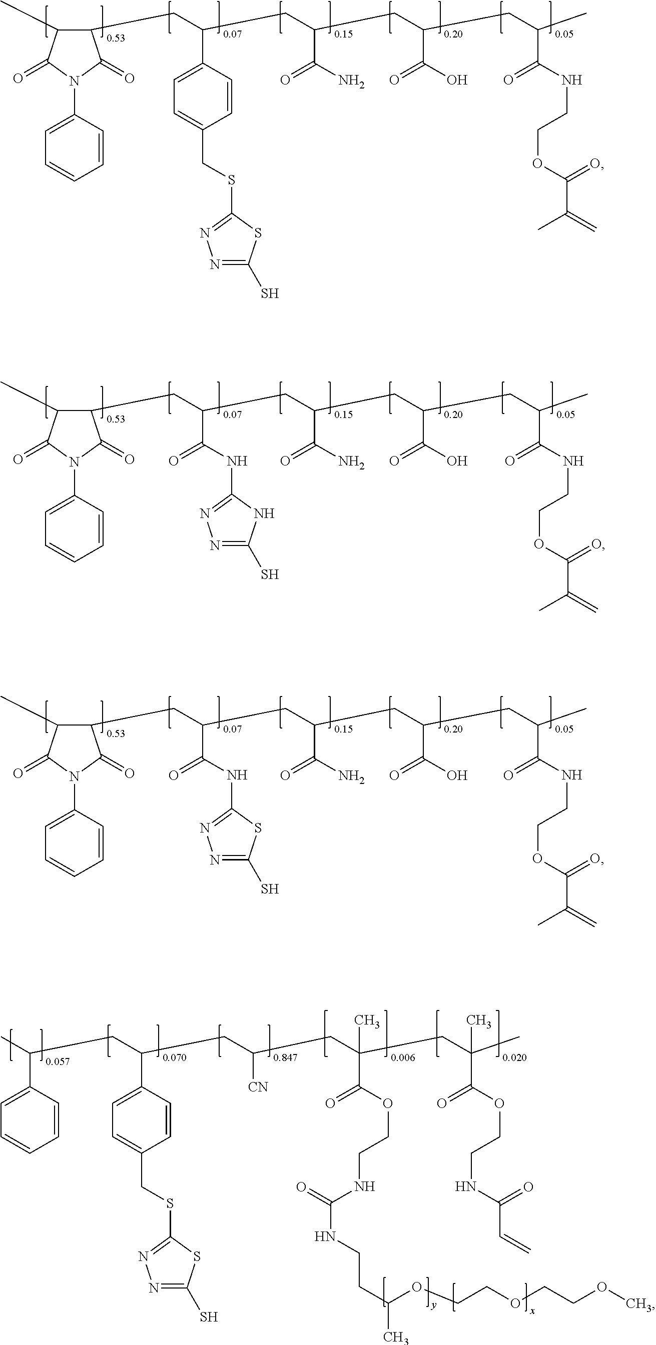
wherein x and y are the number of repeating units and wherein x is 10 and y is 31.
